(19) United States
(12) Patent Application Publication
(10) Pub. No.: US 2022/0352441 A1
(43) Pub. Date: Nov. 3, 2022

(54) CU PADS FOR REDUCED DISHING IN LOW TEMPERATURE ANNEALING AND BONDING

(71) Applicant: Meta Platforms Technologies, LLC, Menlo Park, CA (US)

(72) Inventors: Stephan LUTGEN, Dresden (DE); Shenghui LEI, Castleknock (IE); Sharon Nannette FARRENS, Glounthaune (IE)

(21) Appl. No.: 17/344,131

(22) Filed: Jun. 10, 2021

Related U.S. Application Data
(60) Provisional application No. 63/182,689, filed on Apr. 30, 2021.

(51) Int. Cl. H01L 33/62; H01L 25/075; H01L 23/00

(52) U.S. Cl. CPC H01L 33/62; H01L 25/0753; H01L 24/05; H01L 24/08; H01L 24/80; H01L 2933/0066; H01L 2224/05012; H01L 2224/05013; H01L 2224/05015; H01L 2224/05147; H01L 2224/05144; H01L 2224/05124; H01L 2224/08225; H01L 2224/80097; H01L 2224/80895; H01L 2224/80896; H01L 2924/12041; H01L 2924/1426; H01L 2924/3656

(57) ABSTRACT

A device includes an array of light sources (e.g., micro-LEDs, micro-RCLEDs, micro-laser: micro-SLEDs, or micro-VCSELs), a dielectric layer on the array of light sources, and a set of metal bonding pads (e.g., copper bonding pads) in the dielectric layer. Each metal bonding pad of the set of metal bonding pads is electrically connected to a respective light source of the array of light sources. Each metal bonding pad of the set of metal bonding pads includes a first portion at a bonding surface and characterized by a first lateral cross-sectional area, and a second portion away from the bonding surface and characterized by a second lateral cross-sectional area larger than two times of the first lateral cross-sectional area. The device can be bonded to a backplane that includes a drive circuit through a low annealing temperature hybrid bonding.

### CROSS-REFERENCE TO RELATED APPLICATION

This patent application claims benefit of and priority to U.S. Provisional Patent Application Ser. No. 63/182,689, filed Apr. 30, 2021, entitled “CU PADS FOR REDUCED DISHING IN LOW TEMPERATURE ANNEALING AND BONDING,” the disclosure of which is hereby incorporated by reference in its entirety for all purposes.

### BACKGROUND

Light emitting diodes (LEDs) convert electrical energy into optical energy, and offer many benefits over other light sources, such as reduced size, improved durability, and increased efficiency. LEDs can be used as light sources in many display systems, such as televisions, computer monitors, laptop computers, tablets, smartphones, projection systems, and wearable electronic devices. Micro-LEDs (“μLEDs”) based on III-V semiconductors, such as alloys of AlN, GaN, InN, InGaN, AlGaInP, other ternary and quaternary arsenide and phosphide alloys including GaInAsPN, AlGaInSb, and the like, have begun to be developed for various display applications due to their small size (e.g., with a linear dimension less than 100 μm, less than 50 μm, less than 10 μm, or less than 5 μm), high packing density (and hence higher resolution), and high brightness. For example, micro-LEDs that emit light of different colors (e.g., red, green, and blue) can be used to form the sub-pixels of a display system, such as a television or a near-eye display system.

### SUMMARY

This disclosure relates generally to micro-light emitting diodes (micro-LEDs). More specifically, techniques disclosed herein relate to reliable hybrid bonding of micro-LED devices having small pitches to drive circuits (e.g., on a CMOS backplane) at low temperatures, thereby achieving high bonding strength, minimizing or eliminating metal dishing, and avoiding high-temperature wafer bowing. Various inventive embodiments are described herein, including devices, systems, methods, structures, materials, processes, and the like.

According to certain embodiments, a device may include an array of light sources (e.g., micro-LEDs, micro-RCLEDs, micro-laser: micro-SLEDs, or micro-VCSELs), a dielectric layer on the array of light sources, and a set of metal bonding pads in the dielectric layer. Each metal bonding pad of the set of metal bonding pads may include a bonding surface for bonding to a drive circuit, a first portion at the bonding surface and characterized by a first lateral cross-sectional area, and a second portion away from the bonding surface and electrically connected to a respective light source of the array of light sources, the second portion characterized by a second lateral cross-sectional area larger than 1.2 times of the first lateral cross-sectional area. In some embodiments, a pitch of the set of metal bonding pads is less than 10 μm, less than 5 μm, less than 3 μm, or less than 2 μm.

In some embodiments, each metal bonding pad of the set of metal bonding pads may have a circular, elliptical, or polygonal (e.g., triangular, rectangular, quadrilateral, pentagonal, etc.) shape at the bonding surface, and a linear dimension of each metal bonding pad of the set of metal bonding pads at the bonding surface may be less than a half, a third, or a quarter of a pitch of the set of metal bonding pads. In one example, each metal bonding pad of the set of metal bonding pads may include a first cylindric section having a first diameter and a second cylindric section having a second diameter that is larger than the first diameter, where the bonding surface of the metal bonding pad is on the first cylindric section. A height of the first cylindric section may be equal to or less than a half of a height of the second cylindric section. The first diameter may be less than three quarters or a half of the second diameter. In another example, each metal bonding pad of the set of metal bonding pads may be characterized by a shape of a truncated cone. A diameter of a top surface of the truncated cone may be less than three quarters or a half of a diameter of a base of the truncated cone. Each metal bonding pad of the set of metal bonding pads may be electrically connected to a p-contact region of the respective light source of the array of light sources.

According to certain embodiments, a light source may include a backplane and an LED dies. The backplane may include a drive circuit, a first dielectric layer on the drive circuit, and a first set of metal bonding pads in the first dielectric layer and electrically connected to the drive circuit. The LED die may include an array of micro-LEDs, a second dielectric layer on the array of micro-LEDs, and a second set of metal bonding pads in the second dielectric layer and electrically connected to the array of micro-LEDs. The first dielectric layer may be bonded to the second dielectric layer at a bonding surface through dielectric bonding. Each metal bonding pad of the first set of metal bonding pads is bonded to a corresponding metal bonding pad of the second set of metal bonding pads. At least one of a metal bonding pad of the first set of metal bonding pads or a metal bonding pad of the second set of metal bonding pads may include a first portion at the bonding surface and characterized by a first lateral cross-sectional area, and a second portion away from the bonding surface and characterized by a second lateral cross-sectional area larger than 1.2 times of the first lateral cross-sectional area. A pitch of the first set of metal bonding pads and a pitch of the array of micro-LEDs may be less than 10 μm, less than 5 μm, less than 3 μm, or less than 2 μm.

In some embodiments, a linear dimension of a metal bonding pad of the second set of metal bonding pads at the bonding surface may be less than a half, a third, or a quarter of a pitch of the second set of metal bonding pads. In some embodiments, each metal bonding pad of the first set of metal bonding pads and the second set of metal bonding pads may include a first cylindric section having a first diameter, and a second cylindric section having a second diameter larger than the first diameter. A height of the first cylindric section may be equal to or less than a half of a height of the second cylindric section. The first diameter may be less than three quarters or a half of the second diameter. In some embodiments, each metal bonding pad of the first set of metal bonding pads and the second set of metal bonding pads may be characterized by a shape of a truncated cone, and wherein a diameter of a top surface of the truncated cone is less than three quarters or a half of a diameter of a base of the truncated cone. Each metal bonding pad of the first set of metal bonding pads may include copper, gold, aluminum, or another metal. There may be no void between each metal bonding pad of the first set of metal bonding pads and the corresponding metal bonding pad of the second set of metal bonding pads. Each metal bonding pad of the first set of metal bonding pads may be electrically connected to a respective micro-LED in the array of micro-LEDs through the corresponding metal bonding pad of the second set of metal bonding pads

According to certain embodiments, a method may include fabricating a wafer that includes an array of light sources and a first set of metal bonding pads in a first dielectric layer, where a pitch of the first set of metal bonding pads is less than 10 μm. The method may also include fabricating a CMOS backplane that includes a drive circuit and a second set of metal bonding pads in a second dielectric layer. At least one of a metal bonding pad of the first set of metal bonding pads or a metal bonding pad of the second set of metal bonding pads is characterized by a non-uniform lateral cross-sectional area and has a smallest lateral cross-sectional area at a bonding surface. At least one of the metal bonding pad of the first set of metal bonding pads or the metal bonding pad of the second set of metal bonding pads has a concave surface at the bonding surface. The method may further include bonding the first dielectric layer of the wafer to the second dielectric layer of the CMOS backplane at the bonding surface through dielectric bonding at a first temperature, and annealing the wafer and the CMOS backplane at a second temperature higher than the first temperature to bond the first set of metal bonding pads to the second set of metal bonding pads.

In some embodiments, the first set of metal bonding pads and the second set of metal bonding pads may include copper bonding pads, the first temperature may be at or below 50° C., and the second temperature may be at or below 340° C., such as at or below 200° C. In some embodiments, each metal bonding pad of the first set of metal bonding pads and the second set of metal bonding pads may include a first portion having a first diameter at the bonding surface, and a second portion having a second diameter larger than 1.2 times of the first diameter.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative embodiments are described in detail below with reference to the following figures.

FIG. 1 is a simplified block diagram of an example of an artificial reality system environment including a near-eye display according to certain embodiments.

FIG. 2 is a perspective view of an example of a near-eye display in the form of a head-mounted display (HMD) device for implementing some of the examples disclosed herein.

FIG. 3 is a perspective view of an example of a near-eye display in the form of a pair of glasses for implementing some of the examples disclosed herein.

FIG. 4 illustrates an example of an optical see-through augmented reality system including a waveguide display according to certain embodiments.

FIG. 5A illustrates an example of a near-eye display device including a waveguide display according to certain embodiments.

FIG. 5B illustrates an example of a near-eye display device including a waveguide display according to certain embodiments.

FIG. 6 illustrates an example of an image source assembly in an augmented reality system according to certain embodiments.

FIG. 7A illustrates an example of a light emitting diode (LED) having a vertical mesa structure according to certain embodiments.

FIG. 7B is a cross-sectional view of an example of an LED having a parabolic mesa structure according to certain embodiments.

FIG. 8A illustrates an example of a method of die-to-wafer bonding for arrays of LEDs according to certain embodiments.

FIG. 8B illustrates an example of a method of wafer-to-wafer bonding for arrays of LEDs according to certain embodiments.

FIGS. 9A-9D illustrates an example of a method of hybrid bonding for arrays of LEDs according to certain embodiments.

FIG. 10 illustrates an example of an LED array with secondary optical components fabricated thereon according to certain embodiments.

FIG. 11A illustrates an example of hybrid bonding of two wafers or dice.

FIG. 11B illustrates an example of misalignment during the hybrid bonding of two wafers or dice.

FIG. 11C illustrates an example of a die stack formed by hybrid bonding of two wafers.

FIGS. 12A-12C illustrate examples of bonding pad designs to mitigate misalignment during hybrid bonding.

FIG. 13A illustrates an example of a wafer including bonding pads with dishing.

FIG. 13B illustrates bonding pads with dishing in an example of a wafer.

FIG. 13C illustrates measured surface profiles of an example of a wafer including copper bonding pads with dishing.

FIG. 14 illustrates an example of a wafer including copper bonding pads with dishing of different depths.

FIGS. 15A and 15B illustrate an example of hybrid bonding of two wafers including copper bonding pads with dishing.

FIGS. 16A-16D illustrate an example of an annealing process for a wafer stack formed by hybrid bonding of two wafers including copper bonding pads with dishing.

FIG. 17 illustrates examples of copper expansion at different annealing temperatures for examples of copper bonding pads with different diameters and dishing depths.

FIG. 18 illustrates examples of wafer bowing of a hybrid-bonded wafer stack at different annealing temperatures.

FIGS. 19A-19G illustrate examples of copper bonding pad designs for reducing annealing temperature and improving bonding strength according to certain embodiments.

FIGS. 20A and 20B illustrate dimensions of examples of copper bonding pad designs according to certain embodiments.

FIG. 21 illustrates copper expansion as a function of the annealing temperature for different copper bonding pad designs according to certain embodiments.

FIG. 22A illustrates an example of barrier layer trenching at a bonding surface.

FIG. 22B illustrates an example of barrier layer trenching at a bonding surface according to certain embodiments.

FIG. 22C illustrates an example of bonding two bonding pads according to certain embodiments.

FIG. 23 illustrates an example of a process of hybrid bonding according to certain embodiments.

FIG. 24A illustrates an example of a micro-LED array according to certain embodiments.

FIG. 24B illustrates a cross-sectional view of the example of micro-LED array shown in FIG. 9A according to certain embodiments.

FIG. 24C illustrates an example of a micro-LED array bonded to a CMOS backplane according to certain embodiments.

FIG. 25A illustrates an example of a micro-LED array according to certain embodiments.

FIG. 25B illustrates a cross-sectional view of the example of micro-LED array shown in FIG. 11A according to certain embodiments.

FIG. 25C illustrates an example of a micro-LED array bonded to a CMOS backplane according to certain embodiments.

FIG. 26 is a simplified block diagram of an electronic system of an example of a near-eye display according to certain embodiments.

The figures depict embodiments of the present disclosure for purposes of illustration only. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

This disclosure relates generally to micro-light emitting diodes (micro-LEDs). More specifically, techniques disclosed herein relate to reliable hybrid bonding of micro-LED devices having small pitches to drive circuits (e.g., on a CMOS backplane) at low temperatures (e.g., at or lower than about 200° C. or about 150° C.), thereby achieving high bonding strength, eliminating metal dishing during annealing, forming good metal-to-metal interconnect diffusion bond with low resistance and high interconnect yield in wafer-to-wafer or die-to-wafer bonding, and avoiding high-temperature wafer bowing. Various inventive embodiments are described herein, including devices, systems, methods, structures, materials, processes, and the like. Augmented reality (AR) and virtual reality (VR) applications may use near-eye displays that include tiny light emitters, such as mini-LEDs or micro-LEDs. In LEDs, photons are generated through the recombination of injected electrons and holes within an active region (e.g., one or more semiconductor layers that may form one or more quantum wells). The LEDs may be controlled by drive circuits that can control the drive current for each LED and thus the quantity of injected carriers and the intensity of the light emitted by each LED. For micro-LED devices with small pitches, such as less than about 10 μm, less than about 5 μm, less than about 3 μm, or less than about 2 μm, it can be difficult to electrically connect the drive circuits to the electrodes of the LEDs using, for example, bonding wires, bonding bumps, and the like. In some implementations, the micro-LED devices may be bonded face-to-face with the drive circuits using bonding pads on surfaces of the micro-LED devices and bonding pads on the drive circuits such that no routing wires may be needed and the interconnects between the micro-LEDs and the drive circuits can be short, which may enable high-density and high-performance bonding.

It is challenging to precisely align the bonding pads on the micro-LED devices with the bonding pads on the drive circuits and form reliable bonding at the interfaces that may include both dielectric materials (e.g., SiO₂, SiN, or SiCN) and metal (e.g., Cu, Au, or Al) bonding pads. For example, when the pitch of the micro-LED device is about 2 or 3 microns or lower, the bonding pads may have a linear dimension less than about 1 μm in order to avoid shorting to adjacent micro-LEDs and to improve bonding strength for the dielectric bonding. On the other hand, for small bonding pads, misalignment may reduce the metal bonding area, increase the contact resistance (or may even be an open circuit), and/or cause diffusion of metals to the dielectric materials and the semiconductor materials.

In addition, to bond a micro-LED device (e.g., on a wafer) with the drive circuits (e.g., on a CMOS backplane) through wafer-level hybrid bonding, the bonding surfaces of the micro-LED wafer and the CMOS backplane may need to be planarized, for example, by chemical mechanical planarization (CMP) techniques or other techniques. The planarization of the bonding surfaces may cause dishing (concave surfaces) in the metal bonding pads. As such, there may be a void between a metal bonding pad on the micro-LED device and a corresponding metal bonding pad on the CMOS backplane due to the dishing on the two metal bonding pads.

Annealing at an elevated temperature may be performed such that the metal bonding pads may expand to reduce or eliminate the void and form a reliable metal connection. When the ratio between the volume of the void caused by the dishing and the volume of the metal material in the metal bonding pads is large, the annealing temperature may need to be very high in order to cause sufficient expansion of the metal material to completely fill the void. Annealing the bonded wafer stack including different materials on different substrates at high temperatures may cause large wafer bowing due to, for example, the different thermal expansion coefficients (CTEs) of the different materials, such as the Si substrate of the CMOS backplane and the GaAs (or sapphire) substrate of the micro-LED device. The wafer bowing may create defects or damages in the bonded wafer stack, such as high stress, cracks, delamination, slip lines, cratering, and the like. In addition, annealing the micro-LED device at high temperatures may degrade the performance of the micro-LEDs.

According to certain embodiments, the total volume of a metal (e.g., Cu) bonding pad may be increased, while still ensuring the bonding strength, by making a base portion of the metal bonding pad much larger than the contact portion (at the bonding surface) of the metal bonding pad. For example, the bonding pads can have a shape of a truncated cone, or can include two or more sections having different diameters. As a result, the cross-sectional area at the bonding surface may remain relatively small to have a relatively large oxide bonding area for high bonding strength, even for small-pitch micro-LED devices, while the total volume of the metal (e.g., Cu) bonding pad may be increased significantly, such that the minimum annealing temperature for eliminating the dishing and void can be reduced by, for example, about 50° C. or more. In addition, due to the smaller cross-sectional area of the metal bonding pads at the bonding surface, a barrier layer at the bonding surface can have a higher width, such that barrier layer trenching at the bonding surface and/or misalignment of the bonding pads may not cause metal diffusion into the dielectric layer or semiconductor materials.

According to certain embodiments, a light source may include a backplane bonded to an LED die or wafer. The backplane may include a drive circuit, a first dielectric layer on the drive circuit, and a first set of bonding pads in the first dielectric layer and electrically connected to the drive circuit. The LED die may include an array of micro-LEDs, a second dielectric layer on the array of micro-LEDs, and a second set of bonding pads in the second dielectric layer and electrically connected to the array of micro-LEDs. The first dielectric layer may be bonded to the second dielectric layer through low-temperature (e.g., room temperature) dielectric bonding. Each bonding pad of the first set of bonding pads may be bonded to a corresponding bonding pad of the second set of bonding pads. At least one of a bonding pad of the first set of bonding pads or a bonding pad of the second set of bonding pads may include a first portion characterized by a first lateral cross-sectional area at a bonding surface, and a second portion away from the bonding surface and characterized by a second lateral cross-sectional area larger than the first lateral cross-sectional area, such as larger than two times of the first lateral cross-sectional area or more.

The micro-LEDs described herein may be used in conjunction with various technologies, such as an artificial reality system. An artificial reality system, such as a head-mounted display (HMD) or heads-up display (HUD) system, generally includes a display configured to present artificial images that depict objects in a virtual environment. The display may present virtual objects or combine images of real objects with virtual objects, as in virtual reality (VR), augmented reality (AR), or mixed reality (MR) applications. For example, in an AR system, a user may view both displayed images of virtual objects (e.g., computer-generated images (CGIs)) and the surrounding environment by, for example, seeing through transparent display glasses or lenses (often referred to as optical see-through) or viewing displayed images of the surrounding environment captured by a camera (often referred to as video see-through). In some AR systems, the artificial images may be presented to users using an LED-based display subsystem.

As used herein, the term “light emitting diode (LED)” refers to a light source that includes at least an n-type semiconductor layer, a p-type semiconductor layer, and a light emitting region (i.e., active region) between the n-type semiconductor layer and the p-type semiconductor layer. The light emitting region may include one or more semiconductor layers that form one or more heterostructures, such as quantum wells. In some embodiments, the light emitting region may include multiple semiconductor layers that form one or more multiple-quantum-wells (MQWs), each including multiple (e.g., about 2 to 6) quantum wells.

As used herein, the term “micro-LED” or “μLED” refers to an LED that has a chip where a linear dimension of the chip is less than about 200 μm, such as less than 100 μm, less than 50 μm, less than 20 μm, less than 10 μm, or smaller. For example, the linear dimension of a micro-LED may be as small as 6 μm, 5 μm, 4 μm, 2 μm, or smaller. Some micro-LEDs may have a linear dimension (e.g., length or diameter) comparable to the minority carrier diffusion length. However, the disclosure herein is not limited to micro-LEDs, and may also be applied to mini-LEDs and large LEDs.

As used herein, the term “LED array precursor” refers to an LED die or wafer that does not have the opposing electrical contacts and/or the associated driver circuitry for each LED such that a driving voltage or current may be applied to the LED for the LED to emit light. For example, an LED array precursor may be a wafer or die with an epitaxial layer stack that may or may not include the light emitting regions, a wafer or die with mesa structures formed in the epitaxial layer stack, a wafer or die with LED arrays and metal contacts formed thereon but without the driver circuitry, and the like. Accordingly, the LED die or wafer is a precursor to a monolithic LED array that may be formed after subsequent processing steps are performed, such as forming mesa structures, forming metal electrodes, bonding to electrical backplane, removing the substrate, forming light-extraction structures, or the like.

As used herein, the term “bonding” may refer to various methods for physically and/or electrically connecting two or more devices and/or wafers, such as adhesive bonding, metal-to-metal bonding, metal oxide bonding, wafer-to-wafer bonding, die-to-wafer bonding, hybrid bonding, soldering, under-bump metallization, and the like. For example, adhesive bonding may use a curable adhesive (e.g., an epoxy) to physically bond two or more devices and/or wafers through adhesion. Metal-to-metal bonding may include, for example, wire bonding or flip chip bonding using soldering interfaces (e.g., pads or balls), conductive adhesive, or welded joints between metals. Metal oxide hybrid bonding may form a metal and oxide pattern on each surface, bond the oxide sections together, and then bond the metal sections together to create a conductive path. Wafer-to-wafer bonding may bond two wafers (e.g., silicon wafers or other semiconductor wafers) without any intermediate layers and is based on chemical bonds between the surfaces of the two wafers. Wafer-to-wafer bonding may include wafer cleaning and other preprocessing, aligning and pre-bonding at room temperature, and annealing at elevated temperatures, such as about 250° C. or higher. Die-to-wafer bonding may use bumps on one wafer to align features of a pre-formed chip with drivers of a wafer. Hybrid bonding may include, for example, wafer cleaning, high-precision alignment of contacts of one wafer with contacts of another wafer, dielectric bonding of dielectric materials within the wafers at room temperature, and metal bonding of the contacts by annealing at, for example, 250-300° C. or higher. As used herein, the term “bump” may refer generically to a metal interconnect used or formed during bonding.

In the following description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

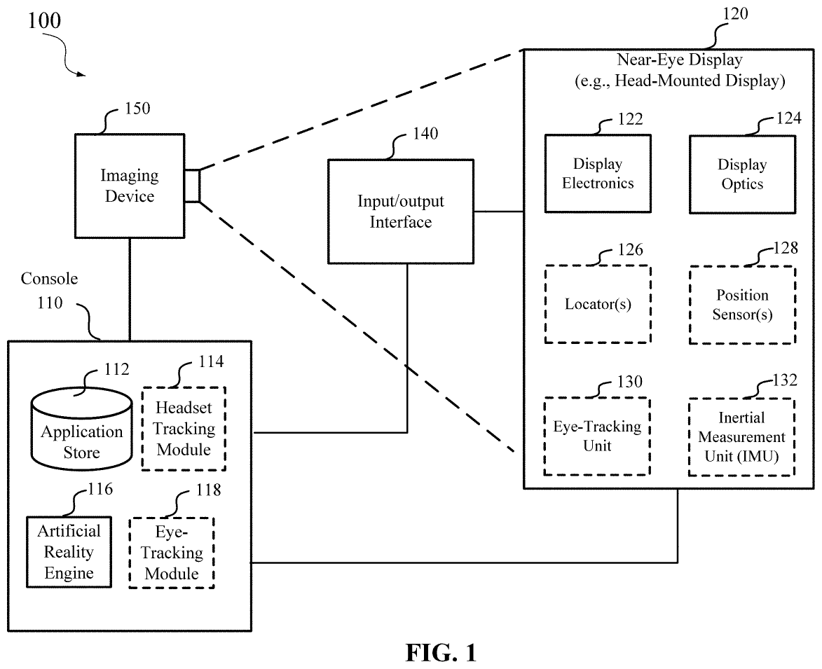

FIG. 1 is a simplified block diagram of an example of an artificial reality system environment 100 including a near-eye display 120 in accordance with certain embodiments. Artificial reality system environment 100 shown in FIG. 1 may include near-eye display 120, an optional external imaging device 150, and an optional input/output interface 140, each of which may be coupled to an optional console 110. While FIG. 1 shows an example of artificial reality system environment 100 including one near-eye display 120, one external imaging device 150, and one input/output interface 140, any number of these components may be included in artificial reality system environment 100, or any of the components may be omitted. For example, there may be multiple near-eye displays 120 monitored by one or more external imaging devices 150 in communication with console 110. In some configurations, artificial reality system environment 100 may not include external imaging device 150, optional input/output interface 140, and optional console 110. In alternative configurations, different or additional components may be included in artificial reality system environment 100.

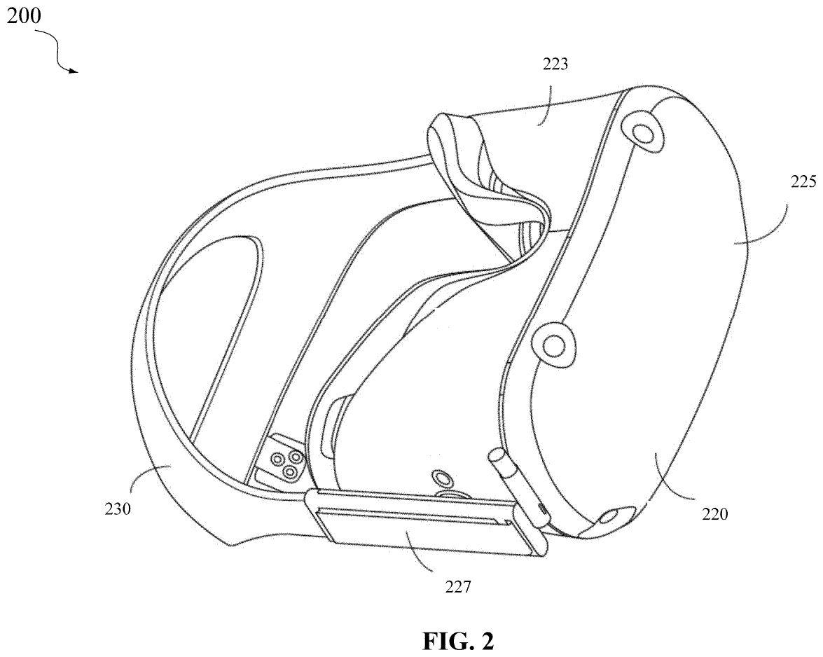

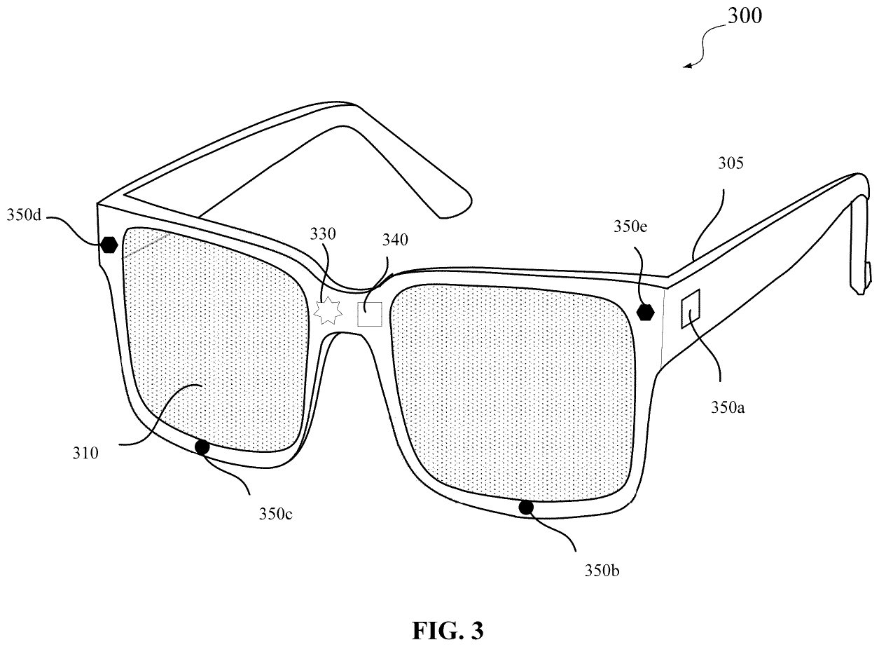

Near-eye display 120 may be a head-mounted display that presents content to a user. Examples of content presented by near-eye display 120 include one or more of images, videos, audio, or any combination thereof. In some embodiments, audio may be presented via an external device (e.g., speakers and/or headphones) that receives audio information from near-eye display 120, console 110, or both, and presents audio data based on the audio information. Near-eye display 120 may include one or more rigid bodies, which may be rigidly or non-rigidly coupled to each other. A rigid coupling between rigid bodies may cause the coupled rigid bodies to act as a single rigid entity. A non-rigid coupling between rigid bodies may allow the rigid bodies to move relative to each other. In various embodiments, near-eye display 120 may be implemented in any suitable form-factor, including a pair of glasses. Some embodiments of near-eye display 120 are further described below with respect to FIGS. 2 and 3. Additionally, in various embodiments, the functionality described herein may be used in a headset that combines images of an environment external to near-eye display 120 and artificial reality content (e.g., computer-generated images). Therefore, near-eye display 120 may augment images of a physical, real-world environment external to near-eye display 120 with generated content (e.g., images, video, sound, etc.) to present an augmented reality to a user.

In various embodiments, near-eye display 120 may include one or more of display electronics 122, display optics 124, and an eye-tracking unit 130. In some embodiments, near-eye display 120 may also include one or more locators 126, one or more position sensors 128, and an inertial measurement unit (IMU) 132. Near-eye display 120 may omit any of eye-tracking unit 130, locators 126, position sensors 128, and IMU 132, or include additional elements in various embodiments. Additionally, in some embodiments, near-eye display 120 may include elements combining the function of various elements described in conjunction with FIG. 1.

Display electronics 122 may display or facilitate the display of images to the user according to data received from, for example, console 110. In various embodiments, display electronics 122 may include one or more display panels, such as a liquid crystal display (LCD), an organic light emitting diode (OLED) display, an inorganic light emitting diode (ILED) display, a micro light emitting diode (μLED) display, an active-matrix OLED display (AMOLED), a transparent OLED display (TOLED), or some other display. For example, in one implementation of near-eye display 120, display electronics 122 may include a front TOLED panel, a rear display panel, and an optical component (e.g., an attenuator, polarizer, or diffractive or spectral film) between the front and rear display panels. Display electronics 122 may include pixels to emit light of a predominant color such as red, green, blue, white, or yellow. In some implementations, display electronics 122 may display a three-dimensional (3D) image through stereoscopic effects produced by two-dimensional panels to create a subjective perception of image depth. For example, display electronics 122 may include a left display and a right display positioned in front of a user's left eye and right eye, respectively. The left and right displays may present copies of an image shifted horizontally relative to each other to create a stereoscopic effect (i.e., a perception of image depth by a user viewing the image).

In certain embodiments, display optics 124 may display image content optically (e.g., using optical waveguides and couplers) or magnify image light received from display electronics 122, correct optical errors associated with the image light, and present the corrected image light to a user of near-eye display 120. In various embodiments, display optics 124 may include one or more optical elements, such as, for example, a substrate, optical waveguides, an aperture, a Fresnel lens, a convex lens, a concave lens, a filter, input/output couplers, or any other suitable optical elements that may affect image light emitted from display electronics 122. Display optics 124 may include a combination of different optical elements as well as mechanical couplings to maintain relative spacing and orientation of the optical elements in the combination. One or more optical elements in display optics 124 may have an optical coating, such as an anti-reflective coating, a reflective coating, a filtering coating, or a combination of different optical coatings.

Magnification of the image light by display optics 124 may allow display electronics 122 to be physically smaller, weigh less, and consume less power than larger displays. Additionally, magnification may increase a field of view of the displayed content. The amount of magnification of image light by display optics 124 may be changed by adjusting, adding, or removing optical elements from display optics 124. In some embodiments, display optics 124 may project displayed images to one or more image planes that may be further away from the user's eyes than near-eye display 120.

Display optics 124 may also be designed to correct one or more types of optical errors, such as two-dimensional optical errors, three-dimensional optical errors, or any combination thereof. Two-dimensional errors may include optical aberrations that occur in two dimensions. Example types of two-dimensional errors may include barrel distortion, pincushion distortion, longitudinal chromatic aberration, and transverse chromatic aberration. Three-dimensional errors may include optical errors that occur in three dimensions. Example types of three-dimensional errors may include spherical aberration, comatic aberration, field curvature, and astigmatism.

Locators 126 may be objects located in specific positions on near-eye display 120 relative to one another and relative to a reference point on near-eye display 120. In some implementations, console 110 may identify locators 126 in images captured by external imaging device 150 to determine the artificial reality headset's position, orientation, or both. A locator 126 may be an LED, a corner cube reflector, a reflective marker, a type of light source that contrasts with an environment in which near-eye display 120 operates, or any combination thereof. In embodiments where locators 126 are active components (e.g., LEDs or other types of light emitting devices), locators 126 may emit light in the visible band (e.g., about 380 nm to 750 nm), in the infrared (IR) band (e.g., about 750 nm to 1 mm), in the ultraviolet band (e.g., about 10 nm to about 380 nm), in another portion of the electromagnetic spectrum, or in any combination of portions of the electromagnetic spectrum.

External imaging device 150 may include one or more cameras, one or more video cameras, any other device capable of capturing images including one or more of locators 126, or any combination thereof. Additionally, external imaging device 150 may include one or more filters (e.g., to increase signal to noise ratio). External imaging device 150 may be configured to detect light emitted or reflected from locators 126 in a field of view of external imaging device 150. In embodiments where locators 126 include passive elements (e.g., retroreflectors), external imaging device 150 may include a light source that illuminates some or all of locators 126, which may retro-reflect the light to the light source in external imaging device 150. Slow calibration data may be communicated from external imaging device 150 to console 110, and external imaging device 150 may receive one or more calibration parameters from console 110 to adjust one or more imaging parameters (e.g., focal length, focus, frame rate, sensor temperature, shutter speed, aperture, etc.).

Position sensors 128 may generate one or more measurement signals in response to motion of near-eye display 120. Examples of position sensors 128 may include accelerometers, gyroscopes, magnetometers, other motion-detecting or error-correcting sensors, or any combination thereof. For example, in some embodiments, position sensors 128 may include multiple accelerometers to measure translational motion (e.g., forward/back, up/down, or left/right) and multiple gyroscopes to measure rotational motion (e.g., pitch, yaw, or roll). In some embodiments, various position sensors may be oriented orthogonally to each other.

IMU 132 may be an electronic device that generates fast calibration data based on measurement signals received from one or more of position sensors 128. Position sensors 128 may be located external to IMU 132, internal to IMU 132, or any combination thereof. Based on the one or more measurement signals from one or more position sensors 128, IMU 132 may generate fast calibration data indicating an estimated position of near-eye display 120 relative to an initial position of near-eye display 120. For example, IMU 132 may integrate measurement signals received from accelerometers over time to estimate a velocity vector and integrate the velocity vector over time to determine an estimated position of a reference point on near-eye display 120. Alternatively, IMU 132 may provide the sampled measurement signals to console 110, which may determine the fast calibration data. While the reference point may generally be defined as a point in space, in various embodiments, the reference point may also be defined as a point within near-eye display 120 (e.g., a center of IMU 132).

Eye-tracking unit 130 may include one or more eye-tracking systems. Eye tracking may refer to determining an eye's position, including orientation and location of the eye, relative to near-eye display 120. An eye-tracking system may include an imaging system to image one or more eyes and may optionally include a light emitter, which may generate light that is directed to an eye such that light reflected by the eye may be captured by the imaging system. For example, eye-tracking unit 130 may include a non-coherent or coherent light source (e.g., a laser diode) emitting light in the visible spectrum or infrared spectrum, and a camera capturing the light reflected by the user's eye. As another example, eye-tracking unit 130 may capture reflected radio waves emitted by a miniature radar unit. Eye-tracking unit 130 may use low-power light emitters that emit light at frequencies and intensities that would not injure the eye or cause physical discomfort. Eye-tracking unit 130 may be arranged to increase contrast in images of an eye captured by eye-tracking unit 130 while reducing the overall power consumed by eye-tracking unit 130 (e.g., reducing power consumed by a light emitter and an imaging system included in eye-tracking unit 130). For example, in some implementations, eye-tracking unit 130 may consume less than 100 milliwatts of power.

Near-eye display 120 may use the orientation of the eye to, e.g., determine an inter-pupillary distance (IPD) of the user, determine gaze direction, introduce depth cues (e.g., blur image outside of the user's main line of sight), collect heuristics on the user interaction in the VR media (e.g., time spent on any particular subject, object, or frame as a function of exposed stimuli), some other functions that are based in part on the orientation of at least one of the user's eyes, or any combination thereof. Because the orientation may be determined for both eyes of the user, eye-tracking unit 130 may be able to determine where the user is looking. For example, determining a direction of a user's gaze may include determining a point of convergence based on the determined orientations of the user's left and right eyes. A point of convergence may be the point where the two foveal axes of the user's eyes intersect. The direction of the user's gaze may be the direction of a line passing through the point of convergence and the mid-point between the pupils of the user's eyes.

Input/output interface 140 may be a device that allows a user to send action requests to console 110. An action request may be a request to perform a particular action. For example, an action request may be to start or to end an application or to perform a particular action within the application. Input/output interface 140 may include one or more input devices. Example input devices may include a keyboard, a mouse, a game controller, a glove, a button, a touch screen, or any other suitable device for receiving action requests and communicating the received action requests to console 110. An action request received by the input/output interface 140 may be communicated to console 110, which may perform an action corresponding to the requested action. In some embodiments, input/output interface 140 may provide haptic feedback to the user in accordance with instructions received from console 110. For example, input/output interface 140 may provide haptic feedback when an action request is received, or when console 110 has performed a requested action and communicates instructions to input/output interface 140. In some embodiments, external imaging device 150 may be used to track input/output interface 140, such as tracking the location or position of a controller (which may include, for example, an IR light source) or a hand of the user to determine the motion of the user. In some embodiments, near-eye display 120 may include one or more imaging devices to track input/output interface 140, such as tracking the location or position of a controller or a hand of the user to determine the motion of the user.

Console 110 may provide content to near-eye display 120 for presentation to the user in accordance with information received from one or more of external imaging device 150, near-eye display 120, and input/output interface 140. In the example shown in FIG. 1, console 110 may include an application store 112, a headset tracking module 114, an artificial reality engine 116, and an eye-tracking module 118. Some embodiments of console 110 may include different or additional modules than those described in conjunction with FIG. 1. Functions further described below may be distributed among components of console 110 in a different manner than is described here.

In some embodiments, console 110 may include a processor and a non-transitory computer-readable storage medium storing instructions executable by the processor. The processor may include multiple processing units executing instructions in parallel. The non-transitory computer-readable storage medium may be any memory, such as a hard disk drive, a removable memory, or a solid-state drive (e.g., flash memory or dynamic random access memory (DRAM)). In various embodiments, the modules of console 110 described in conjunction with FIG. 1 may be encoded as instructions in the non-transitory computer-readable storage medium that, when executed by the processor, cause the processor to perform the functions further described below.

Application store 112 may store one or more applications for execution by console 110. An application may include a group of instructions that, when executed by a processor, generates content for presentation to the user. Content generated by an application may be in response to inputs received from the user via movement of the user's eyes or inputs received from the input/output interface 140. Examples of the applications may include gaming applications, conferencing applications, video playback application, or other suitable applications.

Headset tracking module 114 may track movements of near-eye display 120 using slow calibration information from external imaging device 150. For example, headset tracking module 114 may determine positions of a reference point of near-eye display 120 using observed locators from the slow calibration information and a model of near-eye display 120. Headset tracking module 114 may also determine positions of a reference point of near-eye display 120 using position information from the fast calibration information. Additionally, in some embodiments, headset tracking module 114 may use portions of the fast calibration information, the slow calibration information, or any combination thereof, to predict a future location of near-eye display 120. Headset tracking module 114 may provide the estimated or predicted future position of near-eye display 120 to artificial reality engine 116.

Artificial reality engine 116 may execute applications within artificial reality system environment 100 and receive position information of near-eye display 120, acceleration information of near-eye display 120, velocity information of near-eye display 120, predicted future positions of near-eye display 120, or any combination thereof from headset tracking module 114. Artificial reality engine 116 may also receive estimated eye position and orientation information from eye-tracking module 118. Based on the received information, artificial reality engine 116 may determine content to provide to near-eye display 120 for presentation to the user. For example, if the received information indicates that the user has looked to the left, artificial reality engine 116 may generate content for near-eye display 120 that mirrors the user's eye movement in a virtual environment. Additionally, artificial reality engine 116 may perform an action within an application executing on console 110 in response to an action request received from input/output interface 140, and provide feedback to the user indicating that the action has been performed. The feedback may be visual or audible feedback via near-eye display 120 or haptic feedback via input/output interface 140.

Eye-tracking module 118 may receive eye-tracking data from eye-tracking unit 130 and determine the position of the user's eye based on the eye tracking data. The position of the eye may include an eye's orientation, location, or both relative to near-eye display 120 or any element thereof. Because the eye's axes of rotation change as a function of the eye's location in its socket, determining the eye's location in its socket may allow eye-tracking module 118 to more accurately determine the eye's orientation.

FIG. 2 is a perspective view of an example of a near-eye display in the form of an HMD device 200 for implementing some of the examples disclosed herein. HMD device 200 may be a part of, e.g., a VR system, an AR system, an MR system, or any combination thereof. HMD device 200 may include a body 220 and a head strap 230. FIG. 2 shows a bottom side 223, a front side 225, and a left side 227 of body 220 in the perspective view. Head strap 230 may have an adjustable or extendible length. There may be a sufficient space between body 220 and head strap 230 of HMD device 200 for allowing a user to mount HMD device 200 onto the user's head. In various embodiments, HMD device 200 may include additional, fewer, or different components. For example, in some embodiments, HMD device 200 may include eyeglass temples and temple tips as shown in, for example, FIG. 3 below, rather than head strap 230.

HMD device 200 may present to a user media including virtual and/or augmented views of a physical, real-world environment with computer-generated elements. Examples of the media presented by HMD device 200 may include images (e.g., two-dimensional (2D) or three-dimensional (3D) images), videos (e.g., 2D or 3D videos), audio, or any combination thereof. The images and videos may be presented to each eye of the user by one or more display assemblies (not shown in FIG. 2) enclosed in body 220 of HMD device 200. In various embodiments, the one or more display assemblies may include a single electronic display panel or multiple electronic display panels (e.g., one display panel for each eye of the user). Examples of the electronic display panel(s) may include, for example, an LCD, an OLED display, an ILED display, a μLED display, an AMOLED, a TOLED, some other display, or any combination thereof. HMD device 200 may include two eye box regions.

In some implementations, HMD device 200 may include various sensors (not shown), such as depth sensors, motion sensors, position sensors, and eye tracking sensors. Some of these sensors may use a structured light pattern for sensing. In some implementations, HMD device 200 may include an input/output interface for communicating with a console. In some implementations, HMD device 200 may include a virtual reality engine (not shown) that can execute applications within HMD device 200 and receive depth information, position information, acceleration information, velocity information, predicted future positions, or any combination thereof of HMD device 200 from the various sensors. In some implementations, the information received by the virtual reality engine may be used for producing a signal (e.g., display instructions) to the one or more display assemblies. In some implementations, HMD device 200 may include locators (not shown, such as locators 126) located in fixed positions on body 220 relative to one another and relative to a reference point. Each of the locators may emit light that is detectable by an external imaging device.

FIG. 3 is a perspective view of an example of a near-eye display 300 in the form of a pair of glasses for implementing some of the examples disclosed herein. Near-eye display 300 may be a specific implementation of near-eye display 120 of FIG. 1, and may be configured to operate as a virtual reality display, an augmented reality display, and/or a mixed reality display.

Near-eye display 300 may include a frame 305 and a display 310. Display 310 may be configured to present content to a user. In some embodiments, display 310 may include display electronics and/or display optics. For example, as described above with respect to near-eye display 120 of FIG. 1, display 310 may include an LCD display panel, an LED display panel, or an optical display panel (e.g., a waveguide display assembly).

Near-eye display 300 may further include various sensors 350a, 350b, 350c, 350d, and 350e on or within frame 305. In some embodiments, sensors 350a-350e may include one or more depth sensors, motion sensors, position sensors, inertial sensors, or ambient light sensors. In some embodiments, sensors 350a-350e may include one or more image sensors configured to generate image data representing different fields of views in different directions. In some embodiments, sensors 350a-350e may be used as input devices to control or influence the displayed content of near-eye display 300, and/or to provide an interactive VR/AR/MR experience to a user of near-eye display 300. In some embodiments, sensors 350a-350e may also be used for stereoscopic imaging.

In some embodiments, near-eye display 300 may further include one or more illuminators 330 to project light into the physical environment. The projected light may be associated with different frequency bands (e.g., visible light, infra-red light, ultra-violet light, etc.), and may serve various purposes. For example, illuminator(s) 330 may project light in a dark environment (or in an environment with low intensity of infra-red light, ultra-violet light, etc.) to assist sensors 350a-350e in capturing images of different objects within the dark environment. In some embodiments, illuminator(s) 330 may be used to project certain light patterns onto the objects within the environment. In some embodiments, illuminator(s) 330 may be used as locators, such as locators 126 described above with respect to FIG. 1.

In some embodiments, near-eye display 300 may also include a high-resolution camera 340. Camera 340 may capture images of the physical environment in the field of view. The captured images may be processed, for example, by a virtual reality engine (e.g., artificial reality engine 116 of FIG. 1) to add virtual objects to the captured images or modify physical objects in the captured images, and the processed images may be displayed to the user by display 310 for AR or MR applications.

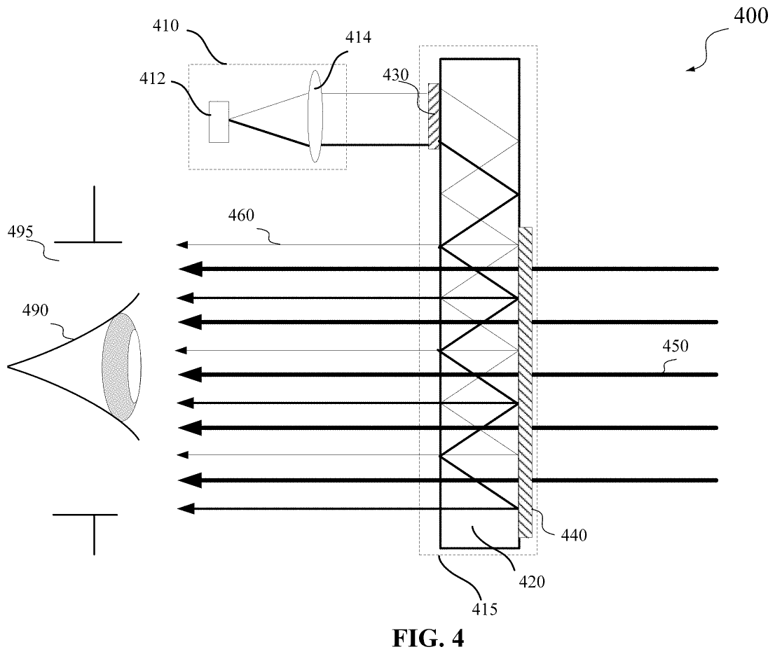

FIG. 4 illustrates an example of an optical see-through augmented reality system 400 including a waveguide display according to certain embodiments. Augmented reality system 400 may include a projector 410 and a combiner 415. Projector 410 may include a light source or image source 412 and projector optics 414. In some embodiments, light source or image source 412 may include one or more micro-LED devices described above. In some embodiments, image source 412 may include a plurality of pixels that displays virtual objects, such as an LCD display panel or an LED display panel. In some embodiments, image source 412 may include a light source that generates coherent or partially coherent light. For example, image source 412 may include a laser diode, a vertical cavity surface emitting laser, an LED, and/or a micro-LED described above. In some embodiments, image source 412 may include a plurality of light sources (e.g., an array of micro-LEDs described above), each emitting a monochromatic image light corresponding to a primary color (e.g., red, green, or blue). In some embodiments, image source 412 may include three two-dimensional arrays of micro-LEDs, where each two-dimensional array of micro-LEDs may include micro-LEDs configured to emit light of a primary color (e.g., red, green, or blue). In some embodiments, image source 412 may include an optical pattern generator, such as a spatial light modulator. Projector optics 414 may include one or more optical components that can condition the light from image source 412, such as expanding, collimating, scanning, or projecting light from image source 412 to combiner 415. The one or more optical components may include, for example, one or more lenses, liquid lenses, mirrors, apertures, and/or gratings. For example, in some embodiments, image source 412 may include one or more one-dimensional arrays or elongated two-dimensional arrays of micro-LEDs, and projector optics 414 may include one or more one-dimensional scanners (e.g., micro-mirrors or prisms) configured to scan the one-dimensional arrays or elongated two-dimensional arrays of micro-LEDs to generate image frames. In some embodiments, projector optics 414 may include a liquid lens (e.g., a liquid crystal lens) with a plurality of electrodes that allows scanning of the light from image source 412.

Combiner 415 may include an input coupler 430 for coupling light from projector 410 into a substrate 420 of combiner 415. Combiner 415 may transmit at least 50% of light in a first wavelength range and reflect at least 25% of light in a second wavelength range. For example, the first wavelength range may be visible light from about 400 nm to about 650 nm, and the second wavelength range may be in the infrared band, for example, from about 800 nm to about 1000 nm. Input coupler 430 may include a volume holographic grating, a diffractive optical element (DOE) (e.g., a surface-relief grating), a slanted surface of substrate 420, or a refractive coupler (e.g., a wedge or a prism). For example, input coupler 430 may include a reflective volume Bragg grating or a transmissive volume Bragg grating. Input coupler 430 may have a coupling efficiency of greater than 30%, 50%, 75%, 90%, or higher for visible light. Light coupled into substrate 420 may propagate within substrate 420 through, for example, total internal reflection (TIR). Substrate 420 may be in the form of a lens of a pair of eyeglasses. Substrate 420 may have a flat or a curved surface, and may include one or more types of dielectric materials, such as glass, quartz, plastic, polymer, poly(methyl methacrylate) (PMMA), crystal, or ceramic. A thickness of the substrate may range from, for example, less than about 1 mm to about 10 mm or more. Substrate 420 may be transparent to visible light.

Substrate 420 may include or may be coupled to a plurality of output couplers 440, each configured to extract at least a portion of the light guided by and propagating within substrate 420 from substrate 420, and direct extracted light 460 to an eyebox 495 where an eye 490 of the user of augmented reality system 400 may be located when augmented reality system 400 is in use. The plurality of output couplers 440 may replicate the exit pupil to increase the size of eyebox 495 such that the displayed image is visible in a larger area. As input coupler 430, output couplers 440 may include grating couplers (e.g., volume holographic gratings or surface-relief gratings), other diffraction optical elements (DOEs), prisms, etc. For example, output couplers 440 may include reflective volume Bragg gratings or transmissive volume Bragg gratings. Output couplers 440 may have different coupling (e.g., diffraction) efficiencies at different locations. Substrate 420 may also allow light 450 from the environment in front of combiner 415 to pass through with little or no loss. Output couplers 440 may also allow light 450 to pass through with little loss. For example, in some implementations, output couplers 440 may have a very low diffraction efficiency for light 450 such that light 450 may be refracted or otherwise pass through output couplers 440 with little loss, and thus may have a higher intensity than extracted light 460. In some implementations, output couplers 440 may have a high diffraction efficiency for light 450 and may diffract light 450 in certain desired directions (i.e., diffraction angles) with little loss. As a result, the user may be able to view combined images of the environment in front of combiner 415 and images of virtual objects projected by projector 410.

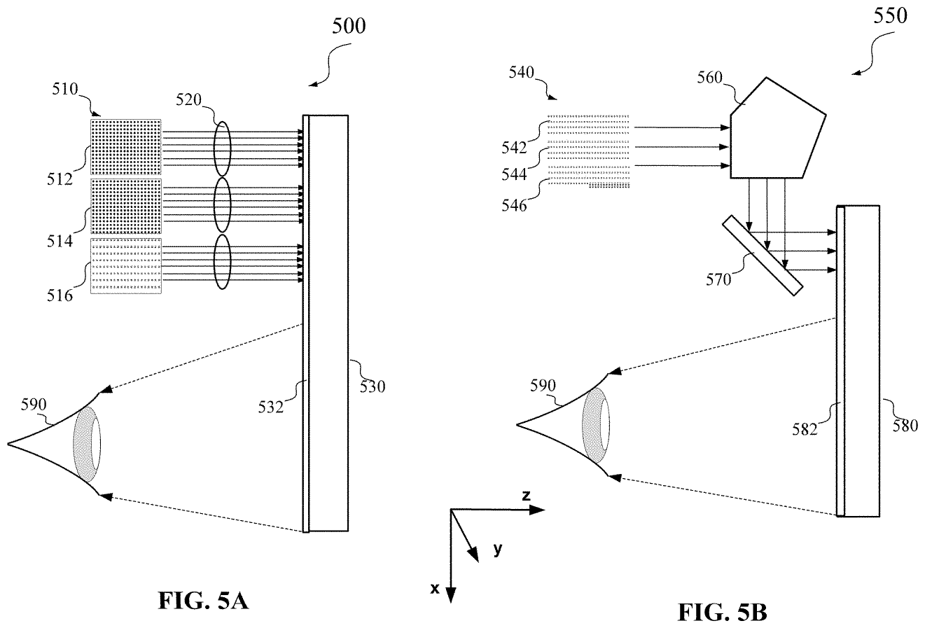

FIG. 5A illustrates an example of a near-eye display (NED) device 500 including a waveguide display 530 according to certain embodiments. NED device 500 may be an example of near-eye display 120, augmented reality system 400, or another type of display device. NED device 500 may include a light source 510, projection optics 520, and waveguide display 530. Light source 510 may include multiple panels of light emitters for different colors, such as a panel of red light emitters 512, a panel of green light emitters 514, and a panel of blue light emitters 516. The red light emitters 512 are organized into an array; the green light emitters 514 are organized into an array; and the blue light emitters 516 are organized into an array. The dimensions and pitches of light emitters in light source 510 may be small. For example, each light emitter may have a diameter less than 2 μm (e.g., about 1.2 μm) and the pitch may be less than 2 μm (e.g., about 1.5 μm). As such, the number of light emitters in each red light emitters 512, green light emitters 514, and blue light emitters 516 can be equal to or greater than the number of pixels in a display image, such as 960×720, 1280×720, 1440×1080, 1920×1080, 2160×1080, or 2560×1080 pixels. Thus, a display image may be generated simultaneously by light source 510. A scanning element may not be used in NED device 500.

Before reaching waveguide display 530, the light emitted by light source 510 may be conditioned by projection optics 520, which may include a lens array. Projection optics 520 may collimate or focus the light emitted by light source 510 to waveguide display 530, which may include a coupler 532 for coupling the light emitted by light source 510 into waveguide display 530. The light coupled into waveguide display 530 may propagate within waveguide display 530 through, for example, total internal reflection as described above with respect to FIG. 4. Coupler 532 may also couple portions of the light propagating within waveguide display 530 out of waveguide display 530 and towards user's eye 590.

FIG. 5B illustrates an example of a near-eye display (NED) device 550 including a waveguide display 580 according to certain embodiments. In some embodiments, NED device 550 may use a scanning mirror 570 to project light from a light source 540 to an image field where a user's eye 590 may be located. NED device 550 may be an example of near-eye display 120, augmented reality system 400, or another type of display device. Light source 540 may include one or more rows or one or more columns of light emitters of different colors, such as multiple rows of red light emitters 542, multiple rows of green light emitters 544, and multiple rows of blue light emitters 546. For example, red light emitters 542, green light emitters 544, and blue light emitters 546 may each include N rows, each row including, for example, 2560 light emitters (pixels). The red light emitters 542 are organized into an array; the green light emitters 544 are organized into an array; and the blue light emitters 546 are organized into an array. In some embodiments, light source 540 may include a single line of light emitters for each color. In some embodiments, light source 540 may include multiple columns of light emitters for each of red, green, and blue colors, where each column may include, for example, 1080 light emitters. In some embodiments, the dimensions and/or pitches of the light emitters in light source 540 may be relatively large (e.g., about 3-5 μm) and thus light source 540 may not include sufficient light emitters for simultaneously generating a full display image. For example, the number of light emitters for a single color may be fewer than the number of pixels (e.g., 2560×1080 pixels) in a display image. The light emitted by light source 540 may be a set of collimated or diverging beams of light.

Before reaching scanning mirror 570, the light emitted by light source 540 may be conditioned by various optical devices, such as collimating lenses or a freeform optical element 560. Freeform optical element 560 may include, for example, a multi-facet prism or another light folding element that may direct the light emitted by light source 540 towards scanning mirror 570, such as changing the propagation direction of the light emitted by light source 540 by, for example, about 90° or larger. In some embodiments, freeform optical element 560 may be rotatable to scan the light. Scanning mirror 570 and/or freeform optical element 560 may reflect and project the light emitted by light source 540 to waveguide display 580, which may include a coupler 582 for coupling the light emitted by light source 540 into waveguide display 580. The light coupled into waveguide display 580 may propagate within waveguide display 580 through, for example, total internal reflection as described above with respect to FIG. 4. Coupler 582 may also couple portions of the light propagating within waveguide display 580 out of waveguide display 580 and towards user's eye 590.

Scanning mirror 570 may include a microelectromechanical system (MEMS) mirror or any other suitable mirrors. Scanning mirror 570 may rotate to scan in one or two dimensions. As scanning mirror 570 rotates, the light emitted by light source 540 may be directed to a different area of waveguide display 580 such that a full display image may be projected onto waveguide display 580 and directed to user's eye 590 by waveguide display 580 in each scanning cycle. For example, in embodiments where light source 540 includes light emitters for all pixels in one or more rows or columns, scanning mirror 570 may be rotated in the column or row direction (e.g., x or y direction) to scan an image. In embodiments where light source 540 includes light emitters for some but not all pixels in one or more rows or columns, scanning mirror 570 may be rotated in both the row and column directions (e.g., both x and y directions) to project a display image (e.g., using a raster-type scanning pattern).

NED device 550 may operate in predefined display periods. A display period (e.g., display cycle) may refer to a duration of time in which a full image is scanned or projected. For example, a display period may be a reciprocal of the desired frame rate. In NED device 550 that includes scanning mirror 570, the display period may also be referred to as a scanning period or scanning cycle. The light generation by light source 540 may be synchronized with the rotation of scanning mirror 570. For example, each scanning cycle may include multiple scanning steps, where light source 540 may generate a different light pattern in each respective scanning step.

In each scanning cycle, as scanning mirror 570 rotates, a display image may be projected onto waveguide display 580 and user's eye 590. The actual color value and light intensity (e.g., brightness) of a given pixel location of the display image may be an average of the light beams of the three colors (e.g., red, green, and blue) illuminating the pixel location during the scanning period. After completing a scanning period, scanning mirror 570 may revert back to the initial position to project light for the first few rows of the next display image or may rotate in a reverse direction or scan pattern to project light for the next display image, where a new set of driving signals may be fed to light source 540. The same process may be repeated as scanning mirror 570 rotates in each scanning cycle. As such, different images may be projected to user's eye 590 in different scanning cycles.

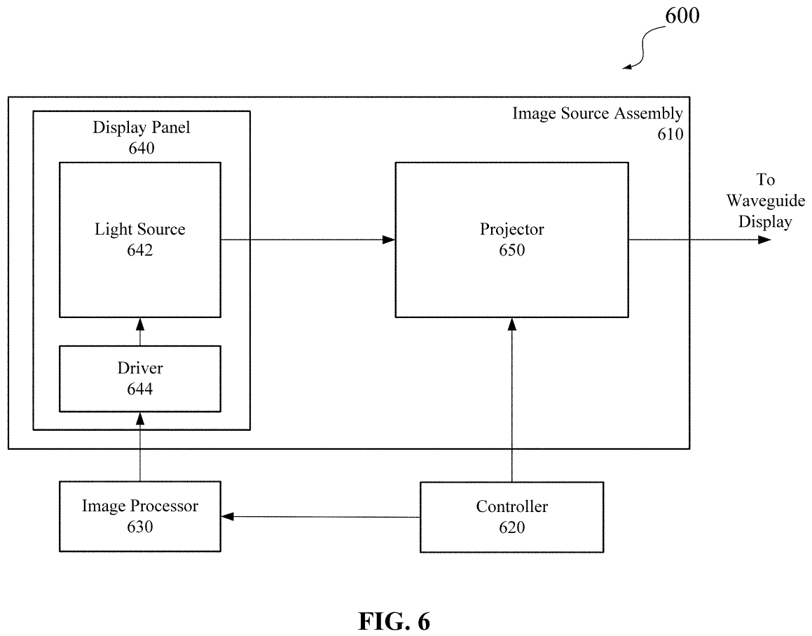

FIG. 6 illustrates an example of an image source assembly 610 in a near-eye display system 600 according to certain embodiments. Image source assembly 610 may include, for example, a display panel 640 that may generate display images to be projected to the user's eyes, and a projector 650 that may project the display images generated by display panel 640 to a waveguide display as described above with respect to FIGS. 4-5B. Display panel 640 may include a light source 642 and a driver circuit 644 for light source 642. Light source 642 may include, for example, light source 510 or 540. Projector 650 may include, for example, freeform optical element 560, scanning mirror 570, and/or projection optics 520 described above. Near-eye display system 600 may also include a controller 620 that synchronously controls light source 642 and projector 650 (e.g., scanning mirror 570). Image source assembly 610 may generate and output an image light to a waveguide display (not shown in FIG. 6), such as waveguide display 530 or 580. As described above, the waveguide display may receive the image light at one or more input-coupling elements, and guide the received image light to one or more output-coupling elements. The input and output coupling elements may include, for example, a diffraction grating, a holographic grating, a prism, or any combination thereof. The input-coupling element may be chosen such that total internal reflection occurs with the waveguide display. The output-coupling element may couple portions of the total internally reflected image light out of the waveguide display.

As described above, light source 642 may include a plurality of light emitters arranged in an array or a matrix. Each light emitter may emit monochromatic light, such as red light, blue light, green light, infra-red light, and the like. While RGB colors are often discussed in this disclosure, embodiments described herein are not limited to using red, green, and blue as primary colors. Other colors can also be used as the primary colors of near-eye display system 600. In some embodiments, a display panel in accordance with an embodiment may use more than three primary colors. Each pixel in light source 642 may include three subpixels that include a red micro-LED, a green micro-LED, and a blue micro-LED. A semiconductor LED generally includes an active light emitting layer within multiple layers of semiconductor materials. The multiple layers of semiconductor materials may include different compound materials or a same base material with different dopants and/or different doping densities. For example, the multiple layers of semiconductor materials may include an n-type material layer, an active region that may include hetero-structures (e.g., one or more quantum wells), and a p-type material layer. The multiple layers of semiconductor materials may be grown on a surface of a substrate having a certain orientation. In some embodiments, to increase light extraction efficiency, a mesa that includes at least some of the layers of semiconductor materials may be formed.

Controller 620 may control the image rendering operations of image source assembly 610, such as the operations of light source 642 and/or projector 650. For example, controller 620 may determine instructions for image source assembly 610 to render one or more display images. The instructions may include display instructions and scanning instructions. In some embodiments, the display instructions may include an image file (e.g., a bitmap file). The display instructions may be received from, for example, a console, such as console 110 described above with respect to FIG. 1. The scanning instructions may be used by image source assembly 610 to generate image light. The scanning instructions may specify, for example, a type of a source of image light (e.g., monochromatic or polychromatic), a scanning rate, an orientation of a scanning apparatus, one or more illumination parameters, or any combination thereof. Controller 620 may include a combination of hardware, software, and/or firmware not shown here so as not to obscure other aspects of the present disclosure.

In some embodiments, controller 620 may be a graphics processing unit (GPU) of a display device. In other embodiments, controller 620 may be other kinds of processors. The operations performed by controller 620 may include taking content for display and dividing the content into discrete sections. Controller 620 may provide to light source 642 scanning instructions that include an address corresponding to an individual source element of light source 642 and/or an electrical bias applied to the individual source element. Controller 620 may instruct light source 642 to sequentially present the discrete sections using light emitters corresponding to one or more rows of pixels in an image ultimately displayed to the user. Controller 620 may also instruct projector 650 to perform different adjustments of the light. For example, controller 620 may control projector 650 to scan the discrete sections to different areas of a coupling element of the waveguide display (e.g., waveguide display 580) as described above with respect to FIG. 5B. As such, at the exit pupil of the waveguide display, each discrete portion is presented in a different respective location. While each discrete section is presented at a different respective time, the presentation and scanning of the discrete sections occur fast enough such that a user's eye may integrate the different sections into a single image or series of images.

Image processor 630 may be a general-purpose processor and/or one or more application-specific circuits that are dedicated to performing the features described herein. In one embodiment, a general-purpose processor may be coupled to a memory to execute software instructions that cause the processor to perform certain processes described herein. In another embodiment, image processor 630 may be one or more circuits that are dedicated to performing certain features. While image processor 630 in FIG. 6 is shown as a stand-alone unit that is separate from controller 620 and driver circuit 644, image processor 630 may be a sub-unit of controller 620 or driver circuit 644 in other embodiments. In other words, in those embodiments, controller 620 or driver circuit 644 may perform various image processing functions of image processor 630. Image processor 630 may also be referred to as an image processing circuit.

In the example shown in FIG. 6, light source 642 may be driven by driver circuit 644, based on data or instructions (e.g., display and scanning instructions) sent from controller 620 or image processor 630. In one embodiment, driver circuit 644 may include a circuit panel that connects to and mechanically holds various light emitters of light source 642. Light source 642 may emit light in accordance with one or more illumination parameters that are set by the controller 620 and potentially adjusted by image processor 630 and driver circuit 644. An illumination parameter may be used by light source 642 to generate light. An illumination parameter may include, for example, source wavelength, pulse rate, pulse amplitude, beam type (continuous or pulsed), other parameter(s) that may affect the emitted light, or any combination thereof. In some embodiments, the source light generated by light source 642 may include multiple beams of red light, green light, and blue light, or any combination thereof.

Projector 650 may perform a set of optical functions, such as focusing, combining, conditioning, or scanning the image light generated by light source 642. In some embodiments, projector 650 may include a combining assembly, a light conditioning assembly, or a scanning mirror assembly. Projector 650 may include one or more optical components that optically adjust and potentially re-direct the light from light source 642. One example of the adjustment of light may include conditioning the light, such as expanding, collimating, correcting for one or more optical errors (e.g., field curvature, chromatic aberration, etc.), some other adjustments of the light, or any combination thereof. The optical components of projector 650 may include, for example, lenses, mirrors, apertures, gratings, or any combination thereof.

Projector 650 may redirect image light via its one or more reflective and/or refractive portions so that the image light is projected at certain orientations toward the waveguide display. The location where the image light is redirected toward the waveguide display may depend on specific orientations of the one or more reflective and/or refractive portions. In some embodiments, projector 650 includes a single scanning mirror that scans in at least two dimensions. In other embodiments, projector 650 may include a plurality of scanning mirrors that each scan in directions orthogonal to each other. Projector 650 may perform a raster scan (horizontally or vertically), a bi-resonant scan, or any combination thereof. In some embodiments, projector 650 may perform a controlled vibration along the horizontal and/or vertical directions with a specific frequency of oscillation to scan along two dimensions and generate a two-dimensional projected image of the media presented to user's eyes. In other embodiments, projector 650 may include a lens or prism that may serve similar or the same function as one or more scanning mirrors. In some embodiments, image source assembly 610 may not include a projector, where the light emitted by light source 642 may be directly incident on the waveguide display.

The overall efficiency of a photonic integrated circuit or a waveguide-based display (e.g., in augmented reality system 400 or NED device 500 or 550) may be a product of the efficiency of individual components and may also depend on how the components are connected. For example, the overall efficiency nₜₒₜ of the waveguide-based display in augmented reality system 400 may depend on the light emitting efficiency of image source 412, the light coupling efficiency from image source 412 into combiner 415 by projector optics 414 and input coupler 430, and the output coupling efficiency of output coupler 440, and thus may be determined as:

ηₜₒₜ=η_{EQE}×ηᵢₙ×ηₒᵤₜ, (1)

where η_{EQE} is the external quantum efficiency of image source 412, ηᵢₙ is the in-coupling efficiency of light from image source 412 into the waveguide (e.g., substrate 420), and ηₒᵤₜ is the outcoupling efficiency of light from the waveguide towards the user's eye by output coupler 440. Thus, the overall efficiency ηₜₒₜ of the waveguide-based display can be improved by improving one or more of η_{EQE}, ηᵢₙ, and ηₒᵤₜ.

The optical coupler (e.g., input coupler 430 or coupler 532) that couples the emitted light from a light source to a waveguide may include, for example, a grating, a lens, a micro-lens, a prism. In some embodiments, light from a small light source (e.g., a micro-LED) can be directly (e.g., end-to-end) coupled from the light source to a waveguide, without using an optical coupler. In some embodiments, the optical coupler (e.g., a lens or a parabolic-shaped reflector) may be manufactured on the light source.

The light sources, image sources, or other displays described above may include one or more LEDs. For example, each pixel in a display may include three subpixels that include a red micro-LED, a green micro-LED, and a blue micro-LED. A semiconductor light emitting diode generally includes an active light emitting layer within multiple layers of semiconductor materials. The multiple layers of semiconductor materials may include different compound materials or a same base material with different dopants and/or different doping densities. For example, the multiple layers of semiconductor materials may generally include an n-type material layer, an active layer that may include hetero-structures (e.g., one or more quantum wells), and a p-type material layer. The multiple layers of semiconductor materials may be grown on a surface of a substrate having a certain orientation.

Photons can be generated in a semiconductor LED (e.g., a micro-LED) at a certain internal quantum efficiency through the recombination of electrons and holes within the active layer (e.g., including one or more semiconductor layers). The generated light may then be extracted from the LEDs in a particular direction or within a particular solid angle. The ratio between the number of emitted photons extracted from the LED and the number of electrons passing through the LED is referred to as the external quantum efficiency, which describes how efficiently the LED converts injected electrons to photons that are extracted from the device. The external quantum efficiency may be proportional to the injection efficiency, the internal quantum efficiency, and the extraction efficiency. The injection efficiency refers to the proportion of electrons passing through the device that are injected into the active region. The extraction efficiency is the proportion of photons generated in the active region that escape from the device. For LEDs, and in particular, micro-LEDs with reduced physical dimensions, improving the internal and external quantum efficiency can be challenging. In some embodiments, to increase the light extraction efficiency, a mesa that includes at least some of the layers of semiconductor materials may be formed.

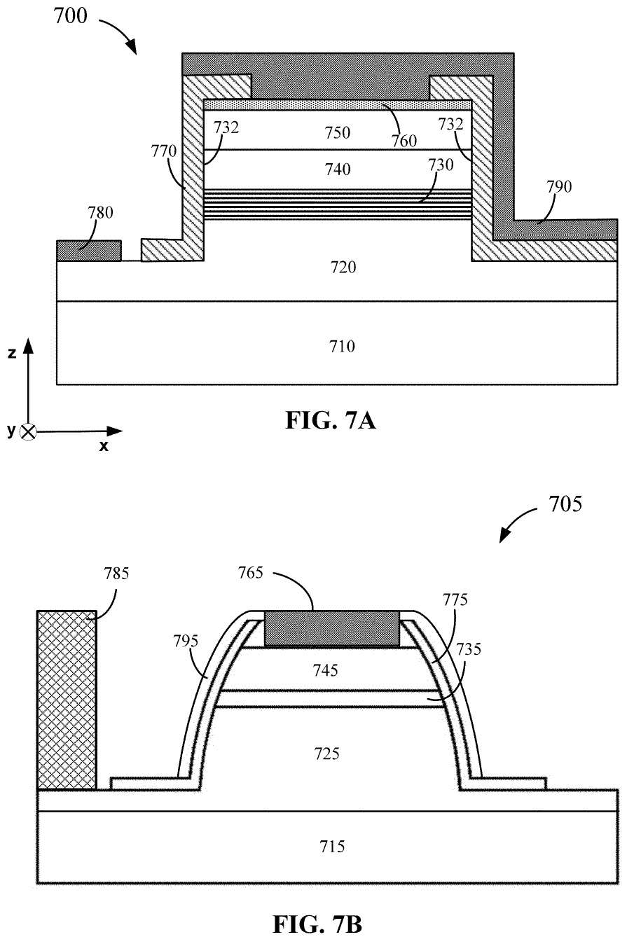

FIG. 7A illustrates an example of an LED 700 having a vertical mesa structure. LED 700 may be a light emitter in light source 510, 540, or 642. LED 700 may be a micro-LED made of inorganic materials, such as multiple layers of semiconductor materials. The layered semiconductor light emitting device may include multiple layers of III-V semiconductor materials. A III-V semiconductor material may include one or more Group III elements, such as aluminum (Al), gallium (Ga), or indium (In), in combination with a Group V element, such as nitrogen (N), phosphorus (P), arsenic (As), or antimony (Sb). When the Group V element of the III-V semiconductor material includes nitrogen, the III-V semiconductor material is referred to as a III-nitride material. The layered semiconductor light emitting device may be manufactured by growing multiple epitaxial layers on a substrate using techniques such as vapor-phase epitaxy (VPE), liquid-phase epitaxy (LPE), molecular beam epitaxy (MBE), or metalorganic chemical vapor deposition (MOCVD). For example, the layers of the semiconductor materials may be grown layer-by-layer on a substrate with a certain crystal lattice orientation (e.g., polar, nonpolar, or semi-polar orientation), such as a GaN, GaAs, or GaP substrate, or a substrate including, but not limited to, sapphire, silicon carbide, silicon, zinc oxide, boron nitride, lithium aluminate, lithium niobate, germanium, aluminum nitride, lithium gallate, partially substituted spinels, or quaternary tetragonal oxides sharing the beta-LiAlO₂ structure, where the substrate may be cut in a specific direction to expose a specific plane as the growth surface.

In the example shown in FIG. 7A, LED 700 may include a substrate 710, which may include, for example, a sapphire substrate or a GaN substrate. A semiconductor layer 720 may be grown on substrate 710. Semiconductor layer 720 may include a III-V material, such as GaN, and may be p-doped (e.g., with Mg, Ca, Zn, or Be) or n-doped (e.g., with Si or Ge). One or more active layers 730 may be grown on semiconductor layer 720 to form an active region. Active layer 730 may include III-V materials, such as one or more InGaN layers, one or more AlGaInP layers, and/or one or more GaN layers, which may form one or more heterostructures, such as one or more quantum wells or MQWs. A semiconductor layer 740 may be grown on active layer 730. Semiconductor layer 740 may include a III-V material, such as GaN, and may be p-doped (e.g., with Mg, Ca, Zn, or Be) or n-doped (e.g., with Si or Ge). One of semiconductor layer 720 and semiconductor layer 740 may be a p-type layer and the other one may be an n-type layer. Semiconductor layer 720 and semiconductor layer 740 sandwich active layer 730 to form the light emitting region. For example, LED 700 may include a layer of InGaN situated between a layer of p-type GaN doped with magnesium and a layer of n-type GaN doped with silicon or oxygen. In some embodiments, LED 700 may include a layer of AlGaInP situated between a layer of p-type AlGaInP doped with zinc or magnesium and a layer of n-type AlGaInP doped with selenium, silicon, or tellurium.

In some embodiments, an electron-blocking layer (EBL) (not shown in FIG. 7A) may be grown to form a layer between active layer 730 and at least one of semiconductor layer 720 or semiconductor layer 740. The EBL may reduce the electron leakage current and improve the efficiency of the LED. In some embodiments, a heavily-doped semiconductor layer 750, such as a P⁺ or P⁺⁺ semiconductor layer, may be formed on semiconductor layer 740 and act as a contact layer for forming an ohmic contact and reducing the contact impedance of the device. In some embodiments, a conductive layer 760 may be formed on heavily-doped semiconductor layer 750. Conductive layer 760 may include, for example, an indium tin oxide (ITO) or Al/Ni/Au film. In one example, conductive layer 760 may include a transparent ITO layer.

To make contact with semiconductor layer 720 (e.g., an n-GaN layer) and to more efficiently extract light emitted by active layer 730 from LED 700, the semiconductor material layers (including heavily-doped semiconductor layer 750, semiconductor layer 740, active layer 730, and semiconductor layer 720) may be etched to expose semiconductor layer 720 and to form a mesa structure that includes layers 720-760. The mesa structure may confine the carriers within the device. Etching the mesa structure may lead to the formation of mesa sidewalls 732 that may be orthogonal to the growth planes. A passivation layer 770 may be formed on mesa sidewalls 732 of the mesa structure. Passivation layer 770 may include an oxide layer, such as a SiO₂ layer, and may act as a reflector to reflect emitted light out of LED 700. A contact layer 780, which may include a metal layer, such as Al, Au, Ni, Ti, or any combination thereof, may be formed on semiconductor layer 720 and may act as an electrode of LED 700. In addition, another contact layer 790, such as an Al/Ni/Au metal layer, may be formed on conductive layer 760 and may act as another electrode of LED 700.

When a voltage signal is applied to contact layers 780 and 790, electrons and holes may recombine in active layer 730, where the recombination of electrons and holes may cause photon emission. The wavelength and energy of the emitted photons may depend on the energy bandgap between the valence band and the conduction band in active layer 730. For example, InGaN active layers may emit green or blue light, AlGaN active layers may emit blue to ultraviolet light, while AlGaInP active layers may emit red, orange, yellow, or green light. The emitted photons may be reflected by passivation layer 770 and may exit LED 700 from the top (e.g., conductive layer 760 and contact layer 790) or bottom (e.g., substrate 710).

In some embodiments, LED 700 may include one or more other components, such as a lens, on the light emission surface, such as substrate 710, to focus or collimate the emitted light or couple the emitted light into a waveguide. In some embodiments, an LED may include a mesa of another shape, such as planar, conical, semi-parabolic, or parabolic, and a base area of the mesa may be circular, rectangular, hexagonal, or triangular. For example, the LED may include a mesa of a curved shape (e.g., paraboloid shape) and/or a non-curved shape (e.g., conic shape). The mesa may be truncated or non-truncated.

FIG. 7B is a cross-sectional view of an example of an LED 705 having a parabolic mesa structure. Similar to LED 700, LED 705 may include multiple layers of semiconductor materials, such as multiple layers of III-V semiconductor materials. The semiconductor material layers may be epitaxially grown on a substrate 715, such as a GaN substrate or a sapphire substrate. For example, a semiconductor layer 725 may be grown on substrate 715.

Semiconductor layer 725 may include a III-V material, such as GaN, and may be p-doped (e.g., with Mg, Ca, Zn, or Be) or n-doped (e.g., with Si or Ge). One or more active layer 735 may be grown on semiconductor layer 725. Active layer 735 may include III-V materials, such as one or more InGaN layers, one or more AlGaInP layers, and/or one or more GaN layers, which may form one or more heterostructures, such as one or more quantum wells. A semiconductor layer 745 may be grown on active layer 735. Semiconductor layer 745 may include a III-V material, such as GaN, and may be p-doped (e.g., with Mg, Ca, Zn, or Be) or n-doped (e.g., with Si or Ge). One of semiconductor layer 725 and semiconductor layer 745 may be a p-type layer and the other one may be an n-type layer.

To make contact with semiconductor layer 725 (e.g., an n-type GaN layer) and to more efficiently extract light emitted by active layer 735 from LED 705, the semiconductor layers may be etched to expose semiconductor layer 725 and to form a mesa structure that includes layers 725-745. The mesa structure may confine carriers within the injection area of the device. Etching the mesa structure may lead to the formation of mesa side walls (also referred to herein as facets) that may be non-parallel with, or in some cases, orthogonal, to the growth planes associated with crystalline growth of layers 725-745.

As shown in FIG. 7B, LED 705 may have a mesa structure that includes a flat top. A dielectric layer 775 (e.g., SiO₂ or SiN) may be formed on the facets of the mesa structure. In some embodiments, dielectric layer 775 may include multiple layers of dielectric materials. In some embodiments, a metal layer 795 may be formed on dielectric layer 775. Metal layer 795 may include one or more metal or metal alloy materials, such as aluminum (Al), silver (Ag), gold (Au), platinum (Pt), titanium (Ti), copper (Cu), or any combination thereof. Dielectric layer 775 and metal layer 795 may form a mesa reflector that can reflect light emitted by active layer 735 toward substrate 715. In some embodiments, the mesa reflector may be parabolic-shaped to act as a parabolic reflector that may at least partially collimate the emitted light.

Electrical contact 765 and electrical contact 785 may be formed on semiconductor layer 745 and semiconductor layer 725, respectively, to act as electrodes. Electrical contact 765 and electrical contact 785 may each include a conductive material, such as Al, Au, Pt, Ag, Ni, Ti, Cu, or any combination thereof (e.g., Ag/Pt/Au or Al/Ni/Au), and may act as the electrodes of LED 705. In the example shown in FIG. 7B, electrical contact 785 may be an n-contact, and electrical contact 765 may be a p-contact. Electrical contact 765 and semiconductor layer 745 (e.g., a p-type semiconductor layer) may form a back reflector for reflecting light emitted by active layer 735 back toward substrate 715. In some embodiments, electrical contact 765 and metal layer 795 include same material(s) and can be formed using the same processes. In some embodiments, an additional conductive layer (not shown) may be included as an intermediate conductive layer between the electrical contacts 765 and 785 and the semiconductor layers.

When a voltage signal is applied across electrical contacts 765 and 785, electrons and holes may recombine in active layer 735. The recombination of electrons and holes may cause photon emission, thus producing light. The wavelength and energy of the emitted photons may depend on the energy bandgap between the valence band and the conduction band in active layer 735. For example, InGaN active layers may emit green or blue light, while AlGaInP active layers may emit red, orange, yellow, or green light. The emitted photons may propagate in many different directions, and may be reflected by the mesa reflector and/or the back reflector and may exit LED 705, for example, from the bottom side (e.g., substrate 715) shown in FIG. 7B. One or more other secondary optical components, such as a lens or a grating, may be formed on the light emission surface, such as substrate 715, to focus or collimate the emitted light and/or couple the emitted light into a waveguide.

When the mesa structure is formed (e.g., etched), the facets of the mesa structure, such as mesa sidewalls 732, may include some imperfections, such as unsatisfied bonds, chemical contamination, and structural damages (e.g., when dry-etched), that may decrease the internal quantum efficiency of the LED. For example, at the facets, the atomic lattice structure of the semiconductor layers may come to an abrupt end, where some atoms of the semiconductor materials may lack neighbors to which bonds may be attached. This results in “dangling bonds,” which may be characterized by unpaired valence electrons. These dangling bonds create energy levels that otherwise would not exist within the bandgap of the semiconductor material, causing non-radiative electron-hole recombination at or near the facets of the mesa structure. Thus, these imperfections may become the recombination centers where electrons and holes may be confined until they combine non-radiatively.

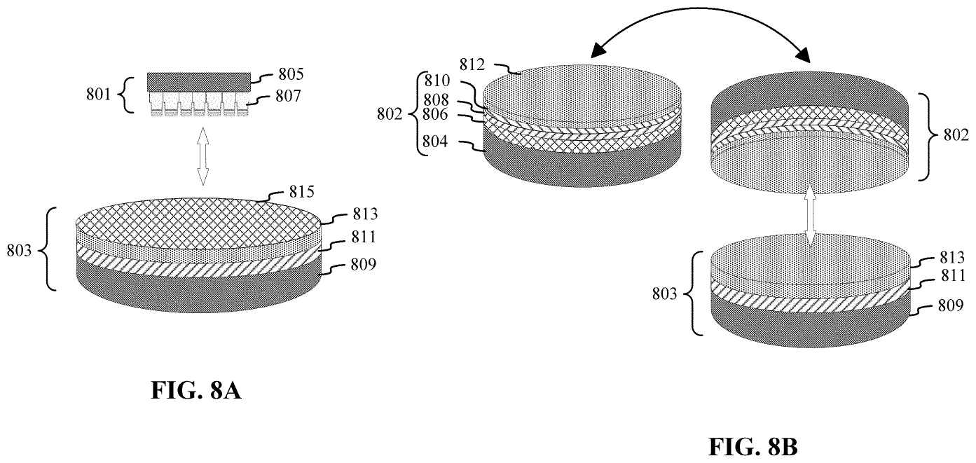

FIG. 8A illustrates an example of a method of die-to-wafer bonding for arrays of LEDs according to certain embodiments. In the example shown in FIG. 8A, an LED array 801 may include a plurality of LEDs 807 (including a bonding layer formed thereon) on a carrier substrate 805. Carrier substrate 805 may include various materials, such as GaAs, InP, GaN, AlN, sapphire, SiC, Si, or the like. LEDs 807 may be fabricated by, for example, growing various epitaxial layers, forming mesa structures, and forming electrical contacts or electrodes, before performing the bonding. The epitaxial layers may include various materials, such as GaN, InGaN, (AlGaIn)P, (AlGaIn)AsP, (AlGaIn)AsN, (Eu:InGa)N, (AlGaIn)N, or the like, and may include an n-type layer, a p-type layer, and an active layer that includes one or more heterostructures, such as one or more quantum wells or MQWs. The electrical contacts may include various conductive materials, such as a metal or a metal alloy.

A wafer 803 may include a base layer 809 having passive or active integrated circuits (e.g., driver circuits 811) fabricated thereon. Base layer 809 may include, for example, a silicon wafer. Driver circuits 811 may be used to control the operations of LEDs 807. For example, the driver circuit for each LED 807 may include a 2T1C pixel structure that has two transistors and one capacitor. Wafer 803 may also include a bonding layer 813. Bonding layer 813 may include various materials, such as a metal, an oxide, a dielectric, CuSn, AuTi, and the like. In some embodiments, a patterned layer 815 may be formed on a surface of bonding layer 813, where patterned layer 815 may include a metallic grid made of a conductive material, such as Cu, Ag, Au, Al, or the like.

LED array 801 may be bonded to wafer 803 via bonding layer 813 or patterned layer 815. For example, patterned layer 815 may include metal pads or bumps made of various materials, such as CuSn, AuSn, or nanoporous Au, that may be used to align LEDs 807 of LED array 801 with corresponding driver circuits 811 on wafer 803. In one example, LED array 801 may be brought toward wafer 803 until LEDs 807 come into contact with respective metal pads or bumps corresponding to driver circuits 811. Some or all of LEDs 807 may be aligned with driver circuits 811, and may then be bonded to wafer 803 via patterned layer 815 by various bonding techniques, such as metal-to-metal bonding. After LEDs 807 have been bonded to wafer 803, carrier substrate 805 may be removed from LEDs 807.

FIG. 8B illustrates an example of a method of wafer-to-wafer bonding for arrays of LEDs according to certain embodiments. As shown in FIG. 8B, a first wafer 802 may include a substrate 804, a first semiconductor layer 806, active layers 808, and a second semiconductor layer 810. Substrate 804 may include various materials, such as GaAs, InP, GaN, AlN, sapphire, SiC, Si, or the like. First semiconductor layer 806, active layers 808, and second semiconductor layer 810 may include various semiconductor materials, such as GaN, InGaN, (AlGaIn)P, (AlGaIn)AsP, (AlGaIn)AsN, (AlGaIn)Pas, (Eu:InGa)N, (AlGaIn)N, or the like. In some embodiments, first semiconductor layer 806 may be an n-type layer, and second semiconductor layer 810 may be a p-type layer. For example, first semiconductor layer 806 may be an n-doped GaN layer (e.g., doped with Si or Ge), and second semiconductor layer 810 may be a p-doped GaN layer (e.g., doped with Mg, Ca, Zn, or Be). Active layers 808 may include, for example, one or more GaN layers, one or more InGaN layers, one or more AlInGaP layers, and the like, which may form one or more heterostructures, such as one or more quantum wells or MQWs.

In some embodiments, first wafer 802 may also include a bonding layer. Bonding layer 812 may include various materials, such as a metal, an oxide, a dielectric, CuSn, AuTi, or the like. In one example, bonding layer 812 may include p-contacts and/or n-contacts (not shown). In some embodiments, other layers may also be included on first wafer 802, such as a buffer layer between substrate 804 and first semiconductor layer 806. The buffer layer may include various materials, such as polycrystalline GaN or MN. In some embodiments, a contact layer may be between second semiconductor layer 810 and bonding layer 812. The contact layer may include any suitable material for providing an electrical contact to second semiconductor layer 810 and/or first semiconductor layer 806.

First wafer 802 may be bonded to wafer 803 that includes driver circuits 811 and bonding layer 813 as described above, via bonding layer 813 and/or bonding layer 812. Bonding layer 812 and bonding layer 813 may be made of the same material or different materials. Bonding layer 813 and bonding layer 812 may be substantially flat. First wafer 802 may be bonded to wafer 803 by various methods, such as metal-to-metal bonding, eutectic bonding, metal oxide bonding, anodic bonding, thermo-compression bonding, ultraviolet (UV) bonding, and/or fusion bonding.

As shown in FIG. 8B, first wafer 802 may be bonded to wafer 803 with the p-side (e.g., second semiconductor layer 810) of first wafer 802 facing down (i.e., toward wafer 803). After bonding, substrate 804 may be removed from first wafer 802, and first wafer 802 may then be processed from the n-side. The processing may include, for example, the formation of certain mesa shapes for individual LEDs, as well as the formation of optical components corresponding to the individual LEDs.

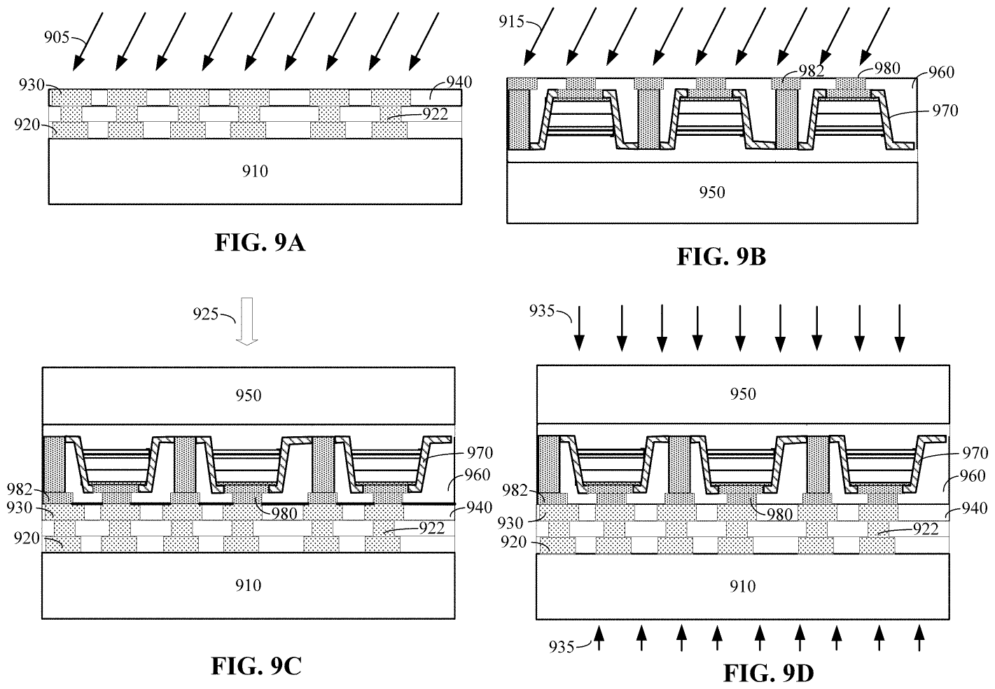

FIGS. 9A-9D illustrate an example of a method of hybrid bonding for arrays of LEDs according to certain embodiments. The hybrid bonding may generally include wafer cleaning and activation, high-precision alignment of contacts of one wafer with contacts of another wafer, dielectric bonding of dielectric materials at the surfaces of the wafers at room temperature, and metal bonding of the contacts by annealing at elevated temperatures. FIG. 9A shows a substrate 910 with passive or active circuits 920 manufactured thereon. As described above with respect to FIGS. 8A-8B, substrate 910 may include, for example, a silicon wafer. Circuits 920 may include driver circuits for the arrays of LEDs. A bonding layer may include dielectric regions 940 and contact pads 930 connected to circuits 920 through electrical interconnects 922. Contact pads 930 may include, for example, Cu, Ag, Au, Al, W, Mo, Ni, Ti, Pt, Pd, or the like. Dielectric materials in dielectric regions 940 may include SiCN, SiO₂, SiN, Al₂O₃, HfO₂, ZrO₂, Ta₂O₅, or the like. The bonding layer may be planarized and polished using, for example, chemical mechanical polishing, where the planarization or polishing may cause dishing (a bowl like profile) in the contact pads. The surfaces of the bonding layers may be cleaned and activated by, for example, an ion (e.g., plasma) or fast atom (e.g., Ar) beam 905. The activated surface may be atomically clean and may be reactive for formation of direct bonds between wafers when they are brought into contact, for example, at room temperature.

FIG. 9B illustrates a wafer 950 including an array of micro-LEDs 970 fabricated thereon as described above. Wafer 950 may be a carrier wafer (or a growth substrate) and may include, for example, GaAs, InP, GaN, AlN, sapphire, SiC, Si, or the like. Micro-LEDs 970 may include an n-type layer, an active region, and a p-type layer epitaxially grown on wafer 950. The epitaxial layers may include various III-V semiconductor materials described above, and may be processed from the p-type layer side to etch mesa structures in the epitaxial layers, such as substantially vertical structures, parabolic structures, conic structures, or the like. Passivation layers and/or reflection layers may be formed on the sidewalls of the mesa structures. P-contacts 980 and n-contacts 982 may be formed in a dielectric material layer 960 deposited on the mesa structures and may make electrical contacts with the p-type layer and the n-type layers, respectively. Dielectric materials in dielectric material layer 960 may include, for example, SiCN, SiO₂, SiN, Al₂O₃, HfO₂, ZrO₂, Ta₂O₅, or the like. P-contacts 980 and n-contacts 982 may include, for example, Cu, Ag, Au, Al, W, Mo, Ni, Ti, Pt, Pd, or the like. The top surfaces of p-contacts 980, n-contacts 982, and dielectric material layer 960 may form a bonding layer. The bonding layer may be planarized and polished using, for example, chemical mechanical polishing, where the polishing may cause dishing in p-contacts 980 and n-contacts 982. The bonding layer may then be cleaned and activated by, for example, an ion (e.g., plasma) or fast atom (e.g., Ar) beam 915. The activated surface may be atomically clean and reactive for formation of direct bonds between wafers when they are brought into contact, for example, at room temperature.

FIG. 9C illustrates a room temperature bonding process for bonding the dielectric materials in the bonding layers. For example, after the bonding layer that includes dielectric regions 940 and contact pads 930 and the bonding layer that includes p-contacts 980, n-contacts 982, and dielectric material layer 960 are surface activated, wafer 950 and micro-LEDs 970 may be turned upside down and brought into contact with substrate 910 and the circuits formed thereon. In some embodiments, compression pressure 925 may be applied to substrate 910 and wafer 950 such that the bonding layers are pressed against each other. Due to the surface activation and the dishing in the contacts, dielectric regions 940 and dielectric material layer 960 may be in direct contact, and may react and form chemical bonds between them because the surface atoms may have dangling bonds and may be in unstable energy states after the activation. Thus, the dielectric materials in dielectric regions 940 and dielectric material layer 960 may be bonded together with or without heat treatment or pressure.

FIG. 9D illustrates an annealing process for bonding the contacts in the bonding layers after bonding the dielectric materials in the bonding layers. For example, contact pads 930 and p-contacts 980 or n-contacts 982 may be bonded together by annealing at, for example, about 90-400° C. or higher. During the annealing process, heat 935 may cause the contacts to expand more than the dielectric materials (due to different coefficients of thermal expansion), and thus may close the dishing gaps between the contacts such that contact pads 930 and p-contacts 980 or n-contacts 982 may be in contact and may form direct metallic bonds at the activated surfaces.

In some embodiments where the two bonded wafers include materials having different coefficients of thermal expansion (CTEs), the dielectric materials bonded at room temperature may help to reduce or prevent misalignment of the contact pads caused by the different thermal expansions. In some embodiments, to further reduce or avoid the misalignment of the contact pads at a high temperature during annealing, trenches may be formed between micro-LEDs, between groups of micro-LEDs, through part or all of the substrate, or the like, before bonding.

After the micro-LEDs are bonded to the driver circuits, the substrate on which the micro-LEDs are fabricated may be thinned or removed, and various secondary optical components may be fabricated on the light emitting surfaces of the micro-LEDs to, for example, extract, collimate, and redirect the light emitted from the active regions of the micro-LEDs. In one example, micro-lenses may be formed on the micro-LEDs, where each micro-lens may correspond to a respective micro-LED and may help to improve the light extraction efficiency and collimate the light emitted by the micro-LED. In some embodiments, the secondary optical components may be fabricated in the substrate or the n-type layer of the micro-LEDs. In some embodiments, the secondary optical components may be fabricated in a dielectric layer deposited on the n-type side of the micro-LEDs. Examples of the secondary optical components may include a lens, a grating, an antireflection (AR) coating, a prism, a photonic crystal, or the like.

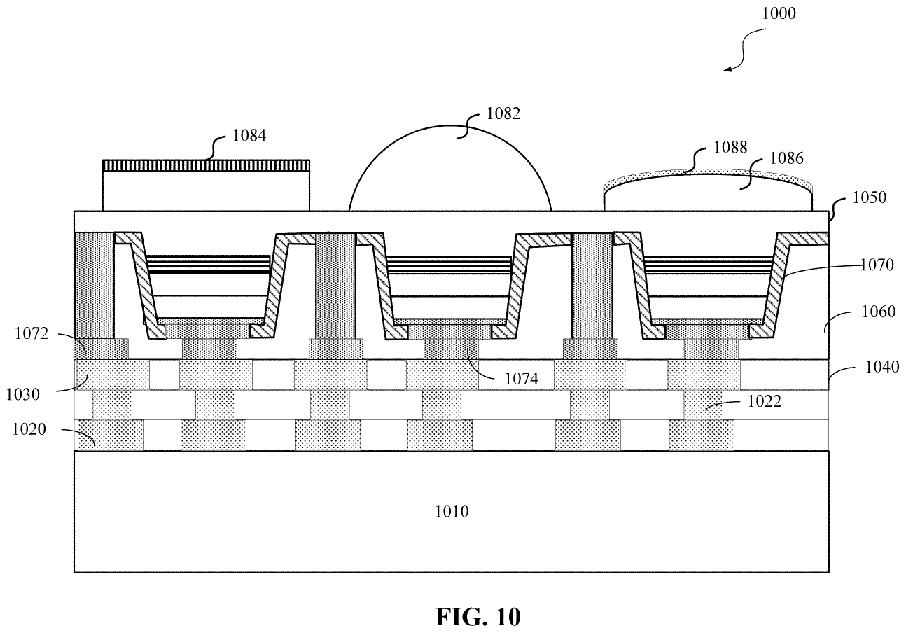

FIG. 10 illustrates an example of an LED array 1000 with secondary optical components fabricated thereon according to certain embodiments. LED array 1000 may be made by bonding an LED chip or wafer with a silicon wafer including electrical circuits fabricated thereon, using any suitable bonding techniques described above with respect to, for example, FIGS. 8A-9D. In the example shown in FIG. 10, LED array 1000 may be bonded using a wafer-to-wafer hybrid bonding technique as described above with respect to FIG. 9A-9D. LED array 1000 may include a substrate 1010, which may be, for example, a silicon wafer. Integrated circuits 1020, such as LED driver circuits, may be fabricated on substrate 1010. Integrated circuits 1020 may be connected to p-contacts 1074 and n-contacts 1072 of micro-LEDs 1070 through interconnects 1022 and contact pads 1030, where contact pads 1030 may form metallic bonds with p-contacts 1074 and n-contacts 1072. Dielectric layer 1040 on substrate 1010 may be bonded to dielectric layer 1060 through fusion bonding.

The substrate (not shown) of the LED chip or wafer may be thinned or may be removed to expose the n-type layer 1050 of micro-LEDs 1070. Various secondary optical components, such as a spherical micro-lens 1082, a grating 1084, a micro-lens 1086, an antireflection layer 1088, and the like, may be formed in or on top of n-type layer 1050. For example, spherical micro-lens arrays may be etched in the semiconductor materials of micro-LEDs 1070 using a gray-scale mask and a photoresist with a linear response to exposure light, or using an etch mask formed by thermal reflowing of a patterned photoresist layer. The secondary optical components may also be etched in a dielectric layer deposited on n-type layer 1050 using similar photolithographic techniques or other techniques. For example, micro-lens arrays may be formed in a polymer layer through thermal reflowing of the polymer layer that is patterned using a binary mask. The micro-lens arrays in the polymer layer may be used as the secondary optical components or may be used as the etch mask for transferring the profiles of the micro-lens arrays into a dielectric layer or a semiconductor layer. The dielectric layer may include, for example, SiCN, SiO₂, SiN, Al₂O₃, HfO₂, ZrO₂, Ta₂O₅, or the like. In some embodiments, a micro-LED 1070 may have multiple corresponding secondary optical components, such as a micro-lens and an anti-reflection coating, a micro-lens etched in the semiconductor material and a micro-lens etched in a dielectric material layer, a micro-lens and a grating, a spherical lens and an aspherical lens, and the like. Three different secondary optical components are illustrated in FIG. 10 to show some examples of secondary optical components that can be formed on micro-LEDs 1070, which does not necessary imply that different secondary optical components are used simultaneously for every LED array.

In the processes described above with respect to, for example, FIGS. 9A-9D, it can be very challenging to precisely align the bonding pads on the micro-LED devices with the bonding pads on the drive circuits, and form reliable bonding at the interfaces that may include both dielectric materials (e.g., SiO₂) and metal (e.g., Cu) bonding pads. For example, when the pitch of the micro-LED device is about 2 or 3 μm or lower, the bonding pads may have a linear dimension less than about 1 μm (e.g., about 0.7 μm), in order to avoid shorting between adjacent micro-LEDs. On the other hand, for small bonding pads, misalignment may reduce the metal-to-metal overlap between the bonding pads, increase the contact resistance (or may even be an open circuit), and/or cause diffusion of metals into the dielectric material and thus may cause current leakage.

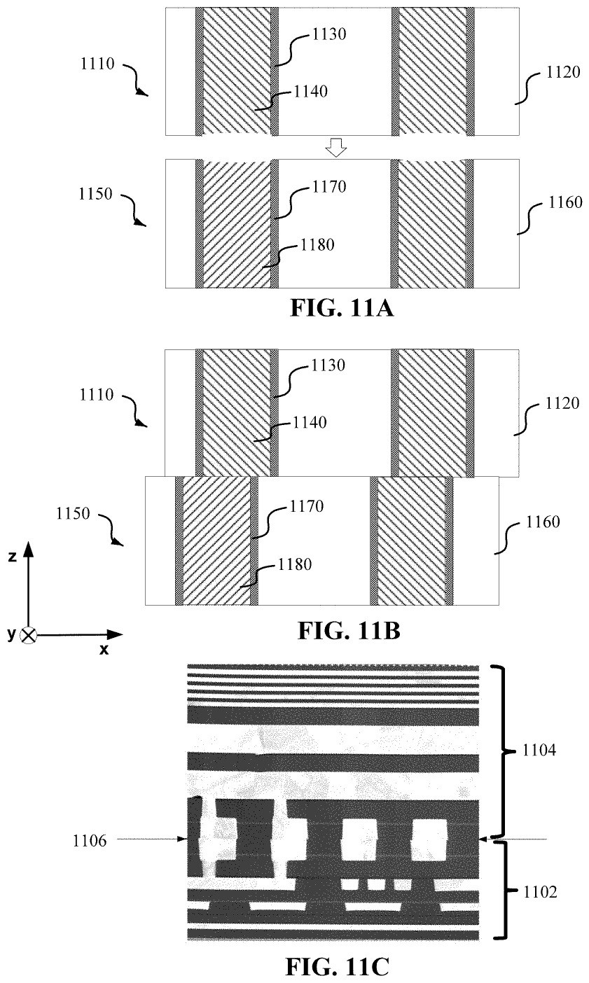

FIG. 11A illustrates an example of hybrid bonding between two wafers or dice. FIG. 11A shows the bonding layers of two wafers or dice, where a first wafer (e.g., a GaAs or sapphire wafer with micro-LEDs fabricated thereon) may include a bonding layer 1110, and a second wafer (e.g., a silicon wafer with drive circuits fabricated thereon) may include a bonding layer 1150. Bonding layer 1110 may include an oxide layer 1120 (e.g., a SiO₂ layer) with bonding pads 1140 (or metal plugs) formed in oxide layer 1120. Bonding layer 1110 may be formed by, for example, depositing oxide layer 1120 on the first wafer, planarizing oxide layer 1120, selectively etching oxide layer 1120 to form trenches in oxide layer 1120, depositing a barrier layer 1130 (e.g., Ti or W) on sidewalls of the trenches, depositing a metal layer (e.g., Cu, Au, or Al) to fill the trenches, removing the metal layer on top of oxide layer 1120, and planarizing the surface of bonding layer 1110 (e.g., using chemical mechanical planarization). Barrier layer 1130 may be used to reduce or prevent the diffusion of the metal material to other regions that may cause leakage. The metal layer remains in the trenches may form bonding pads 1140. Similarly, bonding layer 1150 may be formed by, for example, depositing oxide layer 1160 on the second wafer, planarizing oxide layer 1160, selectively etching oxide layer 1160 to form trenches in oxide layer 1160, depositing a barrier layer 1170 (e.g., Ti or W) on sidewalls of the trenches, depositing a metal (e.g., Cu, Au, or Al) layer to fill the trenches, removing the metal layer on top of oxide layer 1160, and planarizing the surface of bonding layer 1150 (e.g., using chemical mechanical planarization). The metal layer remaining in the trenches may form bonding pads 1180.

As described above, the bonding surfaces of bonding layers 1110 and 1150 may be conditioned before hybrid bonding. For example, the surfaces of the metal bonding pads (e.g., Cu, Au, or Al pads) may include a surface oxide and/or other contamination. Excessive oxidation and/or contamination of the bonding surfaces may drastically decrease the bonding strength and electrical conductivity. Diffusion bonding may be performed in a vacuum or in an inert atmosphere (e.g., dry nitrogen, argon, or helium) to reduce detrimental oxidation or contamination of the bonding surfaces. The bonding layer may be cleaned and activated by, for example, an ion (e.g., plasma) beam or a fast atom (e.g., Ar) beam. Ar sputtering may remove the Cu oxide layer. The activated surface may be atomically clean and reactive for formation of direct bonds between wafers when they are brought into contact, for example, at room temperature. Surface treatments prior to plasma may include processes for removing surface oxide layers on the metal using citric acid, oxalic acid, and the like.

During the hybrid bonding, bonding layers 1110 and 1150 may be brought into contact. In some embodiments, compressive force may be applied to bonding layers 1110 and 1150 such that bonding layers 1110 and 1150 are pressed against each other. Due to the surface activation and the dishing in the bonding pads 1140 and 1180, the oxide of oxide layer 1120 and the oxide of oxide layer 1160 may be in direct contact, and may react and form chemical bonds between them because the surface atoms may have dangling bonds and may be in unstable energy states after the activation. Thus, the oxide of oxide layer 1120 and the oxide of oxide layer 1160 may be bonded together by van der Waals attractions, with or without heat treatment or pressure. During annealing, oxide layer 1120 that is in contact with oxide layer 1160 may strengthen the bonds through a two-step condensation reaction to fuse the oxide-oxide interface together. The bonded wafer stack may be further annealed to cause the metal contacts to expand such that bonding pads 1140 and 1180 may be in contact and may form direct metallic bonds at the activated surfaces.

FIG. 11B illustrates an example of misalignment during the hybrid bonding of two wafers or dice. For micro-LED devices with small pitches (e.g., less than about 5 μm, 3 μm, or 2 μm), in order to have sufficiently large areas for strong dielectric bonding of the oxide-oxide interfaces at room temperature, the metal bonding pads may need to be small, such as about one quarter, one third, or one half of the total bond interface area. Precise alignment of the metal bonding pads may be needed to make good electrical connections between bonding pads 1140 and 1180. In the example illustrated in FIG. 11B, bonding pads 1140 and 1180 may be misaligned, and the contact region between bonding pads 1140 and 1180 may be smaller than the bonding area of a bonding pad 1140 or a bonding pad 1180. In addition, due to the misalignment, the metal material of bonding pads 1140 and 1180 may be in direct contact with the oxide material of the bonding layers, and thus may diffuse into the oxide material and may cause leakage current between bonding pads of adjacent micro-LEDs.

FIG. 11C illustrates an example of a die stack formed by hybrid bonding of a first wafer 1102 and second wafer 1104. The illustrated example shows misalignment of the bonding pads at a bonding interface 1106. The misalignment may increase the resistance at the bonding interface and may cause diffusion of the metal material (e.g., Cu) into the oxide material as described above. In some cases, the bonding pads are small and the misalignment may be large at least in some regions. Thus, some bonding pads on a wafer may not be in contact with corresponding bonding pads on the other wafer, and therefore some micro-LED electrodes may not be connected to the drive circuits.

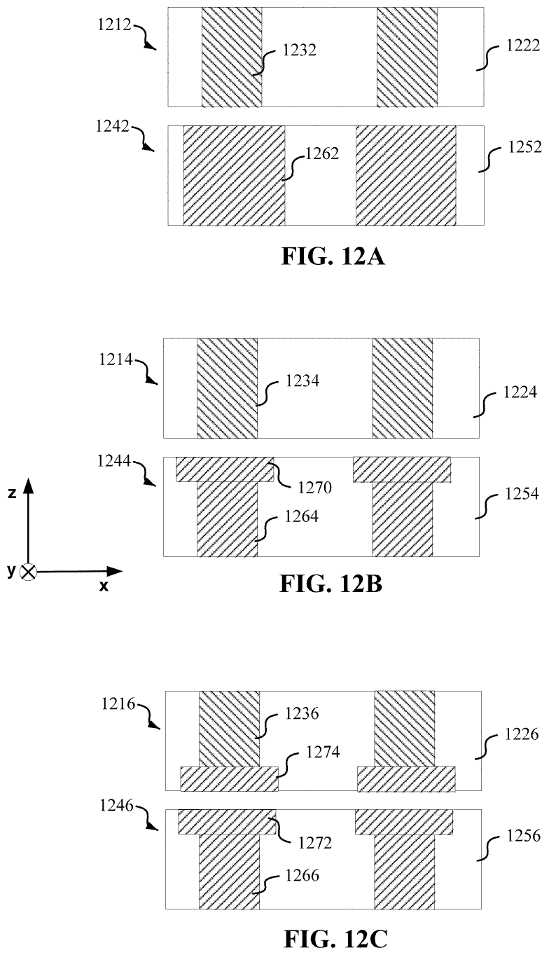

FIGS. 12A-12C illustrate examples of bonding pad designs that may mitigate misalignment during hybrid bonding to a certain degree. However, these bonding pad designs may reduce the dielectric bonding regions at the bonding surfaces or may cause short between bonding pads of adjacent micro-LEDs. In the example shown in FIG. 12A, a first wafer (e.g., GaAs wafer with micro-LEDs fabricated thereon) may including a bonding layer 1212, and a second wafer (e.g., a silicon wafer with drive circuits fabricated thereon) may include a bonding layer 1242. Bonding layer 1212 may include an oxide (e.g., SiO₂) layer 1222 with bonding pads 1232 (or metal plugs) formed in oxide layer 1222 as described above. One or more sidewall layers (e.g., an adhesion layer, a barrier layer, and a seed layer, not shown in FIG. 12A) may be between oxide layer 1222 and bonding pads 1232. Bonding layer 1242 may include an oxide (e.g., SiO₂) layer 1252 with bonding pads 1262 (or metal plugs) formed in oxide layer 1252 as described above. One or more sidewall layers (not shown in FIG. 12A) may be between oxide layer 1252 and bonding pads 1262. Bonding pads 1262 may be larger than bonding pads 1232 such that bonding pads 1232 may be in full contact with bonding pads 1262 even if there is some misalignment.

In the example shown in FIG. 12B, a first wafer (e.g., GaAs wafer with micro-LEDs fabricated thereon) may including a bonding layer 1214, and a second wafer (e.g., a silicon wafer with drive circuits fabricated thereon) may include a bonding layer 1244. Bonding layer 1214 may include an oxide (e.g., SiO₂) layer 1224 with metal bonding pads 1234 (or metal plugs) formed in oxide layer 1224 as described above. One or more sidewall layers (not shown in FIG. 12B) may be between oxide layer 1224 and bonding pads 1234. Bonding layer 1244 may include an oxide (e.g., SiO₂) layer 1254 with bonding pads 1264 (or metal plugs) formed in oxide layer 1254 as described above. One or more sidewall layers (not shown in FIG. 12B) may be between oxide layer 1254 and bonding pads 1264. Bonding pads 1264 may include two sections that have different sizes, where a top portion 1270 at the bonding surface may be larger than the other portion of bonding pads 1264 and larger than bonding pads 1234, such that bonding pads 1234 may be in full contact with bonding pads 1264 even if there is some misalignment.

In the example shown in FIG. 12C, a first wafer (e.g., GaAs wafer with micro-LEDs fabricated thereon) may including a bonding layer 1216, and a second wafer (e.g., a silicon wafer with drive circuits fabricated thereon) may include a bonding layer 1246. Bonding layer 1216 may include an oxide (e.g., SiO₂) layer 1226 with bonding pads 1236 (or metal plugs) formed in oxide layer 1226 as described above. Bonding pads 1236 may include two or more sections that have different sizes, where a top portion 1274 at the bonding surface may be larger than other portions of bonding pads 1236. One or more sidewall layers (not shown in FIG. 12C) may be between oxide layer 1226 and bonding pads 1236. Bonding layer 1246 may include an oxide (e.g., SiO₂) layer 1256 with bonding pads 1266 (or metal plugs) formed in oxide layer 1256 as described above. One or more sidewall layers (not shown in FIG. 12C) may be between oxide layer 1256 and bonding pads 1266. Bonding pads 1266 may also include two or more sections that have different sizes, where a top portion 1272 may be larger than other portions of bonding pads 1266. Therefore, there may be a sufficiently large contact area between bonding pads 1236 and bonding pads 1266 even if there is some misalignment. The examples of bonding pad designs shown in FIGS. 12A-12C may reduce the dielectric bonding regions at the bonding surface, and thus may not have sufficient dielectric bonding strength. In addition, the large bonding pads may cause short between bonding pads of adjacent micro-LEDs if the misalignment is large.

As described above with respect to, for example, FIGS. 9A-9D, to bond the micro-LED device (e.g., on a III-V wafer) with the drive circuits (e.g., on a CMOS backplane) through wafer-level hybrid bonding, the bonding surfaces of the micro-LED wafer and the CMOS backplane may need to be planarized, for example, by chemical mechanical planarization (CMP) techniques or other techniques. The planarization of the bonding surfaces may cause dishing in the metal bonding pads. As such, there may be a void between a metal bonding pad on the micro-LED device and a corresponding metal bonding pad on the CMOS backplane due to the dishing on the two metal bonding pads. In some CMP processes, pad-slurry matching may be used to control the copper dishing and oxide erosion.

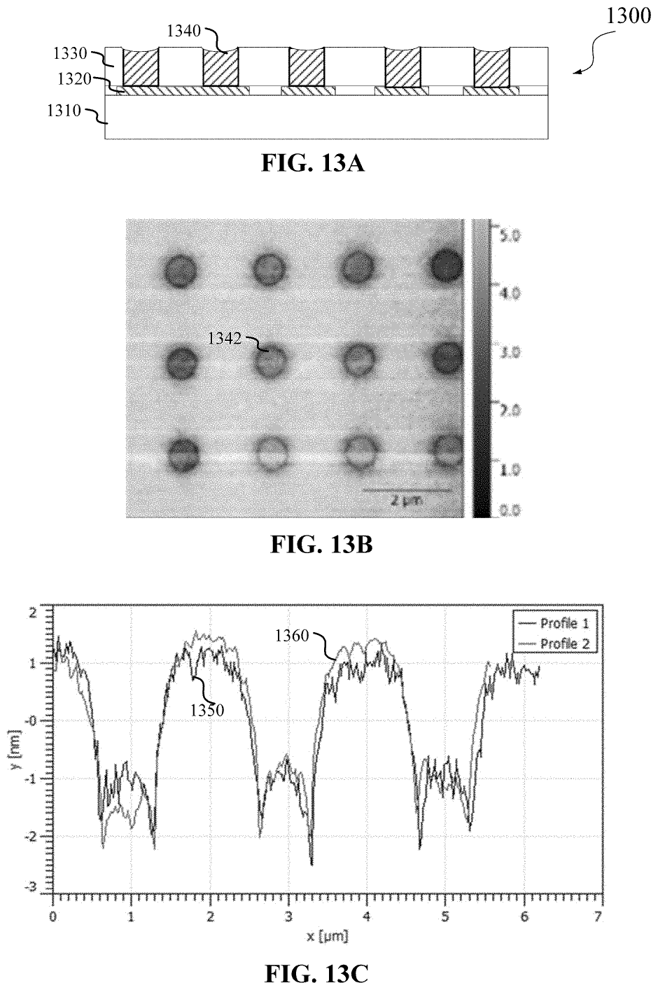

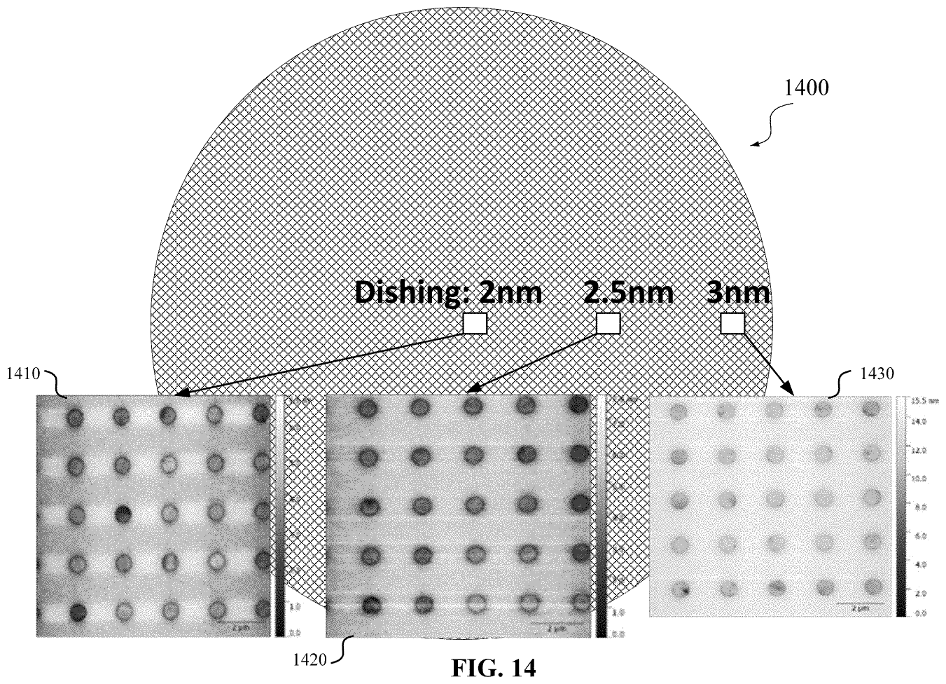

FIG. 13A illustrates an example of a wafer 1300 including bonding pads 1340 with dishing. Wafer 1300 may include a substrate 1310, such as a silicon substrate, a GaAs substrate, a sapphire substrate, or the like. Electrical or optoelectronic circuits 1320 may be formed on substrate 1310. A dielectric layer 1330 may be deposited on electrical or optoelectronic circuits 1320. Trenches may be etched in dielectric layer 1330 and may be filled with a metal material, such as copper, gold, or aluminum, to form bonding pads 1340. The top surface of the wafer 1300 may be planarized as described above to remove metal material on top of dielectric layer 1330 and form a smooth and flat bonding surface, which may be cleaned or activated for hybrid bonding as described above. The planarization process may cause dishing in bonding pads 1340.

FIG. 13B illustrates bonding pads 1342 with dishing in an example of a wafer 1302. In the illustrated example, the pitch of the two-dimensional array of bonding pads 1342 (e.g., for p-contacts) may be about 2 μm, and the diameter of each bonding pad 1342 may be about 0.75 or 0.8 μm. The depth of the dishing of bonding pads 1342 may be about 2 nm to about 2.5 nm.

FIG. 13C illustrates measured surface profiles of the example of wafer 1302 including copper bonding pads 1342 with dishing. A curve 1350 shows the height profile of a linear array of the two-dimensional array of bonding pads 1342. A curve 1360 shows the height profile of another linear array of the two-dimensional array of bonding pads 1342. FIG. 13C shows that the depth of the dishing of bonding pads 1342 may be about 2 nm to about 2.5 nm.

FIG. 14 illustrates an example of a wafer 1400 including copper bonding pads with dishing of different depths. In the illustrated example, wafer 1400 may be an 8-inch silicon wafer. The depth of the dishing at the center region 1410 of wafer 1400 may be about 2 nm. The depth of the dishing at a region 1420 of wafer 1400 may be about 2.5 nm. The depth of the dishing at the edge region 1430 of wafer 1400 may be about 3 nm.

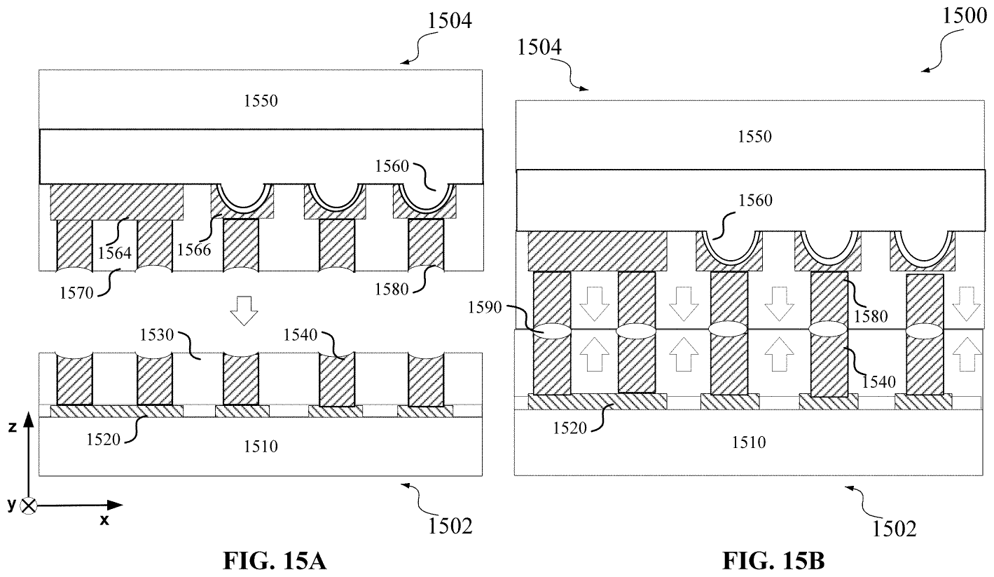

FIGS. 15A and 15B illustrate an example of hybrid bonding of two wafers 1502 and 1504 including copper bonding pads with dishing. FIG. 15A shows wafers 1502 and 1504 before the hybrid bonding. Wafer 1502 may include a silicon substrate 1510 with drive circuits 1520 fabricated thereon. A dielectric layer 1530 (e.g., SiO₂) may be deposited on drive circuits 1520. Trenches may be etched in dielectric layer 1530 and may be filled with a metal material, such as copper, gold, or aluminum, to form bonding pads 1540. As described above, a barrier layer (e.g., a Ti, Ta, or W layer, not shown in FIG. 15A) may be formed on sidewalls of the trenches before depositing the metal material to reduce or prevent the diffusion of the metal material to other regions that may cause leakage. The top surface of wafer 1502 may be planarized as described above to remove metal material on top of dielectric layer 1530 and form a smooth and flat bonding surface, which may then be cleaned or activated for hybrid bonding as described above. The planarization process may cause dishing in bonding pads 1540 as shown in FIG. 15A.

Wafer 1504 may include, for example, a substrate 1550 (e.g., a GaAs substrate) with an array of micro-LEDs 1560 fabricated thereon. The array of micro-LEDs 1560 may include an n-type semiconductor layer, an active region, and a p-type semiconductor layer epitaxially grown on substrate 1550. The epitaxial layers may then be processed from the side of the p-type semiconductor layer to form individual mesa structures, back reflectors/sidewall reflectors, p-contacts 1566, and n-contacts 1564. A dielectric layer 1570 (e.g., SiO₂) may be deposited on p-contacts 1566 and n-contacts 1564. Trenches may be etched in dielectric layer 1570 and may be filled with a metal material, such as copper, gold, or aluminum, to form bonding pads 1580. As described above, at least one barrier layer (e.g., a Ti, Ta, or W layer, or a multiple barrier layer stacks, such as TiN/Ti, TaN/Ta, Ti/TiN, Ta/TaN, etc., not shown in FIG. 15A) may be formed on sidewalls of the trenches before depositing the metal material to reduce or prevent the diffusion of the metal material to other regions that may cause leakage. The top surface of wafer 1504 may be planarized as described above to remove metal material on top of dielectric layer 1570 and form a smooth and flat bonding surface, which may then be cleaned or activated for hybrid bonding as described above. The planarization process may cause dishing in bonding pads 1580 as shown in FIG. 15A.

FIG. 15B shows that wafer 1502 and wafer 1504 may be brought into contact. In some embodiments, compressive force may be applied to wafer 1502 and wafer 1504 such that the bonding surfaces of wafer 1502 and wafer 1504 are pressed against each other. Due to the surface activation and the dishing in the bonding pads 1540 and 1580, the dielectric material (e.g., SiO₂) of dielectric layer 1530 and the dielectric material (e.g., SiO₂) of dielectric layer 1570 may be in direct contact, and may react and form chemical bonds between them because the surface atoms may have dangling bonds or adsorbed hydroxyl groups and may be in unstable energy states after the activation. Thus, the dielectric material (e.g., SiO₂) of dielectric layer 1530 and the dielectric material (e.g., SiO₂) of dielectric layer 1570 may be bonded together with or without heat treatment or pressure. Because of the dishing in the bonding pads 1540 and 1580, there may be a void 1590 between a bonding pad 1540 on wafer 1502 and a corresponding bonding pad 1580 on wafer 1504. As such, there may not be electric connection or may only be a high-impedance electric connection between bonding pad 1540 and bonding pad 1580.

Annealing at an elevated temperature may be performed such that the metal bonding pads may expand to reduce or eliminate void 1590 and form a reliable metal connection. When the ratio between the volume of void 1590 caused by the dishing and the volume of the metal material in metal bonding pads (e.g., bonding pad 1540 and bonding pad 1580) is large, the annealing temperature may need to be high in order to cause sufficient expansion of the metal material to completely fill the void. Annealing the bonded wafer stack including different materials on different substrates at high temperature may cause large wafer bowing due to, for example, the different thermal expansion coefficients of the different materials, such as Si substrate of the CMOS backplane and GaAs (or sapphire) substrate of the micro-LED device. The wafer bowing may create defects in or damages to the bonded wafer stack, such as high stress, cracks, delamination, crystal dislocation slip (glide), cratering, and the like.

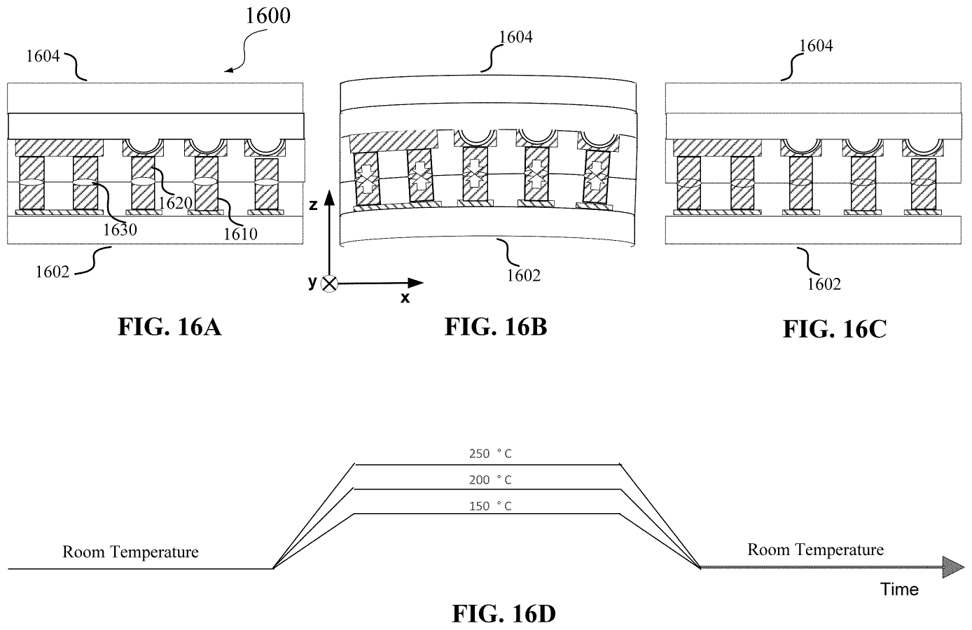

FIGS. 16A-16D illustrate an example of an annealing process for a wafer stack formed by hybrid bonding of two wafers including copper bonding pads with dishing. FIG. 16A shows a wafer stack 1600 that includes a first wafer 1602 (which may be similar to wafer 1502) and a second wafer 1604 (which may be similar to wafer 1504) bonded together by dielectric bonding at room temperature. Because of the dishing in bonding pads 1610 and 1620, there may be a void 1630 between a bonding pad 1610 on first wafer 1602 and a corresponding bonding pad 1620 on second wafer 1604.

FIG. 16B shows thermal annealing of wafer stack 1600 at elevated temperature(s). At sufficiently high annealing temperature(s), the metal material (e.g., copper, gold, or aluminum) in bonding pads 1610 and 1620 may expand to completely fill the void, and thus bonding pad 1610 may be bonded to bonding pad 1620 by metal bonds. As described above, annealing the bonded wafer stack 1600 including different materials on different substrates at high temperature may cause large wafer bowing due to, for example, the different CTEs of the different materials, such as Si substrate of first wafer 1602 (e.g., COS backplane) and GaAs (or sapphire) substrate of second wafer 1604. When the thickness of the substrate is high (e.g., before thinning or removing of the supporting substrate), the bowing may be more significant. For example, in some examples, the wafer bowing may be as high as above 500 μm to above 1000 μm for 200-mm wafers.

FIG. 16C shows that bonded wafer stack 1600 may be gradually cooled down to room temperature, where first wafer 1602 and second wafer 1604 may be flattened. The bowing and/or the subsequent flattening of wafer stack 1600 may create various defects or damages in the bonded wafer stack 1600 as described above.

FIG. 16D shows a temperature cycle during the hybrid bonding. The dielectric bonding may be performed at room temperature. The annealing may be performed at an elevated temperature, where the minimum annealing temperature may be determined based on the volume of the void caused by the dishing, the volume of the metal material in the metal bonding pads, the shape and/or the dimension of the metal bonding pads, and the like. For example, as described above with respect to FIG. 14, the depth of the dishing may be different at different regions of a wafer. Therefore, different minimum annealing temperatures may be applied to different regions of the wafer stack, rather than applying the same annealing temperature for the entire area of the wafer stack, in order to reduce the annealing temperature and the bowing caused by the high temperature annealing. In the example shown in FIG. 16D, during annealing, three different temperatures may be applied to, for example, three different regions of wafer stack 1600. In one example, the center region of wafer stack 1600 may have a lower dishing depth (e.g., about 2 nm in the example shown in FIG. 14), and thus an annealing temperature about 150° C. may be used. The peripheral regions of wafer stack 1600 may have a higher dishing depth (e.g., about 3 nm in the example shown in FIG. 14), and thus an annealing temperature about 250° C. may be used. The regions between the center region and the peripheral regions of wafer stack 1600 may have an intermediate dishing depth (e.g., about 2.5 nm), and thus an intermediate annealing temperature (e.g., about 200° C.) may be used. This non-uniform heating may mitigate overheating on the metal bonding pads with less dishing and the resulted delamination of the dielectric bonding (e.g., oxide-to-oxide bonding) at the higher annealing temperature for larger dishing. After annealing for a certain period of time, wafer stack 1600 may be cooled down gradually to room temperature.

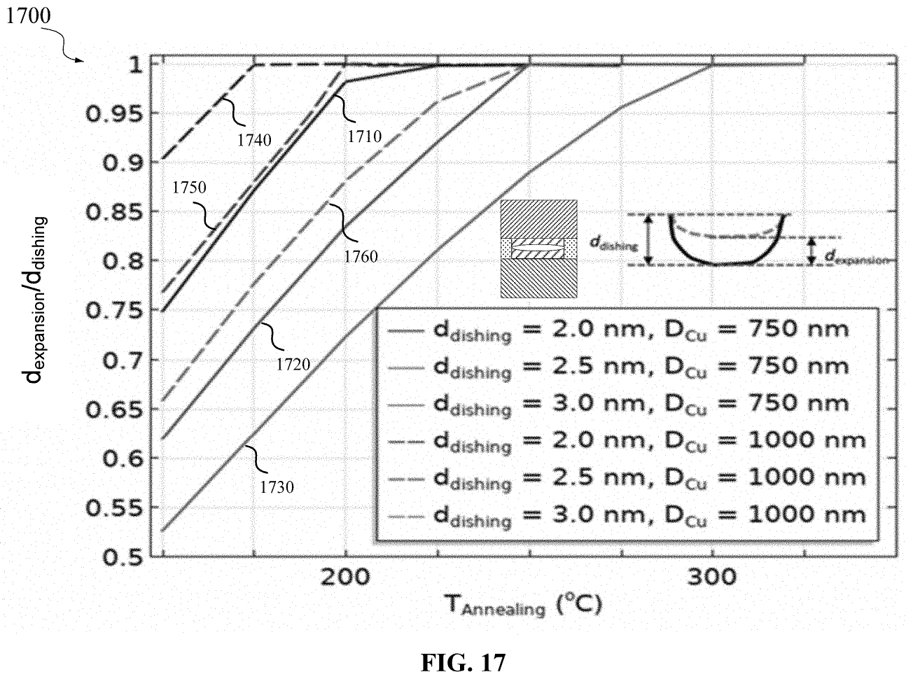

FIG. 17 includes a chart 1700 illustrating examples of copper expansion at different annealing temperatures for different examples of copper bonding pads with different diameters and dishing depths. Each bonding pad shown in the examples may have a cylindrical shape with a substantially uniform diameter of about 750 nm or about 1000 nm, and may have a different dishing depth d_{dishing}, such as about 2 nm, about 2.5 nm, or about 3 nm. The height of the expansion of a bonding pad at an elevated temperature is dₑₓₚₐₙₛᵢₒₙ. The minimum annealing temperature is the temperature under which the height of the expansion dₑₓₚₐₙₛᵢₒₙ of the bonding pad is the same as the dishing depth d_{dishing}.

In the illustrated examples, for a bonding pad with a diameter about 750 nm and a dishing depth d_{dishing} about 2 nm, the ratio between dₑₓₚₐₙₛᵢₒₙ and d_{dishing} at different annealing temperatures may be shown by a curve 1710, where the minimum annealing temperature under which dₑₓₚₐₙₛᵢₒₙ/d_{dishing} reaches 1.0 is about 225° C. For a bonding pad with a diameter about 750 nm and a dishing depth d_{dishing} about 2.5 nm, the ratio between dₑₓₚₐₙₛᵢₒₙ and d_{dishing} at different annealing temperatures may be shown by a curve 1720, where the minimum annealing temperature under which dₑₓₚₐₙₛᵢₒₙ/d_{dishing} reaches 1.0 is about 250° C. For a bonding pad with a diameter about 750 nm and a dishing depth d_{dishing} about 3 nm, the ratio between dₑₓₚₐₙₛᵢₒₙ and d_{dishing} at different annealing temperatures may be shown by a curve 1730, where the minimum annealing temperature under which dₑₓₚₐₙₛᵢₒₙ/d_{dishing} reaches 1.0 is about 300° C. Thus, for a given bonding pad, the higher the dishing depth d_{dishing}, the higher the minimum annealing temperature may need to be.

For a bonding pad with a diameter about 1000 nm and a dishing depth d_{dishing} about 2 nm, the ratio between dₑₓₚₐₙₛᵢₒₙ and d_{dishing} at different annealing temperatures may be shown by a curve 1740, where the minimum annealing temperature under which dₑₓₚₐₙₛᵢₒₙ/d_{dishing} reaches 1.0 is about 175° C. For a bonding pad with a diameter about 1000 nm and a dishing depth d_{dishing} about 2.5 nm, the ratio between dₑₓₚₐₙₛᵢₒₙ and d_{dishing} at different annealing temperatures may be shown by a curve 1750, where the minimum annealing temperature under which dₑₓₚₐₙₛᵢₒₙ/d_{dishing} reaches 1.0 is about 200° C. For a bonding pad with a diameter about 1000 nm and a dishing depth d_{dishing} about 3 nm, the ratio between dₑₓₚₐₙₛᵢₒₙ and d_{dishing} at different annealing temperatures may be shown by a curve 1760, where the minimum annealing temperature under which dₑₓₚₐₙₛᵢₒₙ/d_{dishing} reaches 1.0 is about 250° C. Compared with bonding pads having smaller diameters, bonding pads with larger diameters can be annealed at a lower annealing temperature in order to eliminate dishing having a same depth.

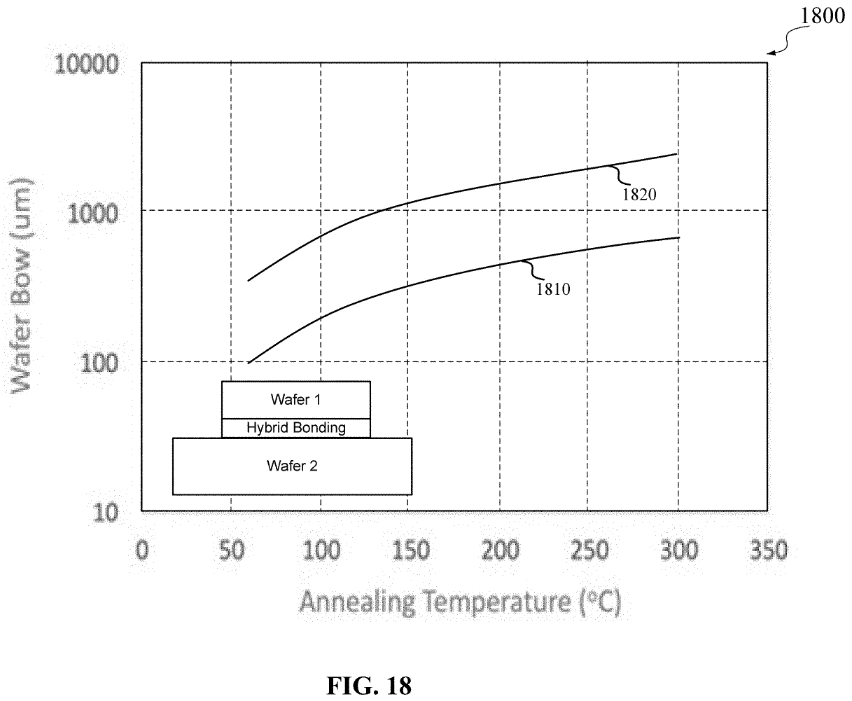

FIG. 18 illustrates examples of wafer bowing of a hybrid-bonded wafer stacks at different annealing temperatures. A curve 1810 in FIG. 18 shows the wafer bowing of a hybrid-bonded wafer stack including a first wafer and a second wafer at different annealing temperatures, where the thickness of the first wafer is about 50 μm. A curve 1820 in FIG. 18 shows the wafer bowing of a hybrid-bonded wafer stack including a first wafer and a second wafer at different annealing temperatures, where the thickness of the first wafer is about 600 μm. Curves 1810 and 1820 show that the wafer bowing of a hybrid-bonded wafer stack can be very large at higher annealing temperatures, in particular, for thick wafers. Thus, it may be desirable to reduce the minimum annealing temperature in order to reduce wafer bowing and the associated defects in the circuits or damages to the bonded wafer stack.

According to certain embodiments, the total volume of a metal (e.g., Cu) bonding pad may be increased, while still ensuring the dielectric bonding strength, by making the base part of the metal bonding pad much larger than the contacting part (at the bonding surface) of metal bonding pad. As a result, the cross-sectional area at the bonding surface may remain relatively small to have a relatively large oxide bonding area for high dielectric bonding strength, even for small-pitch micro-LED device (e.g., less than about 5 μm, 3 μm, or 2 μm), while the total volume of the metal (e.g., Cu) bonding pad may be increased significantly, such that the annealing temperature can be reduced, for example, by about 50° C. or more. In addition, due to the smaller cross-sectional area of the metal bonding pads at the bonding surface, the barrier layer at the bonding surface can have a higher width, such that barrier layer trenching at the bonding surface and/or misalignment of the bonding pads may not cause metal diffusion into the dielectric layer.

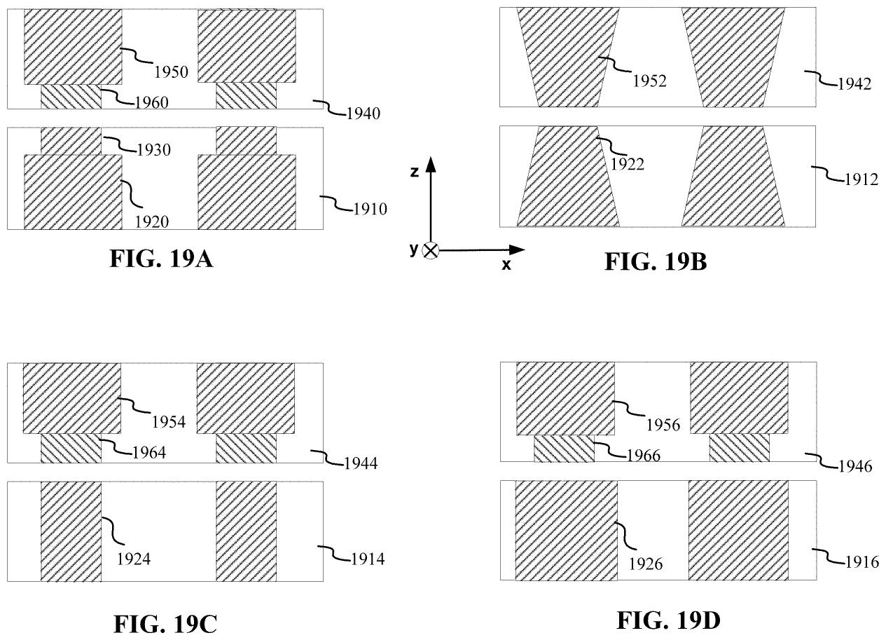

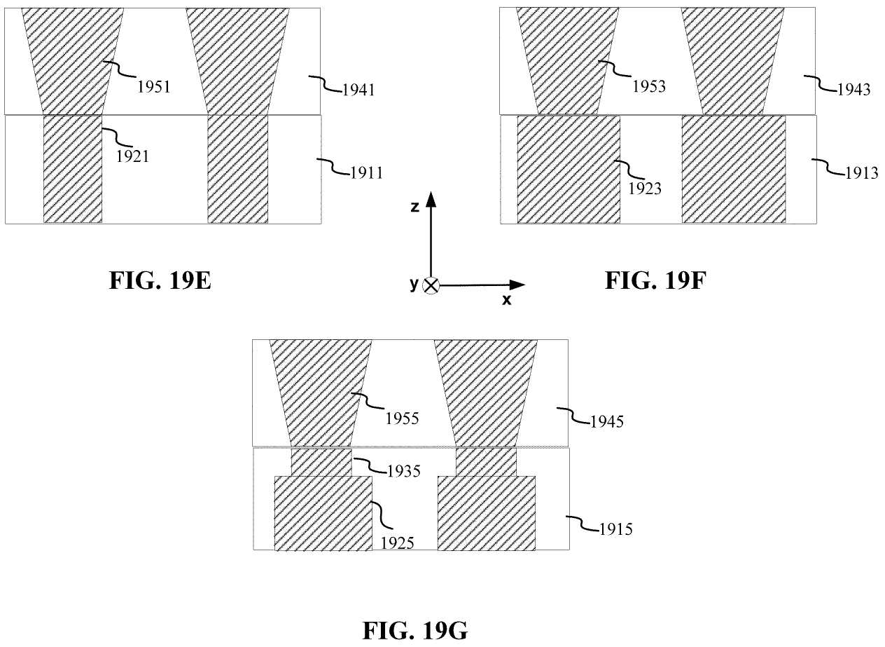

FIGS. 19A-19G illustrate some examples of copper bonding pad designs for reducing annealing temperature and improving bonding strength according to certain embodiments. The copper bonding pads may have any suitable shape at the bonding surface and/or in a horizontal (x-y) cross-section, such as a circle, an oval, a triangle, a rectangle, a square, another polygon, or any other regular or irregular shape. Even though copper bonding pads are shown in the examples, other metals, such as gold or aluminum, may also be used for the metal interconnects and the bonding pads.

In the example shown in FIG. 19A, two bonding layers 1910 and 1940 on two wafers may need to be bonded together using hybrid bonding. Bonding layer 1910 may include a plurality of bonding pads 1920 (e.g., copper pads) formed in a dielectric layer (e.g., SiO₂). Each bonding pad 1920 may include two sections, where the top portion 1930 (at the bonding surface) may have a smaller diameter such that there may be a larger dielectric bonding area at the interface to improve the dielectric bonding strength and reduce the possibility of shorting to an adjacent pad on bonding layer 1940. The bottom (or base) portion of bonding pad 1920 may have a large diameter, and thus the total volume of the metal material in bonding pad 1920 may be high, even though the contact area of bonding pad 1920 at the bonding surface is small (which may also have a lower dishing depth after the surface planarization). Therefore, a lower annealing temperature may be used to eliminate the dishing and the void formed after the room temperature dielectric bonding. As described above, at least a barrier layer (not shown in FIG. 19A) may be formed between bonding pads 1920 and the dielectric material to prevent or reduce the diffusion of the metal material.

Similarly, bonding layer 1940 may include a plurality of bonding pads 1950 (e.g., copper pads) formed in a dielectric layer (e.g., SiO₂). Each bonding pad 1950 may include two sections, where the top portion 1960 (at the bonding surface) may have a smaller diameter such that there may be a larger dielectric bonding area at the interface to improve the dielectric bonding strength and reduce the possibility of shorting to an adjacent bonding pad on bonding layer 1910. The bottom (or base) portion of bonding pad 1950 may have a large diameter, and thus the total volume of the metal material in bonding pad 1950 may be high, even though the contact area of the bonding pad 1950 at the bonding surface is small (which may also have a lower dishing depth after the surface planarization). Thus, a lower annealing temperature can be used to eliminate the dishing and the void formed after the room temperature dielectric bonding. As described above, at least a barrier layer (not shown in FIG. 19A) may be formed between bonding pads 1950 and the dielectric material to prevent or reduce the diffusion of the metal material.

In the example shown in FIG. 19B, two bonding layers 1912 and 1942 on two wafers may need to be bonded together using hybrid bonding. Bonding layer 1912 may include a plurality of bonding pads 1922 (e.g., copper pads) formed in a dielectric layer (e.g., SiO₂). Each bonding pad 1922 may have a shape of truncated cone, where the top surface (at the bonding surface) may have a smaller diameter (and thus may have a lower dishing depth after the surface planarization) such that there may be a larger dielectric bonding area at the interface to improve the dielectric bonding strength and reduce the possibility of shorting to an adjacent pad on bonding layer 1942. The diameter of bonding pad 1922 may gradually increase as the distance from the bonding surface increases. The total volume of the metal material in bonding pad 1922 may be higher than a cylinder-shaped bonding pad having a diameter that is same as the diameter of bonding pad 1922 at the bonding surface. As described above, at least a barrier layer (not shown in FIG. 19B) may be formed between bonding pads 1920 and the dielectric material to prevent or reduce the diffusion of the metal material. Bonding layer 1942 may include a plurality of bonding pads 1952 (e.g., copper pads) formed in a dielectric layer (e.g., SiO₂), where each bonding pad 1952 may be similar to bonding pad 1922. Therefore, a lower annealing temperature can be used to eliminate the dishing and the void formed after the room temperature dielectric bonding.

In the example shown in FIG. 19C, two bonding layers 1914 and 1944 on two wafers may need to be bonded together using hybrid bonding. Bonding layer 1914 may include a plurality of bonding pads 1924 (e.g., copper pads) formed in a dielectric layer (e.g., SiO₂), where each bonding pad 1924 may have a cylinder shape with a small diameter (e.g., ≤about ½, ⅓, or ¼ of a pitch of the plurality of bonding pads 1924). As described above, at least a barrier layer (not shown in FIG. 19C) may be formed between bonding pads 1924 and the dielectric material to prevent or reduce the diffusion of the metal material. Bonding layer 1944 may include a plurality of bonding pads 1954 (e.g., copper pads) formed in a dielectric layer (e.g., SiO₂). As described above, at least a barrier layer (not shown in FIG. 19C) may be formed between bonding pads 1954 and the dielectric material. Each bonding pad 1954 may include two sections, where the top portion 1964 (at the bonding surface) may have a smaller diameter such that there may be a larger dielectric bonding area at the interface to improve the dielectric bonding strength and reduce the possibility of shorting to an adjacent pad on bonding layer 1914. The bottom (or base) portion of bonding pad 1954 may have a large diameter, and thus the total volume of the metal material in bonding pad 1954 may be high, even though the contact area of the bonding pad 1954 at the bonding surface is small (which may have a lower dishing depth after the surface planarization). Therefore, a lower annealing temperature can be used to eliminate the dishing and the void formed after the room temperature dielectric bonding. In some embodiments, bonding pads 1924 may be replaced with bonding pads 1922 or 1952.

In the example shown in FIG. 19D, two bonding layers 1916 and 1946 on two wafers may need to be bonded together using hybrid bonding. Bonding layer 1916 may include a plurality of bonding pads 1926 (e.g., copper pads) formed in a dielectric layer (e.g., SiO₂), where each bonding pad 1926 may have a cylinder shape with a larger diameter. As described above, at least a barrier layer (not shown in FIG. 19D) may be formed between bonding pads 1926 and the dielectric material to prevent or reduce the diffusion of the metal material. Bonding layer 1946 may include a plurality of bonding pads 1956 (e.g., copper pads) formed in a dielectric layer (e.g., SiO₂). As described above, at least a barrier layer (not shown in FIG. 19D) may be formed between bonding pads 1956 and the dielectric material. Each bonding pad 1956 may include two sections, where the top portion 1966 (at the bonding surface) may have a smaller diameter to reduce the possibility of shorting to an adjacent pad on bonding layer 1916. The bottom (or base) portion of bonding pad 1956 may have a large diameter, and thus the total volume of the metal material in bonding pad 1956 may be high, even though the contact area of the bonding pad 1956 at the bonding surface is small (which may have a lower dishing depth after the surface planarization). Therefore, a lower annealing temperature may be used to eliminate the dishing and the void formed after the room temperature dielectric bonding. In some embodiments, bonding pads 1926 may be replaced with bonding pads 1922 or 1952.

FIG. 19E shows two bonding layers 1911 and 1941 (on two wafers) bonded together through hybrid bonding. Bonding layer 1911 may include a plurality of metal (e.g., Cu, Au, or Al) bonding pads 1921 formed in a dielectric (e.g., SiO₂) layer, where each metal bonding pad 1921 may have a cylindrical shape. Bonding layer 1941 may include a plurality of metal (e.g., Cu, Au, or Al) bonding pads 1951 formed in a dielectric (e.g., SiO₂) layer. The dielectric material in bonding layer 1941 may be bonded to the dielectric material in bonding layer 1911 through room temperature dielectric bonding. Each metal bonding pad 1951 may have a truncated conic shape, and may be bonded to a metal bonding pad 1921. The bottom (or base) portion of metal bonding pad 1951 may have a large diameter, and thus the total volume of the metal material in metal bonding pad 1951 may be high, even though the contact area of metal bonding pad 1951 at the bonding surface is small (and thus may have a lower dishing depth after the surface planarization). Therefore, a lower annealing temperature can be used to eliminate the dishing and the void formed after the room temperature dielectric bonding.

FIG. 19F shows two bonding layers 1913 and 1943 (on two wafers) bonded together through hybrid bonding. Bonding layer 1913 may include a plurality of metal (e.g., Cu, Au, or Al) bonding pads 1923 formed in a dielectric (e.g., SiO₂) layer, where each metal bonding pad 1923 may have a cylindrical shape. Bonding layer 1943 may include a plurality of metal (e.g., Cu, Au, or Al) bonding pads 1953 formed in a dielectric (e.g., SiO₂) layer. The dielectric material in bonding layer 1943 may be bonded to the dielectric material in bonding layer 1913 through room temperature dielectric bonding. Each metal bonding pad 1953 may have a truncated conic shape, and may be bonded to a metal bonding pad 1923. The bottom (or base) portion of metal bonding pad 1953 may have a large diameter, and thus the total volume of the metal material in metal bonding pad 1953 may be high, even though the contact area of metal bonding pad 1953 at the bonding surface is small (and thus may have a lower dishing depth after the surface planarization). Metal bonding pad 1923 may also have a large diameter and thus a large volume. Therefore, a lower annealing temperature can be used to eliminate the dishing and the void formed after the room temperature dielectric bonding.

FIG. 19G shows two bonding layers 1915 and 1945 (on two wafers) bonded together through hybrid bonding. Bonding layer 1915 may include a plurality of metal (e.g., Cu, Au, or Al) bonding pads 1925 formed in a dielectric (e.g., SiO₂) layer. Each metal bonding pad 1925 may include two sections, where the top portion 1935 (at or close to the bonding surface) may have a smaller diameter, such that there may be a larger dielectric bonding area at the interface to improve the dielectric bonding strength and reduce the possibility of shorting to an adjacent metal bonding pad on bonding layer 1945. The bottom (or base) portion of metal bonding pad 1925 may have a large diameter, and thus the total volume of the metal material in metal bonding pad 1925 may be high, even though the contact area of metal bonding pad 1925 at the bonding surface is small (and thus may have a lower dishing depth after the surface planarization). Bonding layer 1945 may include a plurality of metal (e.g., Cu, Au, or Al) bonding pads 1955 formed in a dielectric (e.g., SiO₂) layer. The dielectric material in bonding layer 1945 may be bonded to the dielectric material in bonding layer 1915 through room temperature dielectric bonding. Each metal bonding pad 1955 may have a truncated conic shape, and may be bonded to a metal bonding pad 1925. The bottom (or base) portion of metal bonding pad 1955 may have a large diameter, and thus the total volume of the metal material in metal bonding pad 1955 may be high, even though the contact area of metal bonding pad 1955 at the bonding surface is small (and thus may have a lower dishing depth after the surface planarization). Therefore, a lower annealing temperature can be used to eliminate the dishing and the void formed after the room temperature dielectric bonding.

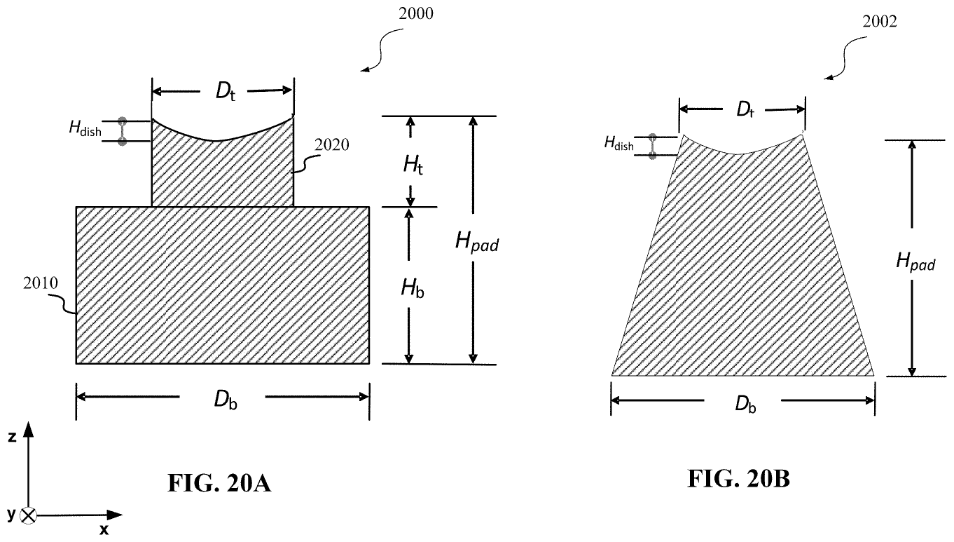

FIGS. 20A and 20B illustrate dimensions of examples of copper bonding pad designs according to certain embodiments. The example of bonding pad 2000 illustrated in FIG. 20A is an example of bonding pad 1920, 1950, 1954, or 1956 described above, and may include a metal material such as copper, gold, or aluminum. Bonding pad 2000 includes a base portion 2010 (the bottom portion) and a bonding portion 2020 (the top portion or the contact portion) that have different diameters and/or heights. Base portion 2010 may have a diameter D_{b} and a height H_{b}. Bonding portion 2020 may have a diameter Dₜ and a height Hₜ, and may have copper dishing with a depth H_{dish} at the bonding surface. The total height of bonding pad 2000 is H_{pad}. The total height of bonding pad 2000 is H_{pad}. Diameter D_{b}, height H_{b}, diameter Dₜ, and height Hₜ may be any suitable values determined based on, for example, the pitch of the ponding pad, dielectric bonding strength, depth H_{dish}, of the dishing, minimum annealing temperature, and the like.

The example of bonding pad 2002 illustrated in FIG. 20B is an example of bonding pads 1922 or 1952 described above, and may include a metal material such as copper, gold, or aluminum. Bonding pad 2002 may have a trapezoid shape in the cross-section (or a truncated cone shape in 3-D), where the top surface (at the bonding surface) may have a diameter Dₜ, and may have dishing with a depth H_{dish}. The diameter of bonding pad 2002 may gradually increase as the distance from the bonding surface increases. The diameter of bonding pad 2002 at the base (bottom) may be D_{b}. The total height of bonding pad 2002 is H_{pad}. Diameter D_{b}, and diameter Dₜ, may be any suitable values determined based on, for example, the pitch, dielectric bonding strength, depth H_{dish} of the dishing, minimum annealing temperature, and the like.

Table 1 shows parameters of examples of bonding pad design described above. The example of the reference design shown in Table 1 includes a cylinder-shaped copper bonding pad as shown in FIGS. 11A, 11B, and 15A-16C, where the height H_{pad} of the bonding pad is about 800 nm, and the bonding surface of the bonding pad may have a diameter Dₜ about 750 nm and a dishing depth H_{dish} about 2.5 nm. The example of bonding pad 2000 shown in Table 1 may also have a height H_{pad} about 800 nm, and the bonding surface of the bonding pad may have a diameter Dₜ about 750 nm and a dishing depth H_{dish} about 2.5 nm. The ratio between diameter Dₜ and diameter D_{b} of the example of bonding pad 2000 shown in Table 1 may be about 5:11, and the ratio between height Hₜ and height H_{b} of the example of bonding pad 2000 shown in Table 1 may be about 1:2. The example of bonding pad 2002 shown in Table 1 may also have a height H_{pad} about 800 nm, and the bonding surface of bonding pad 2002 may have a diameter Dₜ about 750 nm and a dishing depth H_{dish} about 2.5 nm. The ratio between diameter Dₜ and diameter D_{b} of the example of bonding pad 2002 shown in Table 1 may be about 5:11. Each of the three examples of bonding pad may be used in an array of copper bonding pads having a pitch about 2 μm.

TABLE 1
Parameters of examples of copper bonding pad designs

| | Reference | Bonding | Bonding |
|---|---|---|---|
| | bonding pad | pad 2000 | pad 2002 |
| Dₜ, nm | 750 | 750 | 750 |
| H_{pad}, nm | 800 | 800 | 800 |
| H_{dish}, nm | 2.5 | 2.5 | 2.5 |
| Pitch, nm | 2,000 | 2,000 | 2,000 |
| Dₜ:D_{b} | 1 | 5:11 | 5:11 |
| Hₜ:H_{b} | N/A | 1:2 | N/A |

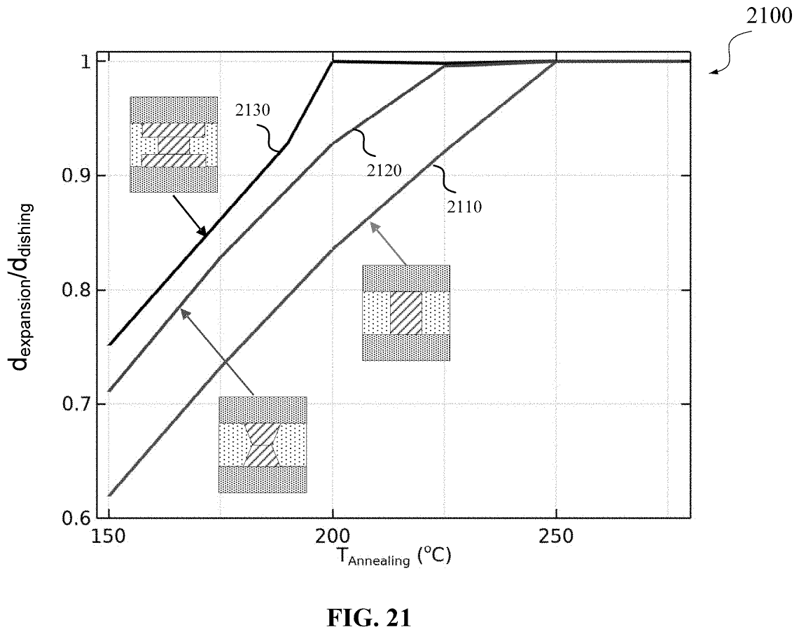

FIG. 21 includes a chart 2100 illustrating copper expansion as a function of the annealing temperature for the examples of copper bonding pad design shown in Table 1 according to certain embodiments. The depth of the dishing in all three examples is about 2.5 nm. A curve 2110 in FIG. 21 shows the ratio between dₑₓₚₐₙₛᵢₒₙ and d_{dishing} in the reference bonding pad of Table 1 at different annealing temperatures, where the minimum annealing temperature under which dₑₓₚₐₙₛᵢₒₙ/d_{dishing} reaches 1.0 (completely filling the void) is about 250° C. A curve 2120 in FIG. 21 shows the ratio between dₑₓₚₐₙₛᵢₒₙ and d_{dishing} in the example of bonding pad 2002 of Table 1 at different annealing temperatures, where the minimum annealing temperature under which dₑₓₚₐₙₛᵢₒₙ/d_{dishing} reaches 1.0 is about 225° C. A curve 2130 in FIG. 21 shows the ratio between dₑₓₚₐₙₛᵢₒₙ and d_{dishing} in the example of bonding pad 2000 of Table 1 at different annealing temperatures, where the minimum annealing temperature under which dₑₓₚₐₙₛᵢₒₙ/d_{dishing} reaches 1.0 is about 200° C. Thus, the minimum annealing temperature for eliminating the dishing in bonding pad 2000 may be about 50° C. lower than that for the reference design because of the larger volume of copper available for expansion in bonding pad 2000. The minimum annealing temperature for eliminating the dishing in bonding pad 2002 may be higher than that for bonding pad 2000 due to the slightly lower volume of copper available for expansion, but may be about 25° C. lower than that for the reference design because of the larger volume of copper available for expansion in bonding pad 2002 than in the reference design.

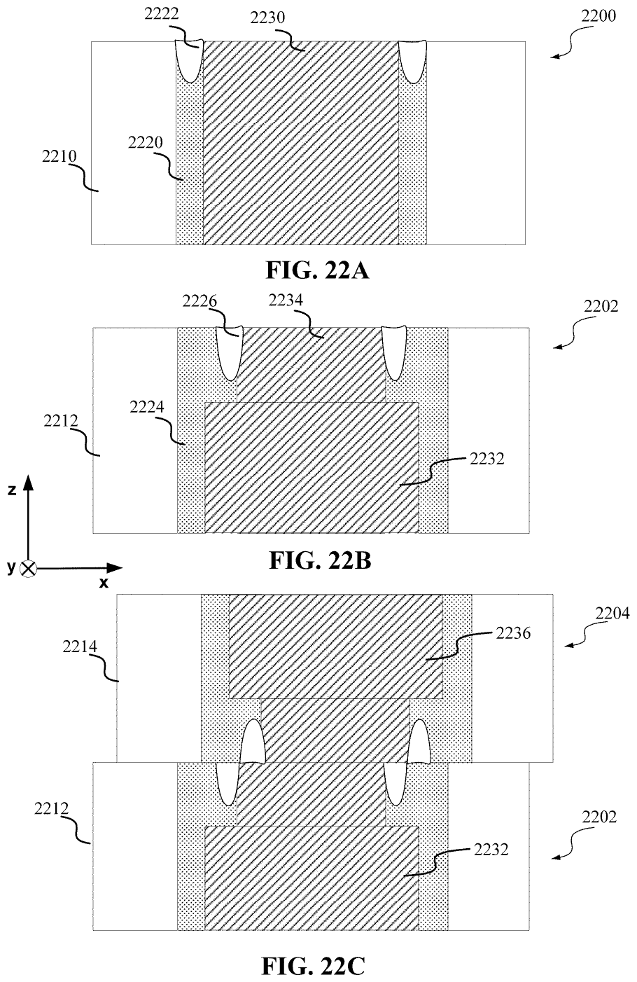

FIG. 22A illustrates an example of barrier layer trenching at a bonding surface. FIG. 22A shows a bonding layer 2200 that includes a copper bonding pad 2230 formed in a dielectric material layer 2210. Bonding layer 2200 also includes a barrier layer 2220 between copper bonding pad 2230 and the dielectric material of dielectric material layer 2210. Barrier layer 2220 may need to have a certain thickness in order to prevent the diffusion of copper from copper bonding pad 2230 to the dielectric material as described above. FIG. 22A shows that the planarization of the bonding surface of bonding layer 2200 may create barrier layer trenches 2222 near the bonding surface. As such, copper material in copper bonding pad 2230 may be in contact with the dielectric material, for example, when copper bonding pad 2230 expands during annealing.

FIG. 22B illustrates an example of barrier layer trenching at a bonding surface according to certain embodiments. FIG. 22B shows a bonding layer 2202 that includes a bonding pad 2232 formed in a dielectric material layer 2212. Bonding pad 2232 may include a base (bottom) portion that has a larger diameter and a top portion 2234 that has a smaller diameter as described above. Bonding layer 2202 also includes a barrier layer 2224 between bonding pad 2232 and the dielectric material of dielectric material layer 2212. Due to the smaller cross-sectional area of the top portion 2234 of bonding pads 2232 at the bonding surface, the barrier layer at the bonding surface can have a higher width, such that barrier layer trenching at the bonding surface and/or misalignment of the bonding pads may not cause metal diffusion into the dielectric layer. For example, FIG. 22B shows that, even though there may be barrier layer trenching at the bonding surface, there may still be some barrier layer material between bonding pad 2232 and the dielectric material of dielectric material layer 2212 to prevent metal diffusion.

FIG. 22C illustrates an example of bonding a bonding pad 2236 to a bonding pad 2232 according to certain embodiments. A bonding layer 2204 includes a dielectric layer 2214 and bonding pads 2236 formed in dielectric layer 2214 is bonded to bonding layer 2202 described above. A bonding layer 2204 may have a similar structure as bonding layer 2202. As illustrated, barrier layer trenching at the bonding surfaces and misalignment of the bonding pads in the two bonding layers may not cause metal diffusion into the dielectric layer due to the thicker barrier layers at or near the bonding surfaces.

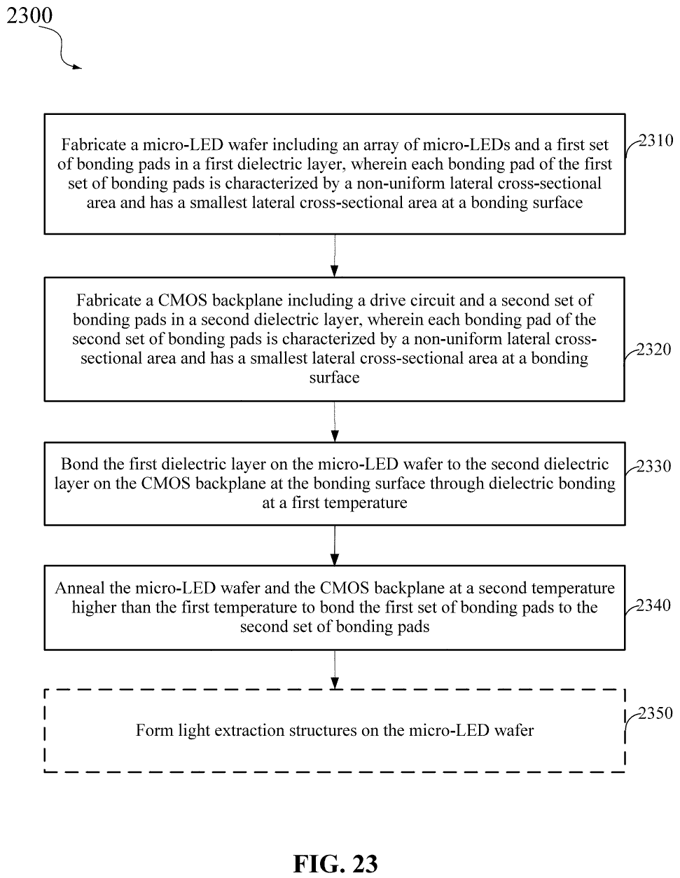

FIG. 23 includes a flowchart 2300 illustrating an example of a process of hybrid bonding according to certain embodiments. The operations described in flowchart 2300 are for illustration purposes only and are not intended to be limiting. Other sequences of operations can also be performed according to alternative embodiments. For example, alternative embodiments may perform the operations in a different order. Moreover, the individual operations illustrated in FIG. 23 can include multiple sub-operations that can be performed in various sequences as appropriate for the individual operation. Furthermore, some operations can be added or removed depending on the particular applications. In some implementations, two or more operations may be performed in parallel. One of ordinary skill in the art would recognize many variations, modifications, and alternatives.

Operations at block 2310 may include fabricating a micro-LED wafer including an array of micro-LEDs and a first set of bonding pads in a first dielectric layer. Each bonding pad of the first set of bonding pads may have a non-uniform lateral cross-sectional area and may have a smallest lateral cross-sectional area at a first surface (the bonding surface). A pitch of the array of micro-LEDs may be less than about 10 μm, less than 5 μm, less than 3 μm, or less than 2 μm. A pitch of the first set of bonding pads may be less than about 10 μm, less than 5 μm, less than 3 μm, or less than 2 μm. The first set of bonding pads may include metal bonding pads, such as copper pads or aluminum pads. In some embodiments, each bonding pad of the first set of bonding pads includes a first section having a first diameter and a second section having a second diameter that is larger than the first diameter. A height of the first section may be less than a half or a third of a height of the second section. The first diameter may be less than three quarters or a half of the second diameter. In some embodiments, each bonding pad of the first set of bonding pads may have a shape of a truncated cone. A diameter of a top surface of the truncated cone may be less than about three quarters or a half of a diameter of a base of the truncated cone. Each bonding pad of the first set of bonding pads may be electrically connected to a respective micro-LED in the array of micro-LEDs.

Operations at block 2320 may include fabricating a CMOS backplane including a drive circuit and a second set of bonding pads in a second dielectric layer. Each bonding pad of the second set of bonding pads may be characterized by a non-uniform lateral cross-sectional area and may have a smallest lateral cross-sectional area at a second surface (the bonding surface). A pitch of the second set of bonding pads may be less than about 10 μm, less than 5 μm, less than 3 μm, or less than 2 μm. The second set of bonding pads may include metal bonding pads, such as copper pads, gold pads, or aluminum pads. In some embodiments, each bonding pad of the second set of bonding pads may include a first section having a first diameter and a second section having a second diameter that is larger than the first diameter. A height of the first section may be less than a half or a third of a height of the second section. The first diameter may be less than three quarters or a half of the second diameter. In some embodiments, each bonding pad of the second set of bonding pads may have a shape of a truncated cone. A diameter of a top surface of the truncated cone may be less than about three quarters or a half of a diameter of a base of the truncated cone. Each bonding pad of the second set of bonding pads may be electrically connected to a respective micro-LED in the array of micro-LEDs through a corresponding bonding pad of the first set of bonding pads.

Operations at block 2330 may include bonding the first dielectric layer on the micro-LED wafer to the second dielectric layer on the CMOS backplane through dielectric bonding at a first temperature, such as a room temperature or another temperature below 50° C. As described above, before bonding, the bonding surface of the micro-LED wafer and the bonding surface of the CMOS backplane may be planarized, cleaned, and/or activated. The bond pads may have dishing after the planarization, and thus the bonded wafer stack may include voids between corresponding bonding pads.

Operations at block 2340 may include annealing the micro-LED wafer and the CMOS backplane at a second temperature higher than the first temperature to bond the first set of bonding pads to the second set of bonding pads (e.g., through thermal expansion). The second temperature may be below about 250° C., at or below about 200° C., or at or below about 150° C. The annealing may cause the expansion of the metal material (e.g., copper) of the bonding pads to fill the voids and for metallic bonds.

Optional operations at block 2350 may include forming a plurality of light extraction structures on the micro-LED wafer, such as micro-lenses, nano-structures, gratings, and the like, as described above with respect to, for example, FIG. 10.

According to certain embodiments, metal interconnects with larger heights may alternatively or additionally be used to provide more metal material and lower the annealing temperature for minimizing dishing and void. The thicker dielectric layer in which the metal interconnects are formed may be deposited at higher deposition temperatures, such as greater than about 300° C. (e.g., between about 350° C. and about 400° C.) for PECVD or greater than about 120° C. (e.g., between about 150° C. and about 250° C.) for inductively-coupled plasma enhanced chemical vapor deposition (ICPECVD). The high deposition temperatures may lead to larger wafer bowing at room temperature for Si, GaAs, or other wafers. In some embodiments, to reduce the wafer bow and warp (e.g., to less than about ±25 μm) for high precision bonding with high yield, an additional strain compensation layer, such as a SiN layer, a diamond like carbon (DLC) layer, and the like, may be deposited on the backside of the LED wafer and/or the backside of the Si wafer. In some embodiments, to reduce the wafer bow and wrap, local annealing inside laser spots may be performed by scanning a laser beam over the wafer, rather than performing a full wafer level annealing (e.g., at or below 250° C.).

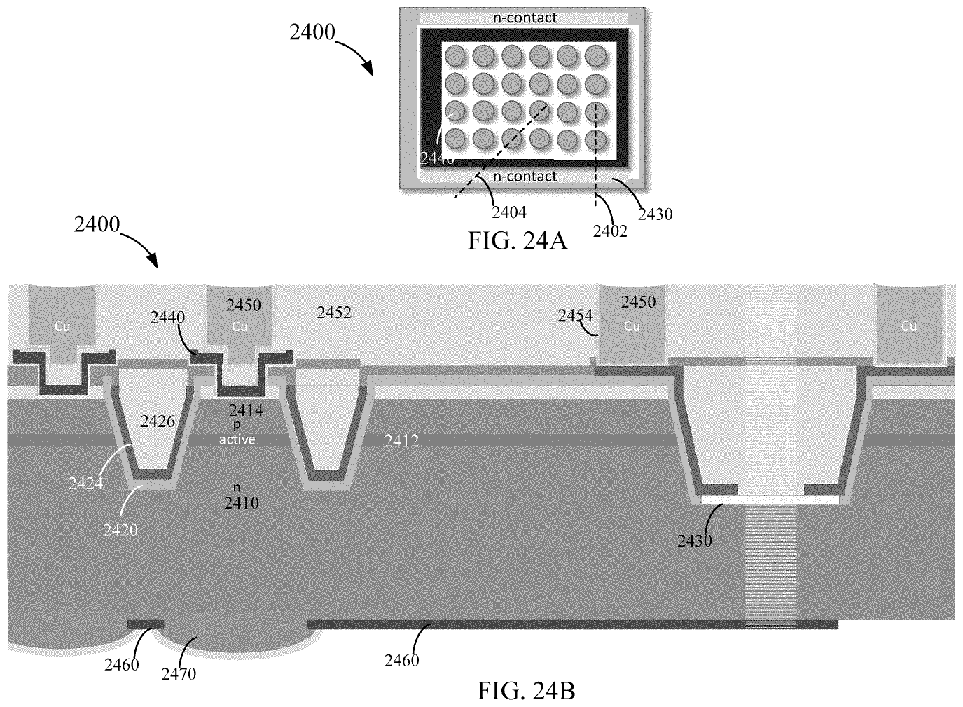

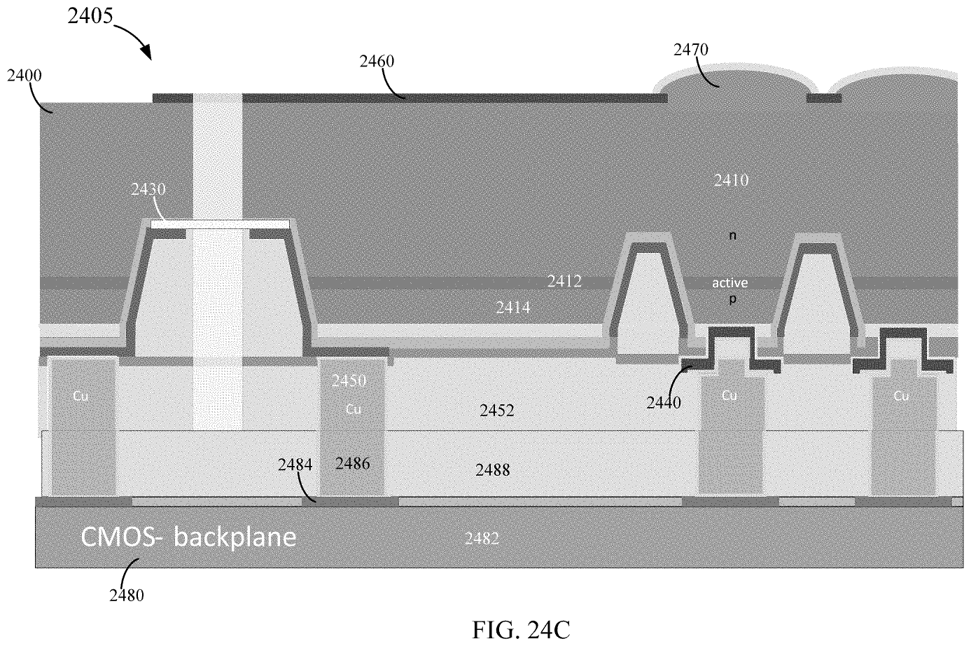

FIG. 24A illustrates an example of a micro-LED array 2400 according to certain embodiments. FIG. 24B illustrates a cross-sectional view of the example of micro-LED array 2400 according to certain embodiments. Micro-LED array 2400 may include a two-dimensional array of micro-LEDs arranged in a plurality of columns and rows. FIG. 24A shows individual p-contacts 2440 for the micro-LEDs in micro-LED array 2400, and two shared n-contacts 2430 near two edges of micro-LED array 2400. FIG. 24B shows the cross-section along a line 2402.

In the example shown in FIG. 24B, micro-LED array 2400 may include an n-type semiconductor layer 2410, an active layer 2412 that may include one or more quantum wells, and a p-type semiconductor layer 2414. Layers 2410, 2412, and 2414 may be etched to form individual mesa structures. A patterned dielectric layer 2420 (e.g., SiN) may be formed on the surfaces of the mesa structures as a barrier layer, and an n-contact 2430 may be formed on the exposed n-type semiconductor layer 2410. A metal (e.g., aluminum) layer 2424 may be formed on dielectric layer 2420 and n-contact 2430. P-contacts 2440 may be formed on p-type semiconductor layers 2414 of the mesa structures. Regions between the mesa structures may be filled with a dielectric material 2426, such as SiO₂. Metal interconnects 2450 (e.g., Cu, Au, or Al interconnects) may be formed in a dielectric (e.g., SiO₂, SiN, or SiCN) layer 2452 to connect to p-contacts 2440 and n-contact 2430. A barrier and/or metal seed layer 2454 (e.g., TiN/Ti or TaN/Ta) may be between metal interconnects 2450 and dielectric layer 2452. A patterned current spreading layer 2460 may be formed on the bottom surface of n-type semiconductor layer to provide additional n-contacts near each individual micro-LEDs. Light extraction structures 2470 (e.g., micro-lenses) may be formed on the exposed regions of n-type semiconductor layer 2410.

In some embodiments, patterned current spreading layer 2460 and light extraction structures 2470 may be formed on n-type semiconductor layer 2410 after micro-LED array 2400 is bonded to a driver circuit fabricated on a silicon wafer as described below, such that the silicon wafer may be used as the handle wafer and the processes can be performed from the side of n-type semiconductor layer 2410.

FIG. 24C illustrates an example of a device 2405 including a micro-LED array (e.g., micro-LED array 2400) bonded to a CMOS backplane 2480 according to certain embodiments. CMOS backplane 2480 may include a substrate 2482, such as a silicon substrate. CMOS integrated circuits 2484, such as micro-LED driving circuits, may be fabricated on substrate 2482. CMOS backplane 2480 may also include metal (e.g., Cu, Au, or Al) interconnects 2486 formed in a dielectric (e.g., SiO₂, SiN, or SiCN) layer 2488. Micro-LED array 2400 and CMOS backplane 2480 may be bonded such that metal interconnects 2450 and metal interconnects 2486 may be bonded together and dielectric layer 2452 and dielectric layer 2488 may be bonded together.

In some embodiments, micro-LED array 2400 may be bonded to CMOS backplane 2480 using a die-to-wafer or wafer-to-wafer hybrid bonding process disclosed herein. For example, the surface of the micro-LED array wafer and the surface of the CMOS backplane wafer may be cleaned and then activated by a low temperature (e.g., room temperature) plasma surface activation process. The surface-activated wafers may be aligned and pre-bonded at low temperature (e.g., room temperature) to bond the dielectric layer on the surface of the micro-LED wafer to the dielectric layer on the surface of the CMOS backplane wafer. The pre-bonded wafers may then be annealed at an elevated temperature, such as between about 150° C. and about 350° C., to bond metal pads on the micro-LED wafer to the metal pads on the CMOS backplane wafer.

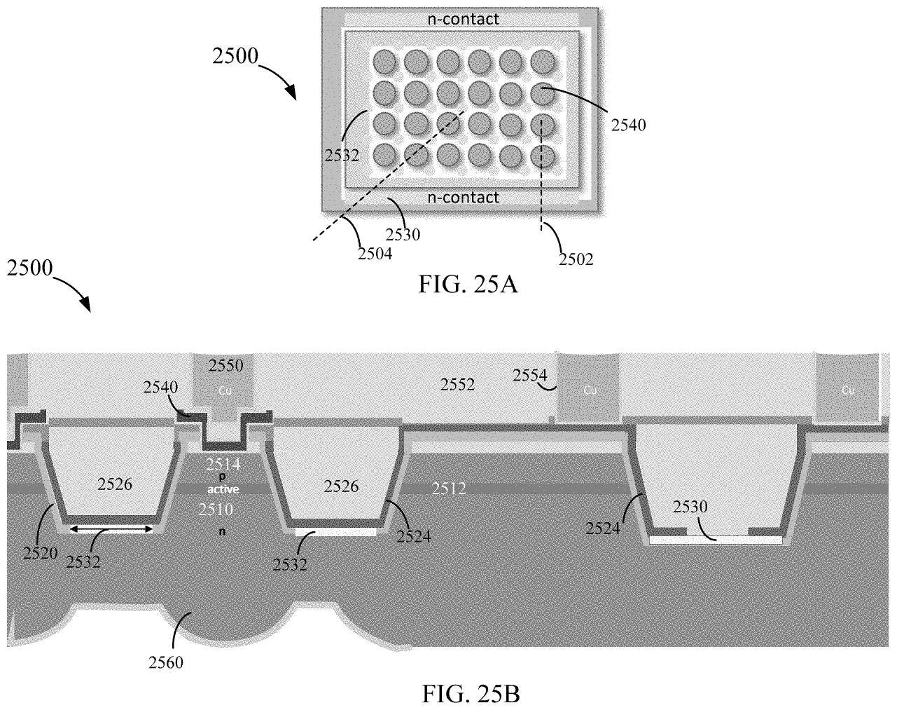

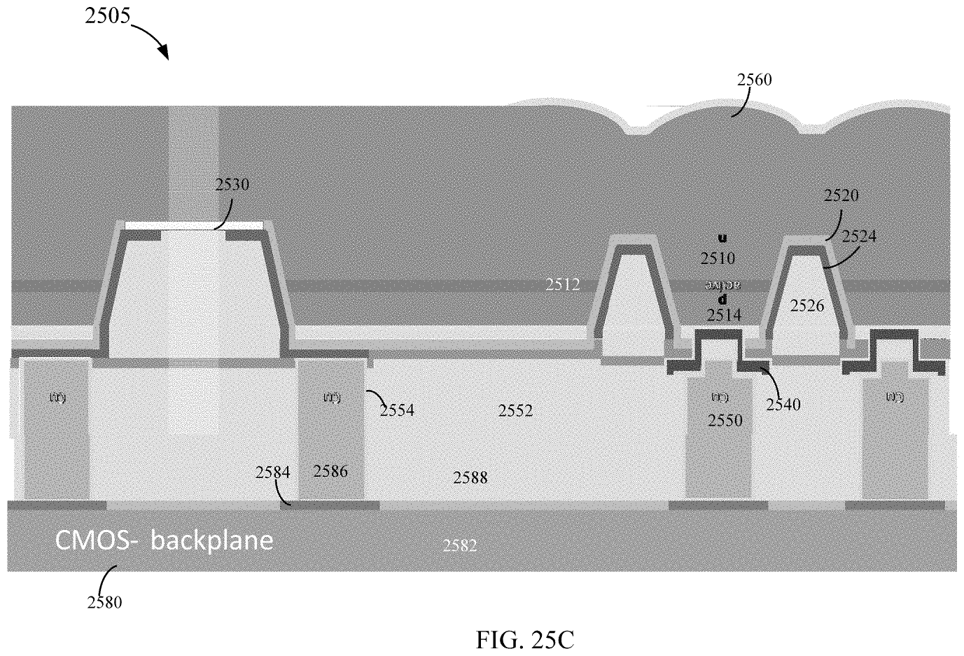

FIG. 25A illustrates an example of a micro-LED array 2500 according to certain embodiments. FIG. 25B illustrates a cross-sectional view of the example of micro-LED array 2500 shown in FIG. 25A according to certain embodiments. Micro-LED array 2500 may include a two-dimensional array of micro-LEDs arranged in a plurality of columns and rows. FIG. 25A shows individual p-contacts 2540 for the micro-LEDs in micro-LED array 2500, two shared n-contacts 2530 near two edges of micro-LED array 2500, and n-contacts 2532 adjacent and between the mesa structures of individual micro-LEDs. FIG. 25B shows the cross-section along a line 2504.

In the example shown in FIG. 25B, micro-LED array 2500 may include an n-type semiconductor layer 2510, an active layer 2512 that may include one or more quantum wells, and a p-type semiconductor layer 2514. Layers 2510, 2512, and 2514 may be etched to form individual mesa structures. A patterned dielectric layer 2520 (e.g., SiN) may be formed on the surfaces of the mesa structures as a barrier layer, and n-contacts 2530 and 2532 may be formed on the exposed n-type semiconductor layer 2510. The cross-sectional view along line 2504 in FIG. 25B shows n-contacts 2532 at locations where there may be larger gaps between adjacent mesa structures, such as the center of the diagonal line (e.g., along line 2504) between two adjacent mesa structures that are not in a same column or row of the two-dimensional micro-LED array 2500. In embodiments where the micro-LED may have a large pitch, n-contacts 2532 may also be at locations between adjacent mesa structures in a same row or column. A metal (e.g., aluminum) layer 2524 may be formed on dielectric layer 2520 and n-contacts 2530 and 2532. P-contacts 2540 may be formed on p-type semiconductor layers 2514 of the mesa structures. Regions between the mesa structures may be filled with a dielectric material 2526, such as SiO₂. Metal (e.g., Cu, Au, or Al) interconnects 2550 may be formed in a dielectric (e.g., SiO₂, SiN, or SiCN) layer 2552 to connect to p-contacts 2540 and n-contact 2530. A barrier and/or metal seed layer 2554 (e.g., TiN/Ti or TaN/Ta) may be between metal interconnects 2550 and dielectric layer 2552. Light extraction structures 2560 (e.g., micro-lenses) may be formed in n-type semiconductor layer 2510.

In some embodiments, light extraction structures 2560 may be formed on n-type semiconductor layer 2510 after micro-LED array 2500 is bonded to a driver circuit fabricated on a silicon wafer as described below, such that the silicon wafer may be used as the handle wafer and the processes can be performed from the side of n-type semiconductor layer 2510.

FIG. 25C illustrates an example of a device 2505 including a micro-LED array (e.g., micro-LED array 2500) bonded to a CMOS backplane 2580 according to certain embodiments. CMOS backplane 2580 may include a substrate 2582, such as a silicon substrate. CMOS integrated circuits 2584, such as micro-LED driving circuits, may be fabricated on substrate 2582. CMOS backplane 2580 may also include metal (e.g., Cu, Au, or Al) interconnects 2586 formed in a dielectric (e.g., SiO₂, SiN, or SiCN) layer 2588. Micro-LED array 2500 and CMOS backplane 2580 may be bonded such that metal interconnects 2550 and metal interconnects 2586 may be bonded together and dielectric layer 2552 and dielectric layer 2588 may be bonded together. FIG. 25C shows the cross-sectional view of micro-LED array 2500 long a line 2502 and thus n-contacts 2532 may not be viewable.

In some embodiments, micro-LED array 2500 may be bonded to CMOS backplane 2580 using a die-to-wafer or wafer-to-wafer hybrid bonding process disclosed herein. For example, the surface of the micro-LED array wafer and the surface of the CMOS backplane wafer may be cleaned and then activated by a low temperature (e.g., room temperature) plasma surface activation process. The surface-activated wafers may be aligned and pre-bonded at low temperature (e.g., room temperature) to bond the dielectric layer on the surface of the micro-LED wafer to the dielectric layer on the surface of the CMOS backplane wafer. The pre-bonded wafers may then be annealed at an elevated temperature, such as about 150° C. to about 350° C., to bond metal pads on the micro-LED wafer to the metal pads on the CMOS backplane wafer.

Embodiments disclosed herein may be used to implement components of an artificial reality system or may be implemented in conjunction with an artificial reality system. Artificial reality is a form of reality that has been adjusted in some manner before presentation to a user, which may include, for example, a virtual reality, an augmented reality, a mixed reality, a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, for example, create content in an artificial reality and/or are otherwise used in (e.g., perform activities in) an artificial reality. The artificial reality system that provides the artificial reality content may be implemented on various platforms, including an HMD connected to a host computer system, a standalone HMD, a mobile device or computing system, or any other hardware platform capable of providing artificial reality content to one or more viewers.

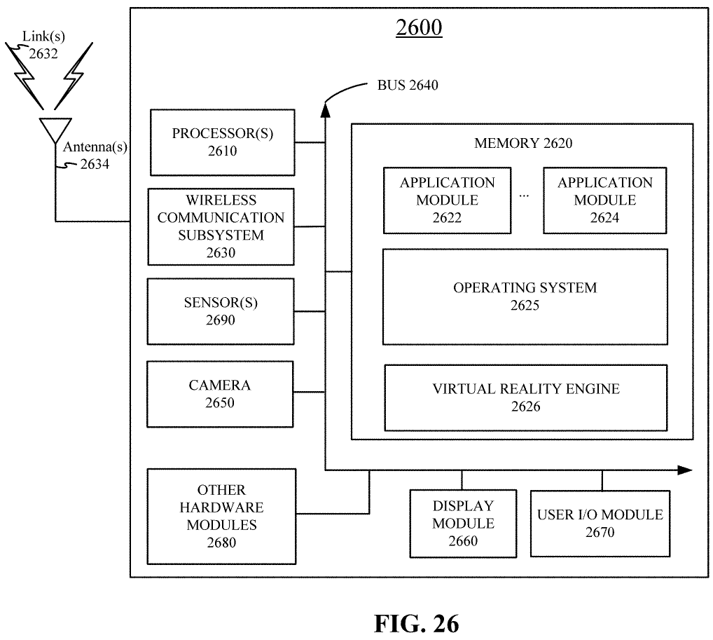

FIG. 26 is a simplified block diagram of an example electronic system 2600 of an example near-eye display (e.g., HMD device) for implementing some of the examples disclosed herein. Electronic system 2600 may be used as the electronic system of an HMD device or other near-eye displays described above. In this example, electronic system 2600 may include one or more processor(s) 2610 and a memory 2620. Processor(s) 2610 may be configured to execute instructions for performing operations at a number of components, and can be, for example, a general-purpose processor or microprocessor suitable for implementation within a portable electronic device. Processor(s) 2610 may be communicatively coupled with a plurality of components within electronic system 2600. To realize this communicative coupling, processor(s) 2610 may communicate with the other illustrated components across a bus 2640. Bus 2640 may be any subsystem adapted to transfer data within electronic system 2600. Bus 2640 may include a plurality of computer buses and additional circuitry to transfer data.

Memory 2620 may be coupled to processor(s) 2610. In some embodiments, memory 2620 may offer both short-term and long-term storage and may be divided into several units. Memory 2620 may be volatile, such as static random access memory (SRAM) and/or dynamic random access memory (DRAM) and/or non-volatile, such as read-only memory (ROM), flash memory, and the like. Furthermore, memory 2620 may include removable storage devices, such as secure digital (SD) cards. Memory 2620 may provide storage of computer-readable instructions, data structures, program modules, and other data for electronic system 2600. In some embodiments, memory 2620 may be distributed into different hardware modules. A set of instructions and/or code might be stored on memory 2620. The instructions might take the form of executable code that may be executable by electronic system 2600, and/or might take the form of source and/or installable code, which, upon compilation and/or installation on electronic system 2600 (e.g., using any of a variety of generally available compilers, installation programs, compression/decompression utilities, etc.), may take the form of executable code.

In some embodiments, memory 2620 may store a plurality of application modules 2622 through 2624, which may include any number of applications. Examples of applications may include gaming applications, conferencing applications, video playback applications, or other suitable applications. The applications may include a depth sensing function or eye tracking function. Application modules 2622-2624 may include particular instructions to be executed by processor(s) 2610. In some embodiments, certain applications or parts of application modules 2622-2624 may be executable by other hardware modules 2680. In certain embodiments, memory 2620 may additionally include secure memory, which may include additional security controls to prevent copying or other unauthorized access to secure information.

In some embodiments, memory 2620 may include an operating system 2625 loaded therein. Operating system 2625 may be operable to initiate the execution of the instructions provided by application modules 2622-2624 and/or manage other hardware modules 2680 as well as interfaces with a wireless communication subsystem 2630 which may include one or more wireless transceivers. Operating system 2625 may be adapted to perform other operations across the components of electronic system 2600 including threading, resource management, data storage control and other similar functionality.

Wireless communication subsystem 2630 may include, for example, an infrared communication device, a wireless communication device and/or chipset (such as a Bluetooth® device, an IEEE 802.11 device, a Wi-Fi device, a WiMax device, cellular communication facilities, etc.), and/or similar communication interfaces. Electronic system 2600 may include one or more antennas 2634 for wireless communication as part of wireless communication subsystem 2630 or as a separate component coupled to any portion of the system. Depending on desired functionality, wireless communication subsystem 2630 may include separate transceivers to communicate with base transceiver stations and other wireless devices and access points, which may include communicating with different data networks and/or network types, such as wireless wide-area networks (WWANs), wireless local area networks (WLANs), or wireless personal area networks (WPANs). A WWAN may be, for example, a WiMax (IEEE 802.16) network. A WLAN may be, for example, an IEEE 802.11x network. A WPAN may be, for example, a Bluetooth network, an IEEE 802.15x, or some other types of network. The techniques described herein may also be used for any combination of WWAN, WLAN, and/or WPAN. Wireless communications subsystem 2630 may permit data to be exchanged with a network, other computer systems, and/or any other devices described herein. Wireless communication subsystem 2630 may include a means for transmitting or receiving data, such as identifiers of HMD devices, position data, a geographic map, a heat map, photos, or videos, using antenna(s) 2634 and wireless link(s) 2632. Wireless communication subsystem 2630, processor(s) 2610, and memory 2620 may together comprise at least a part of one or more of a means for performing some functions disclosed herein.

Embodiments of electronic system 2600 may also include one or more sensors 2690. Sensor(s) 2690 may include, for example, an image sensor, an accelerometer, a pressure sensor, a temperature sensor, a proximity sensor, a magnetometer, a gyroscope, an inertial sensor (e.g., a module that combines an accelerometer and a gyroscope), an ambient light sensor, or any other similar module operable to provide sensory output and/or receive sensory input, such as a depth sensor or a position sensor. For example, in some implementations, sensor(s) 2690 may include one or more inertial measurement units (IMUs) and/or one or more position sensors. An IMU may generate calibration data indicating an estimated position of the HMD device relative to an initial position of the HMD device, based on measurement signals received from one or more of the position sensors. A position sensor may generate one or more measurement signals in response to motion of the HMD device. Examples of the position sensors may include, but are not limited to, one or more accelerometers, one or more gyroscopes, one or more magnetometers, another suitable type of sensor that detects motion, a type of sensor used for error correction of the IMU, or any combination thereof. The position sensors may be located external to the IMU, internal to the IMU, or any combination thereof. At least some sensors may use a structured light pattern for sensing.

Electronic system 2600 may include a display module 2660. Display module 2660 may be a near-eye display, and may graphically present information, such as images, videos, and various instructions, from electronic system 2600 to a user. Such information may be derived from one or more application modules 2622-2624, virtual reality engine 2626, one or more other hardware modules 2680, a combination thereof, or any other suitable means for resolving graphical content for the user (e.g., by operating system 2625). Display module 2660 may use LCD technology, LED technology (including, for example, OLED, ILED, μ-LED, AMOLED, TOLED, etc.), light emitting polymer display (LPD) technology, or some other display technology.

Electronic system 2600 may include a user input/output module 2670. User input/output module 2670 may allow a user to send action requests to electronic system 2600. An action request may be a request to perform a particular action. For example, an action request may be to start or end an application or to perform a particular action within the application. User input/output module 2670 may include one or more input devices. Example input devices may include a touchscreen, a touch pad, microphone(s), button(s), dial(s), switch(es), a keyboard, a mouse, a game controller, or any other suitable device for receiving action requests and communicating the received action requests to electronic system 2600. In some embodiments, user input/output module 2670 may provide haptic feedback to the user in accordance with instructions received from electronic system 2600. For example, the haptic feedback may be provided when an action request is received or has been performed.

Electronic system 2600 may include a camera 2650 that may be used to take photos or videos of a user, for example, for tracking the user's eye position. Camera 2650 may also be used to take photos or videos of the environment, for example, for VR, AR, or MR applications. Camera 2650 may include, for example, a complementary metal-oxide-semiconductor (CMOS) image sensor with a few millions or tens of millions of pixels. In some implementations, camera 2650 may include two or more cameras that may be used to capture 3-D images.

In some embodiments, electronic system 2600 may include a plurality of other hardware modules 2680. Each of other hardware modules 2680 may be a physical module within electronic system 2600. While each of other hardware modules 2680 may be permanently configured as a structure, some of other hardware modules 2680 may be temporarily configured to perform specific functions or temporarily activated. Examples of other hardware modules 2680 may include, for example, an audio output and/or input module (e.g., a microphone or speaker), a near field communication (NFC) module, a rechargeable battery, a battery management system, a wired/wireless battery charging system, etc. In some embodiments, one or more functions of other hardware modules 2680 may be implemented in software.

In some embodiments, memory 2620 of electronic system 2600 may also store a virtual reality engine 2626. Virtual reality engine 2626 may execute applications within electronic system 2600 and receive position information, acceleration information, velocity information, predicted future positions, or any combination thereof of the HMD device from the various sensors. In some embodiments, the information received by virtual reality engine 2626 may be used for producing a signal (e.g., display instructions) to display module 2660. For example, if the received information indicates that the user has looked to the left, virtual reality engine 2626 may generate content for the HMD device that mirrors the user's movement in a virtual environment. Additionally, virtual reality engine 2626 may perform an action within an application in response to an action request received from user input/output module 2670 and provide feedback to the user. The provided feedback may be visual, audible, or haptic feedback. In some implementations, processor(s) 2610 may include one or more GPUs that may execute virtual reality engine 2626.

In various implementations, the above-described hardware and modules may be implemented on a single device or on multiple devices that can communicate with one another using wired or wireless connections. For example, in some implementations, some components or modules, such as GPUs, virtual reality engine 2626, and applications (e.g., tracking application), may be implemented on a console separate from the head-mounted display device. In some implementations, one console may be connected to or support more than one HMD.

In alternative configurations, different and/or additional components may be included in electronic system 2600. Similarly, functionality of one or more of the components can be distributed among the components in a manner different from the manner described above. For example, in some embodiments, electronic system 2600 may be modified to include other system environments, such as an AR system environment and/or an MR environment.

The methods, systems, and devices discussed above are examples. Various embodiments may omit, substitute, or add various procedures or components as appropriate. For instance, in alternative configurations, the methods described may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples that do not limit the scope of the disclosure to those specific examples.

Specific details are given in the description to provide a thorough understanding of the embodiments. However, embodiments may be practiced without these specific details. For example, well-known circuits, processes, systems, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing various embodiments. Various changes may be made in the function and arrangement of elements without departing from the spirit and scope of the present disclosure.

Also, some embodiments were described as processes depicted as flow diagrams or block diagrams. Although each may describe the operations as a sequential process, many of the operations may be performed in parallel or concurrently. In addition, the order of the operations may be rearranged. A process may have additional steps not included in the figure. Furthermore, embodiments of the methods may be implemented by hardware, software, firmware, middleware, microcode, hardware description languages, or any combination thereof. When implemented in software, firmware, middleware, or microcode, the program code or code segments to perform the associated tasks may be stored in a computer-readable medium such as a storage medium. Processors may perform the associated tasks.

It will be apparent to those skilled in the art that substantial variations may be made in accordance with specific requirements. For example, customized or special-purpose hardware might also be used, and/or particular elements might be implemented in hardware, software (including portable software, such as applets, etc.), or both. Further, connection to other computing devices such as network input/output devices may be employed.

With reference to the appended figures, components that can include memory can include non-transitory machine-readable media. The term “machine-readable medium” and “computer-readable medium” may refer to any storage medium that participates in providing data that causes a machine to operate in a specific fashion. In embodiments provided hereinabove, various machine-readable media might be involved in providing instructions/code to processing units and/or other device(s) for execution. Additionally or alternatively, the machine-readable media might be used to store and/or carry such instructions/code. In many implementations, a computer-readable medium is a physical and/or tangible storage medium. Such a medium may take many forms, including, but not limited to, non-volatile media, volatile media, and transmission media. Common forms of computer-readable media include, for example, magnetic and/or optical media such as compact disk (CD) or digital versatile disk (DVD), punch cards, paper tape, any other physical medium with patterns of holes, a RAM, a programmable read-only memory (PROM), an erasable programmable read-only memory (EPROM), a FLASH-EPROM, any other memory chip or cartridge, a carrier wave as described hereinafter, or any other medium from which a computer can read instructions and/or code. A computer program product may include code and/or machine-executable instructions that may represent a procedure, a function, a subprogram, a program, a routine, an application (App), a subroutine, a module, a software package, a class, or any combination of instructions, data structures, or program statements.

Those of skill in the art will appreciate that information and signals used to communicate the messages described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Terms, “and” and “or” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or any combination of A, B, and/or C, such as AB, AC, BC, AA, ABC, AAB, AABBCCC, or the like.

Further, while certain embodiments have been described using a particular combination of hardware and software, it should be recognized that other combinations of hardware and software are also possible. Certain embodiments may be implemented only in hardware, or only in software, or using combinations thereof. In one example, software may be implemented with a computer program product containing computer program code or instructions executable by one or more processors for performing any or all of the steps, operations, or processes described in this disclosure, where the computer program may be stored on a non-transitory computer readable medium. The various processes described herein can be implemented on the same processor or different processors in any combination.

Where devices, systems, components or modules are described as being configured to perform certain operations or functions, such configuration can be accomplished, for example, by designing electronic circuits to perform the operation, by programming programmable electronic circuits (such as microprocessors) to perform the operation such as by executing computer instructions or code, or processors or cores programmed to execute code or instructions stored on a non-transitory memory medium, or any combination thereof. Processes can communicate using a variety of techniques, including, but not limited to, conventional techniques for inter-process communications, and different pairs of processes may use different techniques, or the same pair of processes may use different techniques at different times.

The specification and drawings are, accordingly, to be regarded in an illustrative rather than a restrictive sense. It will, however, be evident that additions, subtractions, deletions, and other modifications and changes may be made thereunto without departing from the broader spirit and scope as set forth in the claims. Thus, although specific embodiments have been described, these are not intended to be limiting. Various modifications and equivalents are within the scope of the following claims.

What is claimed is:

1. A device comprising:
an array of light sources;
a dielectric layer on the array of light sources; and
a set of metal bonding pads in the dielectric layer, each metal bonding pad of the set of metal bonding pads including:
a bonding surface for bonding to a drive circuit;
a first portion at the bonding surface and characterized by a first lateral cross-sectional area; and
a second portion away from the bonding surface and electrically connected to a respective light source of the array of light sources, the second portion characterized by a second lateral cross-sectional area larger than 1.2 times of the first lateral cross-sectional area.

2. The device of claim 1, wherein a pitch of the set of metal bonding pads is less than 10 μm, less than 5 μm, less than 3 μm, or less than 2 μm.

3. The device of claim 1, wherein:
each metal bonding pad of the set of metal bonding pads has a circular, elliptical, triangular, rectangular, quadrilateral, or another polygonal shape at the bonding surface; and
a linear dimension of each metal bonding pad of the set of metal bonding pads at the bonding surface is less than a half, a third, or a quarter of a pitch of the set of metal bonding pads.

4. The device of claim 1, wherein:
each metal bonding pad of the set of metal bonding pads includes a first cylindric section having a first diameter and a second cylindric section having a second diameter that is larger than the first diameter; and
the bonding surface of the metal bonding pad is on the first cylindric section.

5. The device of claim 4, wherein a height of the first cylindric section is equal to or less than a half of a height of the second cylindric section.

6. The device of claim 4, wherein the first diameter is less than three quarters or a half of the second diameter.

7. The device of claim 1, wherein each metal bonding pad of the set of metal bonding pads is characterized by a shape of a truncated cone.

8. The device of claim 7, wherein a diameter of a top surface of the truncated cone is less than three quarters or a half of a diameter of a base of the truncated cone.

9. The device of claim 1, wherein each metal bonding pad of the set of metal bonding pads is electrically connected to a p-contact region of the respective light source of the array of light sources.

10. A light source comprising:
a backplane including:
a drive circuit;
a first dielectric layer on the drive circuit; and
a first set of metal bonding pads in the first dielectric layer and electrically connected to the drive circuit; and
a light emitting diode (LED) die including:
an array of micro-light emitting diodes (micro-LEDs);
a second dielectric layer on the array of micro-LEDs; and
a second set of metal bonding pads in the second dielectric layer and electrically connected to the array of micro-LEDs,
wherein the first dielectric layer is bonded to the second dielectric layer at a bonding surface through dielectric bonding,
wherein each metal bonding pad of the first set of metal bonding pads is bonded to a corresponding metal bonding pad of the second set of metal bonding pads, and
wherein at least one of a metal bonding pad of the first set of metal bonding pads or a metal bonding pad of the second set of metal bonding pads includes:
a first portion at the bonding surface and characterized by a first lateral cross-sectional area; and
a second portion away from the bonding surface and characterized by a second lateral cross-sectional area larger than 1.2 times of the first lateral cross-sectional area.

11. The light source of claim 10, wherein a pitch of the first set of metal bonding pads and a pitch of the array of micro-LEDs are less than 10 μm, less than 5 μm, less than 3 μm, or less than 2 μm.

12. The light source of claim 10, wherein a linear dimension of a metal bonding pad of the second set of metal bonding pads at the bonding surface is less than a half, a third, or a quarter of a pitch of the second set of metal bonding pads.

13. The light source of claim 10, wherein each metal bonding pad of the first set of metal bonding pads and the second set of metal bonding pads includes:
a first cylindric section having a first diameter; and
a second cylindric section having a second diameter larger than the first diameter,
wherein a height of the first cylindric section is equal to or less than a half of a height of the second cylindric section, and
wherein the first diameter is less than three quarters or a half of the second diameter.

14. The light source of claim 10, wherein each metal bonding pad of the first set of metal bonding pads and the second set of metal bonding pads is characterized by a shape of a truncated cone, and wherein a diameter of a top surface of the truncated cone is less than three quarters or a half of a diameter of a base of the truncated cone.

15. The light source of claim 10, wherein each metal bonding pad of the first set of metal bonding pads includes a copper bonding pad, a gold bonding pad, or an aluminum bonding pad.

16. The light source of claim 10, wherein there is no void between each metal bonding pad of the first set of metal bonding pads and the corresponding metal bonding pad of the second set of metal bonding pads.

17. The light source of claim 10, wherein each metal bonding pad of the first set of metal bonding pads is electrically connected to a respective micro-LED in the array of micro-LEDs through the corresponding metal bonding pad of the second set of metal bonding pads.

18. A method comprising:
fabricating a wafer that includes an array of light sources and a first set of metal bonding pads in a first dielectric layer, wherein a pitch of the first set of metal bonding pads is less than 10 μm;
fabricating a CMOS backplane that includes a drive circuit and a second set of metal bonding pads in a second dielectric layer, wherein:
at least one of a metal bonding pad of the first set of metal bonding pads or a metal bonding pad of the second set of metal bonding pads is characterized by a non-uniform lateral cross-sectional area and has a smallest lateral cross-sectional area at a bonding surface, and
at least one of the metal bonding pad of the first set of metal bonding pads or the metal bonding pad of the second set of metal bonding pads has a concave surface at the bonding surface;
bonding the first dielectric layer of the wafer to the second dielectric layer of the CMOS backplane at the bonding surface through dielectric bonding at a first temperature; and
annealing the wafer and the CMOS backplane at a second temperature higher than the first temperature to bond the first set of metal bonding pads to the second set of metal bonding pads.

19. The method of claim 18, wherein:
the first set of metal bonding pads and the second set of metal bonding pads include copper bonding pads;
the first temperature is at or below 50° C.; and
the second temperature is at or below 340° C., or at or below 200° C.

20. The method of claim 18, wherein each metal bonding pad of the first set of metal bonding pads and the second set of metal bonding pads includes:
a first portion having a first diameter at the bonding surface; and
a second portion having a second diameter larger than 1.2 times of the first diameter.
